(19) United States
(12) Patent Application Publication
(10) Pub. No.: US 2025/0248034 A1
(43) Pub. Date: Jul. 31, 2025

(54) THREE-DIMENSIONAL MEMORY DEVICE WITH A STAIRCASE ISOLATION RIDGE AND METHODS OF FORMING THE SAME

(71) Applicant: SANDISK TECHNOLOGIES LLC, ADDISON, TX (US)

(72) Inventors: Kazuto Ohsawa, Yokkaichi (JP); Hirofumi Tokita, Yokkaichi (JP); Kota Funayama, Yokkaichi (JP)

(21) Appl. No.: 18/425,719

(22) Filed: Jan. 29, 2024

(51) Int. Cl. H10B 43/27; H10B 41/27

(52) U.S. Cl. CPC H10B 43/27; H10B 41/27

(57) ABSTRACT

A three-dimensional memory device includes an alternating stack of insulating layers and electrically conductive layers, memory openings vertically extending through the alternating stack in a first memory array region and in a second memory array region; memory opening fill structures located in the memory openings, a connection region in which at least a majority of the word lines continuously extend between the first memory array region and the second memory array region, a first staircase region in which first horizontally-extending surface segments of the alternating stack are arranged along the first horizontal direction and are interconnected to each other by first vertically-extending surface segments, and an upwardly protruding ridge including a second staircase region in which second horizontally-extending surface segments of the alternating stack are arranged along the first horizontal direction and are interconnected to each other by second vertically-extending surface segments.

### FIELD

The present disclosure relates generally to the field of semiconductor devices, and particularly to a three-dimensional memory device including a staircase isolation ridge and methods of forming the same.

### BACKGROUND

A three-dimensional memory device including three-dimensional vertical NAND strings having one bit per cell are disclosed in an article by T. Endoh et al, titled “Novel Ultra High Density Memory With A Stacked-Surrounding Gate Transistor (S-SGT) Structured Cell”, IEDM Proc. (2001) 33-36.

### SUMMARY

According to an aspect of the present disclosure, a three-dimensional memory device is provided, which comprises: an alternating stack of insulating layers and electrically conductive layers, wherein each layer within the alternating stack is present in a first memory array region and in a second memory array region that are laterally spaced from each other along a first horizontal direction, and the first memory array region and the second memory array region have a first width along a second horizontal direction that is perpendicular to the first horizontal direction; first memory openings and second memory openings vertically extending through the alternating stack in the first memory array region and in the second memory array region, respectively; first memory opening fill structures and second memory opening fill structures located in the first memory openings and in the second memory openings, respectively, and comprising a respective vertical stack of memory elements and a vertical semiconductor channel, wherein a predominant subset of the electrically conductive layers comprise word lines for the vertical stacks of memory elements; and an intermediate region located between the first memory array region and the second memory array region and comprising, in order along the second horizontal direction, a connection region in which at least a majority of the word lines continuously extend between the first memory array region and the second memory array region with a respective width that is less than the first width, a first staircase region in which first horizontally-extending surface segments of the alternating stack are arranged along the first horizontal direction and are interconnected to each other by first vertically-extending surface segments, and a second staircase region in which second horizontally-extending surface segments of the alternating stack are arranged along the first horizontal direction and are interconnected to each other by second vertically-extending surface segments, wherein each of the second horizontally-extending surface segments is vertically offset upward relative to a respective neighboring one of the first horizontally-extending surface segments by a respective vertical step.

According to another aspect of the present disclosure, a method forming a device structure is provided, which comprises: forming an alternating stack of insulating layers and sacrificial material layers over a substrate, wherein the alternating stack comprises a first memory array region, a second memory array region that is laterally spaced from the first memory array region along a first horizontal direction, and an intermediate region that is located between the first memory array region and the second memory array region; forming stepped surfaces within the intermediate region, wherein the intermediate region comprises a connection region in which at least a majority of the sacrificial material layers continuously extend between the first memory array region and the second memory array region, a first staircase region in which first horizontally-extending surface segments of the alternating stack are arranged along the first horizontal direction and are interconnected to each other by first vertically-extending surface segments, and a second staircase region in which second horizontally-extending surface segments of the alternating stack are arranged along the first horizontal direction and are interconnected to each other by second vertically-extending surface segments, wherein each of the second horizontally-extending surface segments is vertically offset upward relative to a respective neighboring one of the first horizontally-extending surface segments by a respective offset vertical step; forming a row of first dielectric etch-stop plates over the first horizontally-extending surface segments of the alternating stack; forming a row of second dielectric etch-stop plates over the second horizontally-extending surface segments of the alternating stack; forming a retro-stepped dielectric material portion over the first dielectric etch-stop plates and the second dielectric etch-stop plates; forming a first lateral isolation trench outside an area of the retro-stepped dielectric material portion and a second lateral isolation trench through the retro-stepped dielectric material portion and through the second dielectric etch-stop plates; and replacing the sacrificial material layers and the second dielectric etch-stop plates with electrically conductive layers and electrically conductive plates, respectively, without removing the first dielectric etch-stop plates.

### BRIEF DESCRIPTION OF THE DRAWINGS

FIG. 1 is a plan view of a memory die according to an embodiment of the present disclosure.

FIG. 2 is a vertical cross-sectional view of a region of a first exemplary structure after formation of an alternating layer stack of insulating layers and sacrificial material layers and a hard mask layer according to an embodiment of the present disclosure. The view shown in FIG. 2 corresponds to a vertical cross-sectional view of region M1 in FIG. 1.

FIGS. 3A-3D are various views of a region of the first exemplary structure after patterning the hard mask layer according to an embodiment of the present disclosure. FIG. 3A is a top-down view. FIG. 3B is a vertical cross-sectional view along the vertical plane B-B′ of FIG. 3A. FIG. 3C is a vertical cross-sectional view along the vertical plane C-C′ of FIG. 3A. FIG. 3D is a vertical cross-sectional view along the vertical plane D-D′ of FIG. 3A.

FIGS. 4A-4D are various views of a region of the first exemplary structure after formation of scale patterns according to an embodiment of the present disclosure. FIG. 4A is a top-down view. FIG. 4B is a vertical cross-sectional view along the vertical plane B-B′ of FIG. 4A. FIG. 4C is a vertical cross-sectional view along the vertical plane C-C′ of FIG. 4A. FIG. 4D is a vertical cross-sectional view along the vertical plane D-D′ of FIG. 4A.

FIGS. 5A-5D are various views of a region of the first exemplary structure after formation of stepped surfaces according to an embodiment of the present disclosure. FIG. 5A is a top-down view. FIG. 5B is a vertical cross-sectional view along the vertical plane B-B′ of FIG. 5A. FIG. 5C is a vertical cross-sectional view along the vertical plane C-C′ of FIG. 5A. FIG. 5D is a vertical cross-sectional view along the vertical plane D-D′ of FIG. 5A.

FIGS. 6A-6D are various views of a region of the first exemplary structure after formation of a first contact well according to an embodiment of the present disclosure. FIG. 6A is a top-down view. FIG. 6B is a vertical cross-sectional view along the vertical plane B-B′ of FIG. 6A. FIG. 6C is a vertical cross-sectional view along the vertical plane C-C′ of FIG. 6A. FIG. 6D is a vertical cross-sectional view along the vertical plane D-D′ of FIG. 6A.

FIGS. 7A-7D are various views of a region of the first exemplary structure after formation of second contact wells according to an embodiment of the present disclosure. FIG. 7A is a top-down view. FIG. 7B is a vertical cross-sectional view along the vertical plane B-B′ of FIG. 7A. FIG. 7C is a vertical cross-sectional view along the vertical plane C-C′ of FIG. 7A. FIG. 7D is a vertical cross-sectional view along the vertical plane D-D′ of FIG. 7A.

FIGS. 8A-8D are various views of a region of the first exemplary structure after formation of third contact wells according to an embodiment of the present disclosure. FIG. 8A is a top-down view. FIG. 8B is a vertical cross-sectional view along the vertical plane B-B′ of FIG. 8A. FIG. 8C is a vertical cross-sectional view along the vertical plane C-C′ of FIG. 8A. FIG. 8D is a vertical cross-sectional view along the vertical plane D-D′ of FIG. 8A.

FIGS. 9A-9D are various views of a region of the first exemplary structure after formation of fourth contact wells according to an embodiment of the present disclosure. FIG. 9A is a top-down view. FIG. 9B is a vertical cross-sectional view along the vertical plane B-B′ of FIG. 9A. FIG. 9C is a vertical cross-sectional view along the vertical plane C-C′ of FIG. 9A. FIG. 9D is a vertical cross-sectional view along the vertical plane D-D′ of FIG. 9A.

FIGS. 10A and 10B are vertical cross-sectional views of a region of the first exemplary structure after formation of stepped surfaces and contact wells according to an embodiment of the present disclosure. The vertical plane A-A′ in FIG. 10B is the cut plane of the vertical cross-sectional view of FIG. 10A.

FIGS. 11A and 11B are vertical cross-sectional views of a region of the first exemplary structure after formation of a conformal silicon oxide liner and a dielectric etch-stop material layer according to an embodiment of the present disclosure. The vertical plane A-A′ in FIG. 11B is the cut plane of the vertical cross-sectional view of FIG. 11A.

FIGS. 12A and 12B are vertical cross-sectional views of a region of the first exemplary structure after formation of a cover material layer according to an embodiment of the present disclosure. The vertical plane A-A′ in FIG. 12B is the cut plane of the vertical cross-sectional view of FIG. 12A.

FIGS. 13A and 13B are vertical cross-sectional views of a region of the first exemplary structure after dividing the dielectric etch-stop material layer into dielectric etch-stop plates according to an embodiment of the present disclosure. The vertical plane A-A′ in FIG. 13B is the cut plane of the vertical cross-sectional view of FIG. 13A.

FIGS. 14A and 14B are vertical cross-sectional views of a region of the first exemplary structure after removing the cover material layer according to an embodiment of the present disclosure. The vertical plane A-A′ in FIG. 14B is the cut plane of the vertical cross-sectional view of FIG. 14A.

FIGS. 15A and 15B are vertical cross-sectional views of a region of the first exemplary structure after formation of a retro-stepped dielectric material portion according to an embodiment of the present disclosure. The vertical plane A-A′ in FIG. 15B is the cut plane of the vertical cross-sectional view of FIG. 15A.

FIGS. 16A-16C are various views of a region of the first exemplary structure after formation of the retro-stepped dielectric material portion according to an embodiment of the present disclosure. FIG. 16C is a top-down view. FIG. 16A is a vertical cross-sectional view along the vertical plane A-A′ of FIG. 16C. FIG. 16B is a vertical cross-sectional view along the vertical plane A-A′ of FIG. 16C.

FIGS. 17A and 17B are additional views of a region of the first exemplary structure at the processing steps of FIGS. 16A-16C. FIG. 17A is a vertical cross-sectional view. FIG. 17B is a top-down view. The vertical plane A-A′ is the cut plane of the vertical cross-sectional view of FIG. 17A.

FIGS. 18A and 18B are views of a region of the first exemplary structure after formation of support pillar structures according to an embodiment of the present disclosure. FIG. 18A is a vertical cross-sectional view. FIG. 18B is a top-down view. The vertical plane A-A′ is the cut plane of the vertical cross-sectional view of FIG. 18A.

FIGS. 19A and 19B are views of a region of the first exemplary structure after formation of memory openings according to an embodiment of the present disclosure. FIG. 19A is a vertical cross-sectional view. FIG. 19B is a top-down view. The vertical plane A-A′ is the cut plane of the vertical cross-sectional view of FIG. 19A.

FIGS. 20A-20F are sequential vertical cross-sectional views of a memory opening during formation of a memory opening fill structure according to an embodiment of the present disclosure.

FIGS. 21A and 21B are various views of a region of the first exemplary structure after formation of the memory opening fill structures according to an embodiment of the present disclosure. FIG. 21A is a vertical cross-sectional view. FIG. 21B is a top-down view. The vertical plane A-A′ in FIG. 21B is the cut plane of the vertical cross-sectional view of FIG. 21A.

FIGS. 22A-22E are various views of a region of the first exemplary structure after formation of a contact-level dielectric layer and lateral isolation trenches according to an embodiment of the present disclosure. FIG. 22C is a top-down view. FIG. 22A is a vertical cross-sectional view along the vertical plane A-A′ of FIG. 22C. FIG. 22B is a vertical cross-sectional view along the vertical plane B-B′ of FIG. 22C. FIG. 22D is a vertical cross-sectional view along the vertical plane D-D′ of FIG. 22C. FIG. 22E is a vertical cross-sectional view along the vertical plane E-E′ of FIG. 22C. The vertical plane D-D′ in FIG. 22E is the cut plane of the vertical cross-sectional view of FIG. 22D.

FIGS. 23A-23C are various views of a region of the first exemplary structure after replacement of the sacrificial material layers with electrically conductive layers according to an embodiment of the present disclosure. FIG. 23C is a top-down view. FIG. 23A is a vertical cross-sectional view along the vertical plane A-A′ of FIG. 23C. FIG. 23B is a vertical cross-sectional view along the vertical plane B-B′ of FIG. 23C.

FIGS. 24A-24E are various views of a region of the first exemplary structure after formation of layer contact via structures according to an embodiment of the present disclosure. FIG. 24C is a top-down view. FIG. 24A is a vertical cross-sectional view along the vertical plane A-A′ of FIG. 24C. FIG. 24B is a vertical cross-sectional view along the vertical plane B-B′ of FIG. 24C. FIG. 24D is a vertical cross-sectional view along the vertical plane D-D′ of FIG. 24C. FIG. 24E is a vertical cross-sectional view along the vertical plane E-E′ of FIG. 24C. The vertical plane D-D′ in FIG. 24E is the cut plane of the vertical cross-sectional view of FIG. 24D.

FIGS. 25A and 25B are various views of a region of the first exemplary structure after formation of layer contact via structures according to an embodiment of the present disclosure. FIG. 25A is a top-down view. FIG. 25B is a vertical cross-sectional view along the vertical plane B-B′ of FIG. 25A.

FIGS. 26A and 26B are vertical cross-sectional views of a region of an alternative configuration of the first exemplary structure after formation of the layer contact via structures according to an embodiment of the present disclosure. The vertical plane A-A′ in FIG. 26B is the cut plane of the vertical cross-sectional view of FIG. 26A.

FIGS. 27A and 27B are vertical cross-sectional views of a second exemplary structure after formation of a conformal silicon oxide liner and a dielectric etch-stop material layer according to an embodiment of the present disclosure.

FIGS. 28A and 28B are vertical cross-sectional views of the second exemplary structure after dividing the dielectric etch-stop material layer into dielectric etch-stop plates according to an embodiment of the present disclosure.

FIGS. 29A and 29B are vertical cross-sectional views of the second exemplary structure after formation of a retro-stepped dielectric material portion and lateral isolation trenches, and replacement of sacrificial material layers with electrically conductive layers according to an embodiment of the present disclosure.

FIGS. 30A and 30B are vertical cross-sectional views of the second exemplary structure after formation of lateral isolation trench fill structures and layer contact via cavities according to an embodiment of the present disclosure.

FIGS. 31A and 31B are vertical cross-sectional views of the second exemplary structure after formation of layer contact via structures according to an embodiment of the present disclosure.

FIGS. 32A and 32B are vertical cross-sectional views of a third exemplary structure after formation of a conformal silicon oxide liner and a dielectric etch-stop material layer according to an embodiment of the present disclosure.

FIGS. 33A and 33B are vertical cross-sectional views of the third exemplary structure after dividing the dielectric etch-stop material layer into dielectric etch-stop plates according to an embodiment of the present disclosure.

FIGS. 34A and 34B are vertical cross-sectional views of the third exemplary structure after formation of sacrificial via structures, retro-stepped dielectric material portions, and lateral isolation trenches, and replacement of sacrificial material layers with electrically conductive layers according to an embodiment of the present disclosure.

FIGS. 35A and 35B are vertical cross-sectional views of the third exemplary structure after formation of lateral isolation trench fill structures and layer contact via cavities according to an embodiment of the present disclosure.

FIGS. 36A and 36B are vertical cross-sectional views of the third exemplary structure after formation of layer contact via structures according to an embodiment of the present disclosure.

FIGS. 37A and 37B are vertical cross-sectional views of a fourth exemplary structure after formation of a conformal silicon oxide liner and a dielectric etch-stop material layer according to an embodiment of the present disclosure.

FIGS. 38A and 38B are vertical cross-sectional views of the fourth exemplary structure after dividing the dielectric etch-stop material layer into dielectric etch-stop plates according to an embodiment of the present disclosure.

FIGS. 39A and 39B are vertical cross-sectional views of the fourth exemplary structure after formation of a retro-stepped dielectric material portion, sacrificial contact via structures, and lateral isolation trenches, and replacement of sacrificial material layers with electrically conductive layers according to an embodiment of the present disclosure.

FIGS. 40A and 40B are vertical cross-sectional views of the fourth exemplary structure after formation of lateral isolation trench fill structures and layer contact via cavities according to an embodiment of the present disclosure.

FIGS. 41A and 41B are vertical cross-sectional views of the fourth exemplary structure after formation of layer contact via structures according to an embodiment of the present disclosure.

### DETAILED DESCRIPTION

As discussed above, the embodiments of the present disclosure are directed to a three-dimensional memory device including a staircase isolation ridge and methods of forming the same, the various aspects of which are now described in detail.

The drawings are not drawn to scale. Multiple instances of an element may be duplicated where a single instance of the element is illustrated, unless absence of duplication of elements is expressly described or clearly indicated otherwise. Ordinals such as “first,” “second,” and “third” are employed merely to identify similar elements, and different ordinals may be employed across the specification and the claims of the instant disclosure. The term “at least one” element refers to all possibilities including the possibility of a single element and the possibility of multiple elements.

The same reference numerals refer to the same element or similar element. Unless otherwise indicated, elements having the same reference numerals are presumed to have the same composition and the same function. Unless otherwise indicated, a “contact” between elements refers to a direct contact between elements that provides an edge or a surface shared by the elements. If two or more elements are not in direct contact with each other or to each other, the two elements are “disjoined from” each other or “disjoined among” one another. As used herein, a first element located “on” a second element can be located on the exterior side of a surface of the second element or on the interior side of the second element. As used herein, a first element is located “directly on” a second element if there exists a physical contact between a surface of the first element and a surface of the second element. As used herein, a first element is “electrically connected to” a second element if there exists a conductive path consisting of at least one conductive material between the first element and the second element. As used herein, a “prototype” structure or an “in-process” structure refers to a transient structure that is subsequently modified in the shape or composition of at least one component therein.

As used herein, a “layer” refers to a material portion including a region having a thickness. A layer may extend over the entirety of an underlying or overlying structure, or may have an extent less than the extent of an underlying or overlying structure. Further, a layer may be a region of a homogeneous or inhomogeneous continuous structure that has a thickness less than the thickness of the first continuous structure. For example, a layer may be located between any pair of horizontal planes between, or at, a top surface and a bottom surface of the first continuous structure. A layer may extend horizontally, vertically, and/or along a tapered surface. A substrate may be a layer, may include one or more layers therein, or may have one or more layer thereupon, thereabove, and/or therebelow.

As used herein, a first surface and a second surface are “vertically coincident” with each other if the second surface overlies or underlies the first surface and there exists a vertical plane or a substantially vertical plane that includes the first surface and the second surface. A substantially vertical plane is a plane that extends straight along a direction that deviates from a vertical direction by an angle less than 5 degrees. A vertical plane or a substantially vertical plane is straight along a vertical direction or a substantially vertical direction, and may, or may not, include a curvature along a direction that is perpendicular to the vertical direction or the substantially vertical direction.

As used herein, a “memory level” or a “memory array level” refers to the level corresponding to a general region between a first horizontal plane (i.e., a plane parallel to the top surface of the substrate) including topmost surfaces of an array of memory elements and a second horizontal plane including bottommost surfaces of the array of memory elements. As used herein, a “through-stack” element refers to an element that vertically extends through a memory level.

As used herein, a “semiconducting material” refers to a material having electrical conductivity in the range from 1.0×10⁻⁵ S/m to 1.0×10⁵ S/m. As used herein, a “semiconductor material” refers to a material having electrical conductivity in the range from 1.0×10⁻⁵ S/m to 1.0 S/m in the absence of electrical dopants therein, and is capable of producing a doped material having electrical conductivity in a range from 1.0 S/m to 1.0×10⁷ S/m upon suitable doping with an electrical dopant. As used herein, an “electrical dopant” refers to a p-type dopant that adds a hole to a valence band within a band structure, or an n-type dopant that adds an electron to a conduction band within a band structure. As used herein, a “conductive material” refers to a material having electrical conductivity greater than 1.0×10⁵ S/m. As used herein, an “insulator material” or a “dielectric material” refers to a material having electrical conductivity less than 1.0×10⁻⁵ S/m. As used herein, a “heavily doped semiconductor material” refers to a semiconductor material that is doped with electrical dopant at a sufficiently high atomic concentration to become a conductive material either as formed as a crystalline material or if converted into a crystalline material through an anneal process (for example, from an initial amorphous state), i.e., to provide electrical conductivity greater than 1.0×10⁵ S/m. A “doped semiconductor material” may be a heavily doped semiconductor material, or may be a semiconductor material that includes electrical dopants (i.e., p-type dopants and/or n-type dopants) at a concentration that provides electrical conductivity in the range from 1.0×10⁻⁵ S/m to 1.0×10⁷ S/m. An “intrinsic semiconductor material” refers to a semiconductor material that is not doped with electrical dopants. Thus, a semiconductor material may be semiconducting or conductive, and may be an intrinsic semiconductor material or a doped semiconductor material. A doped semiconductor material may be semiconducting or conductive depending on the atomic concentration of electrical dopants therein. As used herein, a “metallic material” refers to a conductive material including at least one metallic element therein. All measurements for electrical conductivities are made at the standard condition.

The various three-dimensional memory devices of the present disclosure include a monolithic three-dimensional NAND string memory device, and may be fabricated using the various embodiments described herein. The monolithic three-dimensional NAND string is located in a monolithic, three-dimensional array of NAND strings located over the substrate. At least one memory cell in the first device level of the three-dimensional array of NAND strings is located over another memory cell in the second device level of the three-dimensional array of NAND strings.

Generally, a semiconductor package (or a “package”) refers to a unit semiconductor device that may be attached to a circuit board through a set of pins or solder balls. A semiconductor package may include a semiconductor chip (or a “chip”) or a plurality of semiconductor chips that are bonded throughout, for example, by flip-chip bonding or another chip-to-chip bonding. A package or a chip may include a single semiconductor die (or a “die”) or a plurality of semiconductor dies. A die is the smallest unit that may independently execute external commands or report status. Typically, a package or a chip with multiple dies is capable of simultaneously executing as many number of external commands as the total number of dies therein. Each die includes one or more planes. Identical concurrent operations may be executed in each plane within a same die, although there may be some restrictions. In case a die is a memory die, i.e., a die including memory elements, concurrent read operations, concurrent write operations, or concurrent erase operations may be performed in each plane within a same memory die. In a memory die, each plane contains a number of memory blocks (or “blocks”), which are the smallest unit that may be erased by in a single erase operation. Each memory block contains a number of pages, which are the smallest units that may be selected for programming. A page is also the smallest unit that may be selected to a read operation.

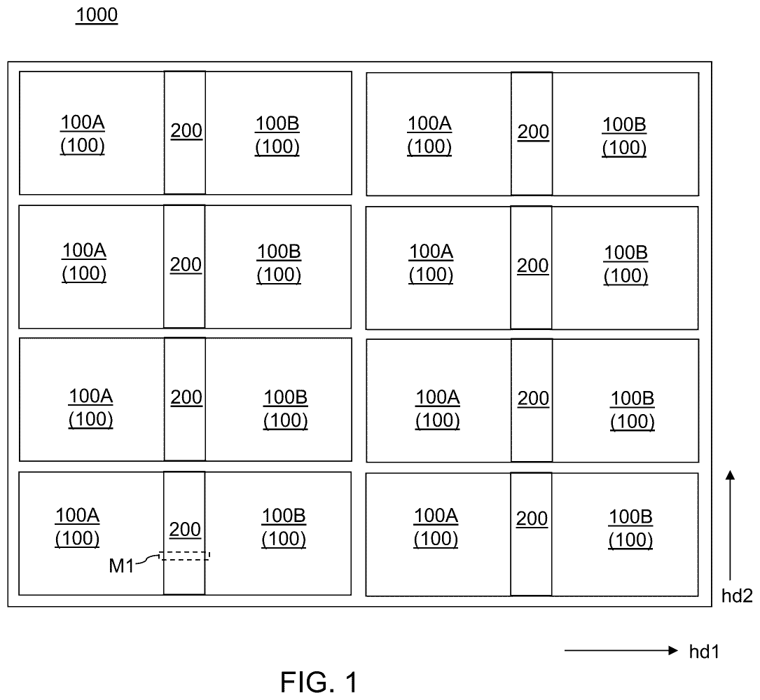

Referring to FIG. 1, a memory die 1000 is illustrated, which comprises multiple planes. Each plane may comprises two memory array regions 100, such as a first memory array region 100A and a second memory array region 100B that are laterally spaced apart by a respective intermediate region 200. Generally, a memory die 1000 may include a single plane or multiple planes. The total number of planes in the memory die 1000 may be selected based on performance requirements on the memory die. A pair of memory array regions 100 in a plane may be laterally spaced apart along a first horizontal direction hd1 (which may be the word line direction). For example, each pair of memory array regions 100 in a plane may include first memory array region 100A and a second memory array region 100B that are laterally spaced apart along the first horizontal direction hd1 by an intermediate region 200. A second horizontal direction hd2 (which may be the bit line direction) can be perpendicular to the first horizontal direction hd1. The memory die 1000 illustrated in FIG. 1 can be manufactured employing various embodiments of the present disclosure to be described below. Specifically, region M1 in FIG. 1 is illustrated in detail in subsequent figures.

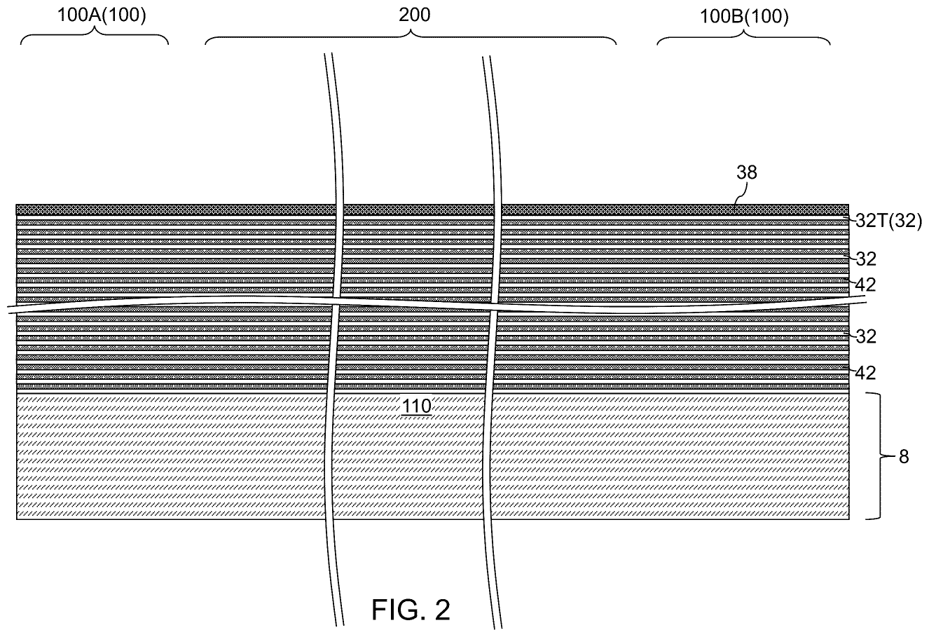

Referring to FIG. 2, a vertical cross-sectional view of a first exemplary structure for forming the memory die of FIG. 1 is illustrated. The first exemplary structure may comprise a substrate 8 containing a semiconductor material layer 110. The substrate may comprise a silicon wafer, a silicon on insulator substrate, or another substrate. The semiconductor material layer 110 may comprise a single crystalline or polycrystalline semiconductor layer, such as a single crystalline silicon layer or a polysilicon layer, and may comprise a doped well in a top portion of a silicon wafer substrate 8, a silicon layer deposited over the substrate 8, a silicon layer bonded to the substrate 8, etc.

An alternating stack (32, 42) of insulating layers 32 and spacer material layers can be formed over the semiconductor material layer 110. The spacer material layers are formed as, or are subsequently replaced with, electrically conductive layers. In case the spacer material layers are subsequently replaced with the electrically conductive layers, the spacer material layers may be formed as sacrificial material layers 42.

As used herein, an alternating stack refers to a sequence of multiple instances of a first element and multiple instances of a second element that is arranged such that an instance of a second element is located between each vertically neighboring pair of instances of the first element, and an instance of a first element is located between each vertically neighboring pair of instances of the second element. An alternating stack refers to a sequence of multiple instances of a first material layer and multiple instances of a second material layer such that the instances of the first material layer and the instances of the second material layer are interlaced.

The insulating layers 32 can be composed of the first material, and the sacrificial material layers 42 can be composed of the second material, which is different from the first material. Each of the insulating layers 32 continuously extends over the entire area of the substrate 8, and may have a uniform thickness throughout. Each of the sacrificial material layers 42 includes a sacrificial dielectric material and continuously extends over the entire area of the substrate 8, and may have a uniform thickness throughout. Insulating materials that may be used for the insulating layers 32 include, but are not limited to silicon oxide (including doped or undoped silicate glass), silicon nitride, silicon oxynitride, organosilicate glass (OSG), spin-on dielectric materials, dielectric metal oxides that are commonly known as high dielectric constant (high-k) dielectric oxides (e.g., aluminum oxide, hafnium oxide, etc.) and silicates thereof, dielectric metal oxynitrides and silicates thereof, and organic insulating materials. In one embodiment, the first material of the insulating layers 32 may be silicon oxide.

The second material of the sacrificial material layers 42 is a dielectric material, which is a sacrificial material that may be removed selective to the first material of the insulating layers 32. As used herein, a removal of a first material is “selective to” a second material if the removal process removes the first material at a rate that is at least twice the rate of removal of the second material. The ratio of the rate of removal of the first material to the rate of removal of the second material is herein referred to as a “selectivity” of the removal process for the first material with respect to the second material. The second material of the sacrificial material layers 42 may be subsequently replaced with electrically conductive electrodes which may function, for example, as control gate electrodes of a vertical NAND device. In one embodiment, the sacrificial material layers 42 may be material layers that comprise silicon nitride.

Each insulating layer 32 may have a first thickness, which may be in a range from 15 nm to 60 nm, although lesser and greater thicknesses may also be employed. Each sacrificial material layer 42 may have a second thickness, which may be in a range from 15 nm to 60 nm, although lesser and greater thicknesses may also be employed. The total number of repetitions of a pair of an insulating layer 32 and a sacrificial material layer 42 in the alternating stack (32, 42) may be in a range from 16 to 1,024, such as from 64 to 512, although lesser and greater numbers may also be employed. The topmost layer among the insulating layers 32 is herein referred to as a topmost insulating layer 32T.

Generally, an alternating stack (32, 42) of insulating layers 32 and sacrificial material layers 42 can be formed over the substrate 8. The alternating stack (32, 42) comprises a first memory array region 100A, a second memory array region 100B that is laterally spaced from the first memory array region 100A along a first horizontal direction hd1, and an intermediate region 200 that is located between the first memory array region 100A and the second memory array region 100B.

A hard mask layer 38 can be formed over the alternating stack (32, 42). The hard mask layer 38 comprises a material that can be removed selectively to the material of the topmost insulating layer 32T. In one embodiment, the hard mask layer 38 comprises silicon nitride, aluminum oxide or a metallic material, such as titanium nitride. The thickness of the hard mask layer 38 may be in a range from 100 nm to 300 nm, although lesser and greater thicknesses may also be employed.

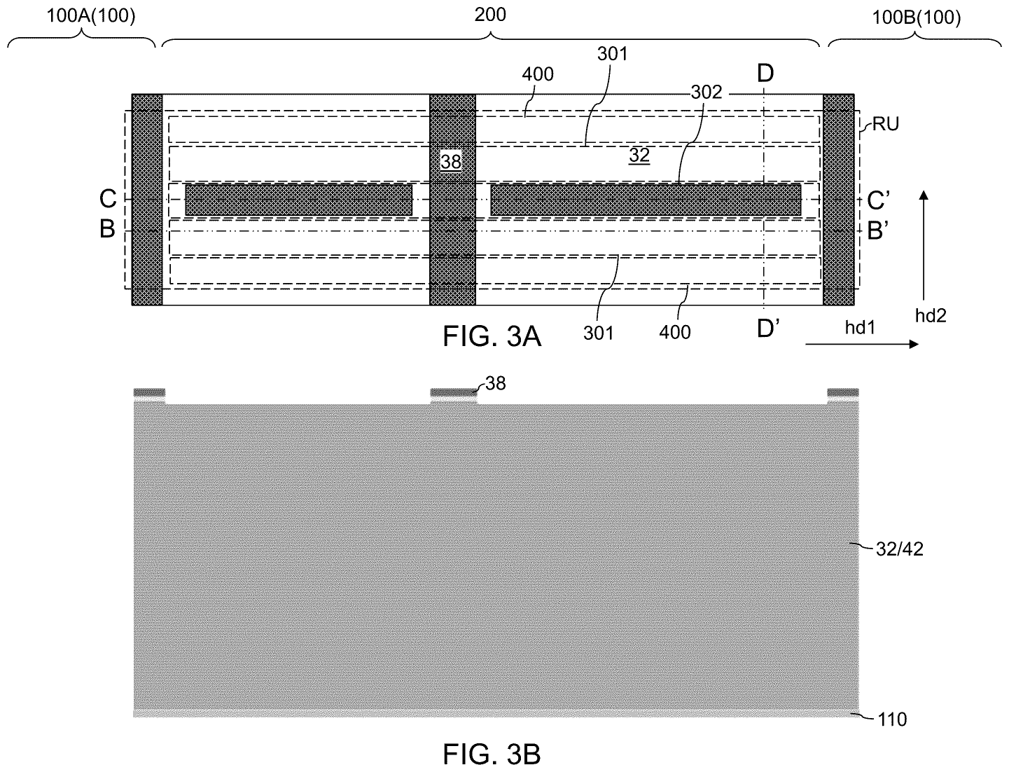

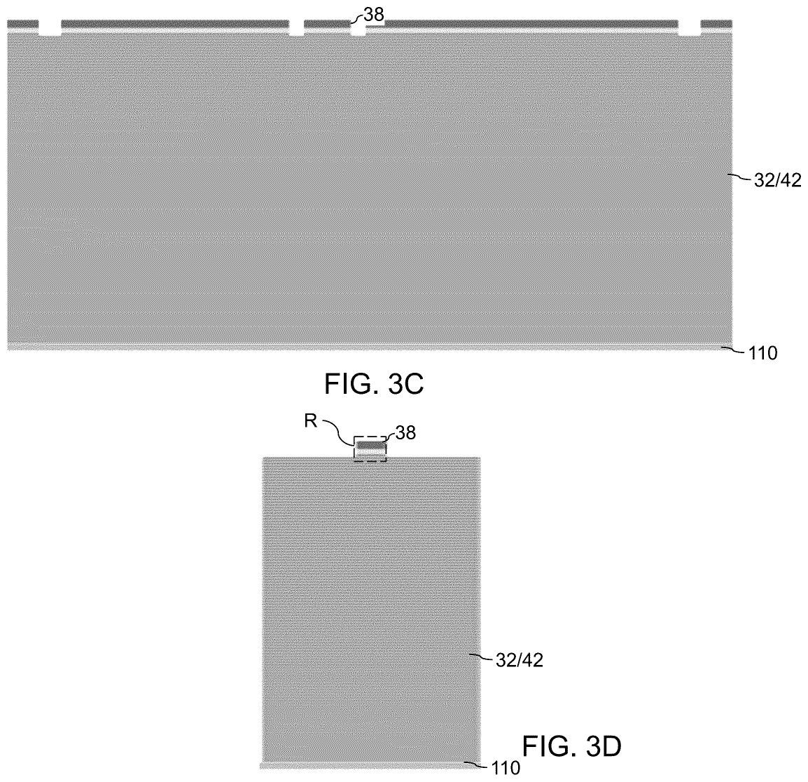

Referring to FIGS. 3A-3D, the hard mask layer 38 can be patterned to cover the first memory array region 100A and the second memory array region 100B and to partially cover the intermediate region 200. According to an aspect of the present disclosure, the pattern of the hard mask layer 38 may have a periodicity along the second horizontal direction hd2. The unit of repetition for the pattern of the hard mask layer 38 is herein referred to as a repetition unit RU. Each repetition unit RU may have a rectangular area, and includes a portion of the first memory array region 100A, a portion of the second memory array region 100B, and a portion of the intermediate region 200. The portion of the intermediate region 200 within each repetition unit RU may comprise, from one side to another along the second horizontal direction hd2, a connection region 400, a first (“edge”) staircase region 301, a second (i.e., “middle”) staircase region 302, an additional first (“edge”) staircase region 301, and an additional connection region 400. The second (i.e., “middle”) staircase region 302 is located between the pair of first (“edge”) staircase regions 301 along the second horizontal direction (e.g., bit line direction) hd2. The second staircase region 302 is mostly covered with patterned portions of the hard mask layer 38. Another patterned portion of the hard mask layer 38 may laterally extend through the intermediate region 200 along the second horizontal direction hd2.

An anisotropic etch process can be performed to transfer the pattern in the hard mask layer 38 through at least one pair of an insulating layer 32 and a sacrificial material layer 42. Ridges “R” are formed underneath the hard mask layer 38 in the portion of the alternating stack (32, 42) that is located in the second staircase region 302. The height differential across each ridge R may be an integer K times the sum of a thickness of an insulating layer 32 and a thickness of a sacrificial material layer 42. The integer K may be in a range from 1 to 10, although a greater number may also be employed. In other words, the ridge R may include 1 to 10 pairs of an insulating layer 32 and a sacrificial material layer 42.

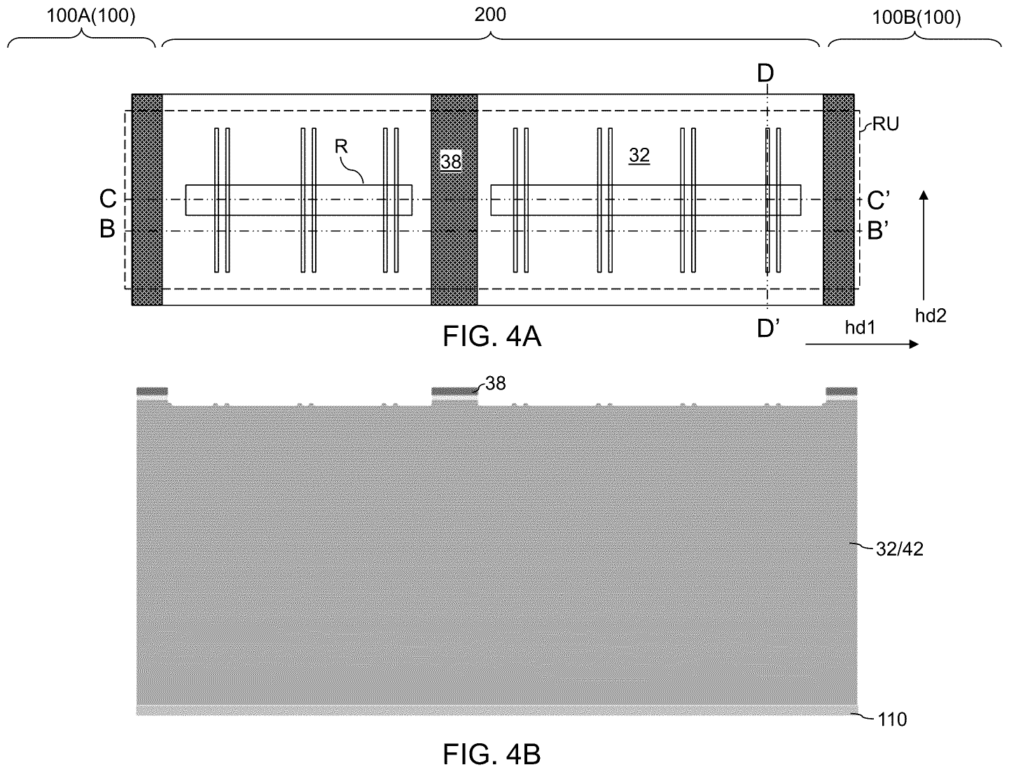

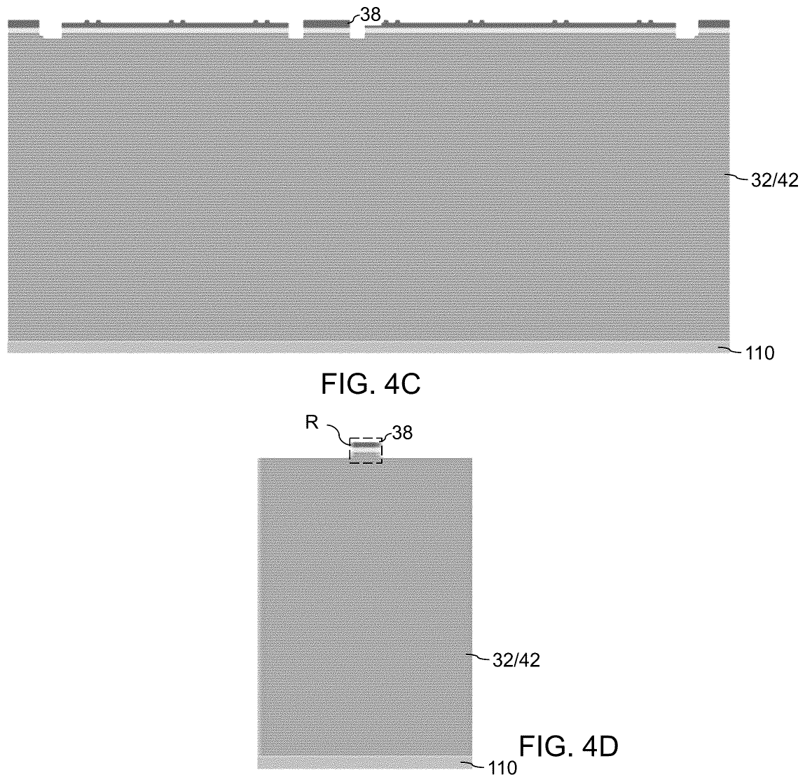

Referring to FIGS. 4A-4D, portions of the hard mask layer 38 that overlie the ridges R can be removed selectively to the alternating stack (32, 42). A photoresist layer (not shown) can be applied over the first exemplary structure, and can be lithographically patterned into strip patterns that laterally extend along the second horizontal direction hd2 in the intermediate region 200. An anisotropic etch process can be performed to transfer the pattern in the photoresist layer into the alternating stack (32, 42) in the intermediate region 200. Scale patterns are formed in the intermediate region 200. The scale patterns may comprise pairs of strip patterns that laterally extend along the second horizontal direction hd2.

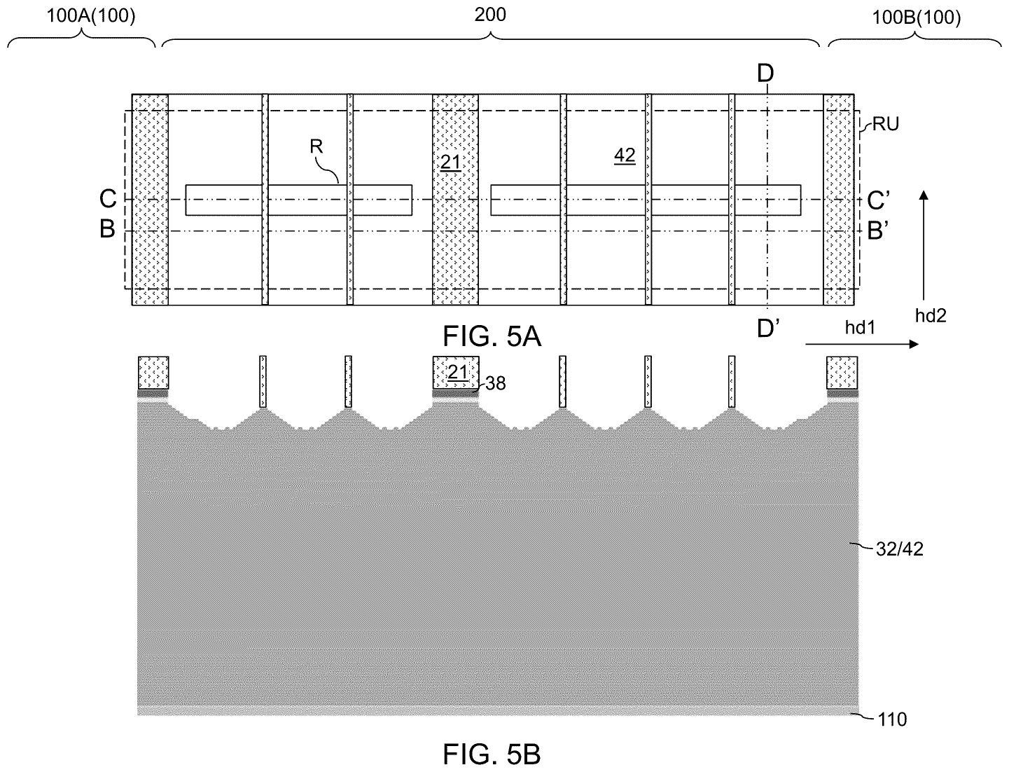

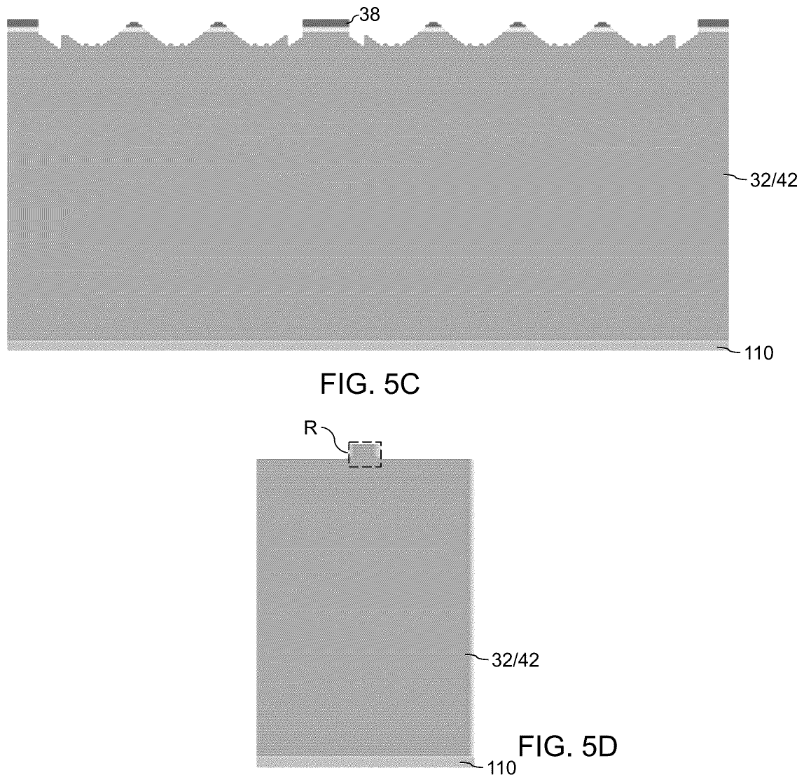

Referring to FIGS. 5A-5D, a patterned trimmable etch mask layer can be formed over the alternating stack (32, 42). The patterned trimmable etch mask layer comprises a photoresist material that can be isotropically recessed by slow ashing. The patterned trimmable etch mask layer can be lithographically patterned into trimmable etch mask patterns 21. A sequence of processing steps including an anisotropic etch process and a trimming process can be repeatedly performed to form stepped surfaces in the intermediate region 200. Each anisotropic etch process can etch unmasked portions of an underlying pair of an insulating layer 32 and a sacrificial material layer 42. Each trimming process can trim the trimmable etch mask patterns 21. The duration of each trimming process can determine the length of each horizontal step of the stepped surfaces that are formed by the sequences of the processing steps. The total number L of iterations of the sequence of processing steps may be in a range from 6 to 12, although lesser and greater numbers of iterations may also be employed. The scale patterns may be employed as reference structures for measuring the lateral dimensions of the horizontal steps of the stepped surfaces. The height differential at the vertical steps that are formed by the sequences of the processing steps can be the same as the sum of the thickness of an insulating layer 32 and the thickness of a sacrificial material layer 42. The trimmable etch mask patterns 21 can be subsequently removed, for example, by ashing.

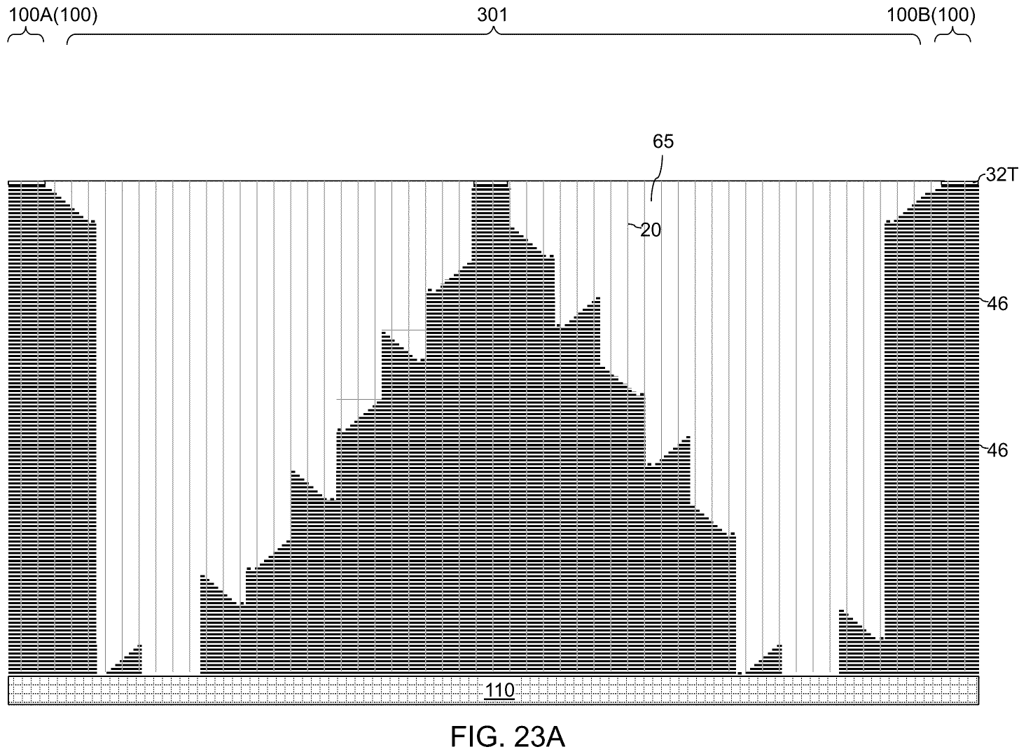

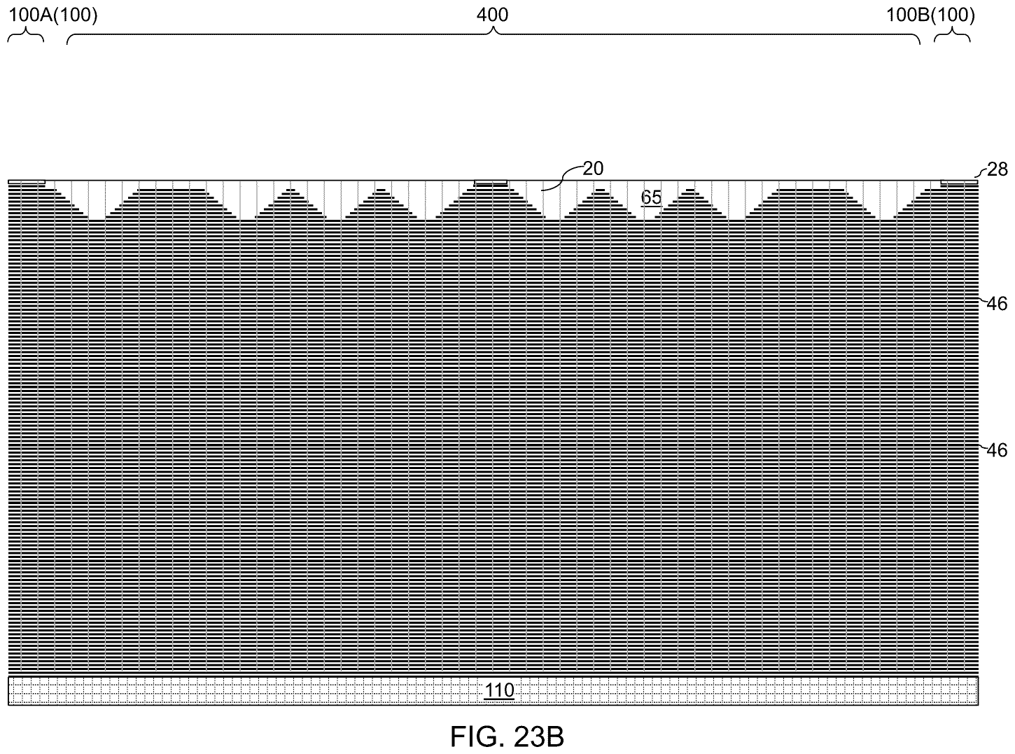

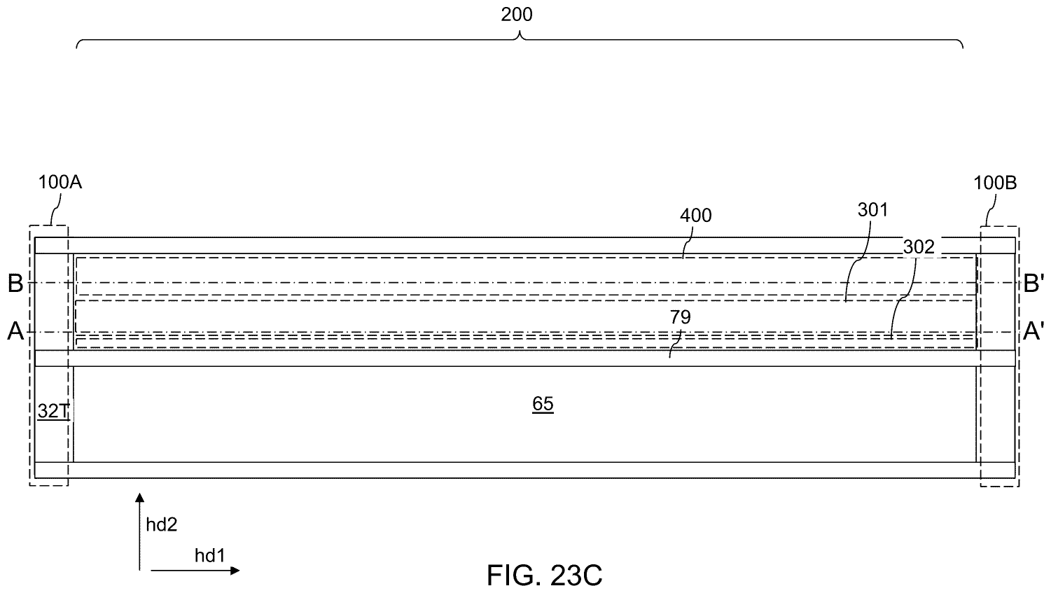

At least a majority of the sacrificial material layers 42 extend continuously from the first memory array region 100A to the second memory array region 100B through the intermediate (e.g., contact) region 200 in one or both of the first and second connection regions 400. For example, all sacrificial material layers 42, or at least 80 percent, such as at least 90 percent of the sacrificial material layers 42 counted from the bottom of the alternating stack (32, 42) extend continuously from the first memory array region 100A to the second memory array region 100B through the intermediate region 200 in one or both of the first and second connection regions 400. In one embodiment, at least one topmost sacrificial material layer 42 does not extend continuously from the first memory array region 100A to the second memory array region 100B through the intermediate region 200 in one or both of the first and second connection regions 400. In this case, after the sacrificial material layers 42 are replaced with electrically conductive layers (as shown in FIGS. 23A-23C and described below), the portions of each of the topmost electrically conductive layers which do not extend continuously from the first memory array region 100A to the second memory array region 100B through the intermediate region 200 may be electrically connected to each other by overlying electrically conductive interconnects which are formed after the electrically conductive layers. The intermediate region 200 also includes a first staircase region 301 in which first horizontally-extending surface segments (i.e., first horizontal steps) of the alternating stack (32, 42) are arranged along the first horizontal direction hd1 and are interconnected to each other by first vertically-extending surface segments (i.e., first vertical steps), and a second staircase region 302 in which second horizontally-extending surface segments (i.e., second horizontal steps) of the alternating stack (32, 42) are arranged along the first horizontal direction hd1 and are interconnected to each other by second vertically-extending surface segments (i.e., second vertical steps). The second staircase region 302 includes the areas of the ridges R. Thus, each of the second horizontally-extending surface segments (i.e., second horizontal step) can be vertically offset upward relative to a respective neighboring one of the first horizontally-extending surface segments (i.e., first horizontal step) by a respective offset vertical step. The height of the respective offset vertical step can be the same as the height of each ridge R, which can be an integer K times the sum of a thickness of an insulating layer 32 and a thickness of a sacrificial material layer 42. The integer K may be in a range from 1 to 10, although a greater number may also be employed. In one embodiment, all of the offset vertical steps have a same height. In one embodiment, the insulating layers 32 have a first thickness, and the sacrificial material layers 42 have a second thickness, and the same height is an integer multiple of the sum of the first thickness and the second thickness.

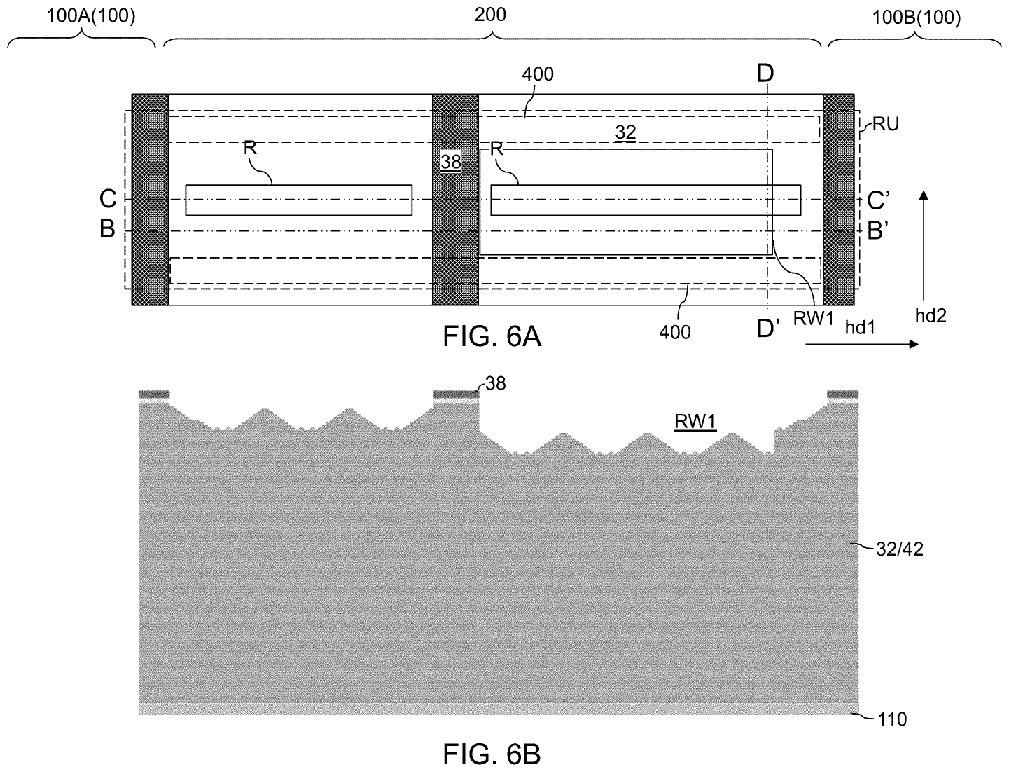

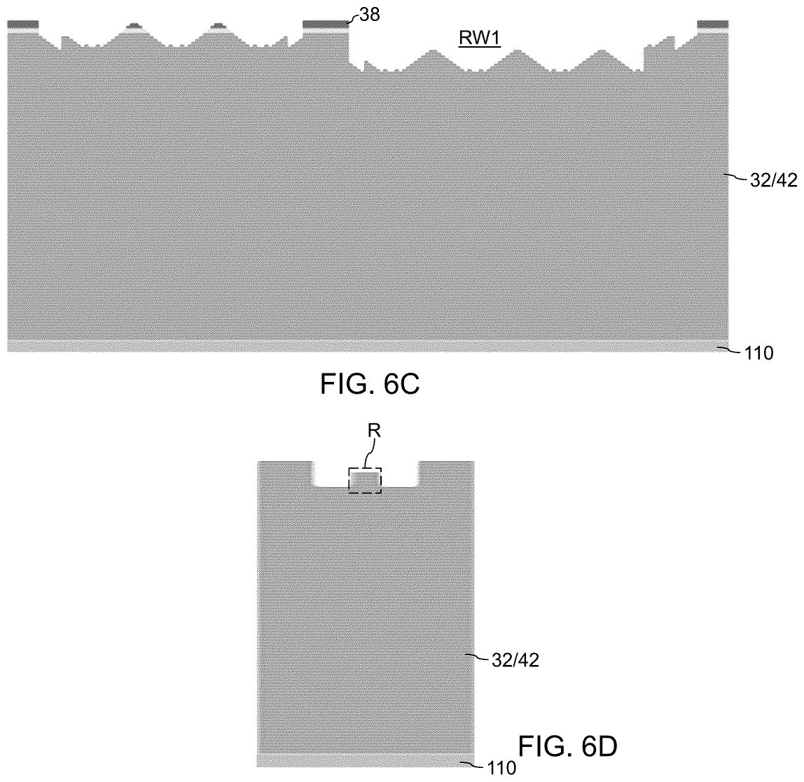

Referring to FIGS. 6A-6D, a first photoresist layer (not shown) can be applied over the first exemplary structure, and can be lithographically patterned to form at least one rectangular opening in the intermediate region 200 within the area of each repetition unit RU. The area of each rectangular opening may be entirely outside the areas of the connection regions 400. A first anisotropic etch process can be performed to vertically recess portions of the stepped surfaces that are located within the openings in the photoresist layer. At least one first recess well RW1 can be formed. The depth by which the regions of the at least one first recess well RW1 are vertically recessed may be an integer multiple of the a unit well recess depth, which may equal, or may be about, L times the sum of the thickness of an insulating layer 32 and a sacrificial material layer 42. The integer L is the total number of iterations of the sequence of processing steps that are performed at the processing steps described with reference to FIGS. 5A-5D. The first photoresist layer can be subsequently removed, for example, by ashing.

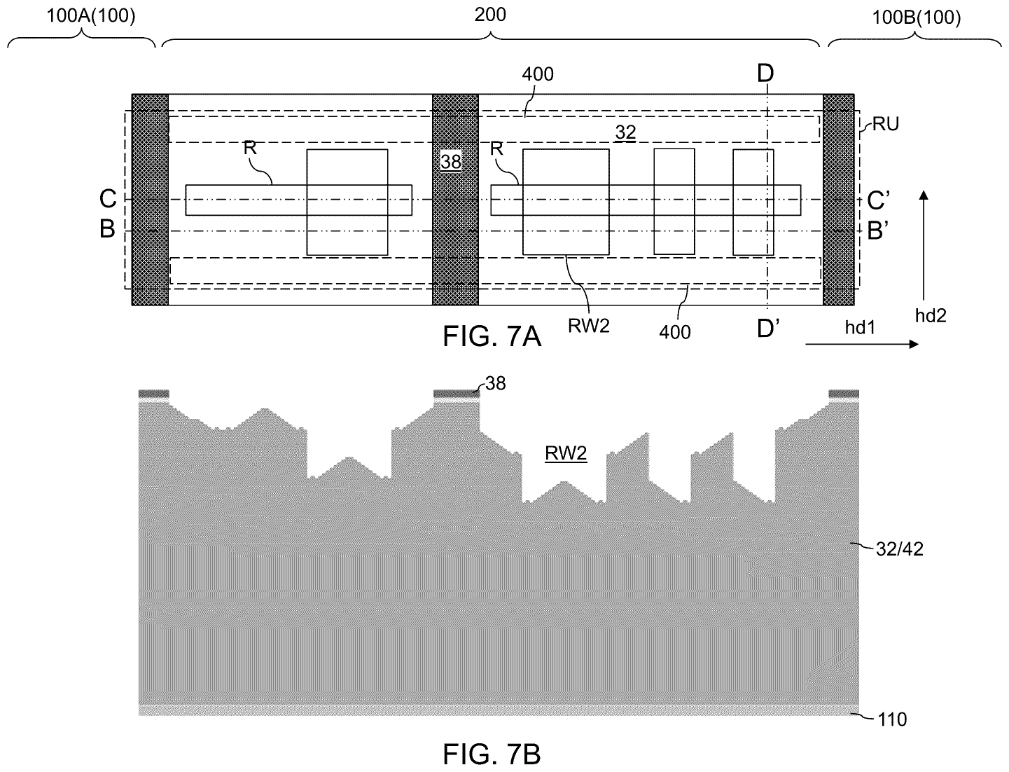

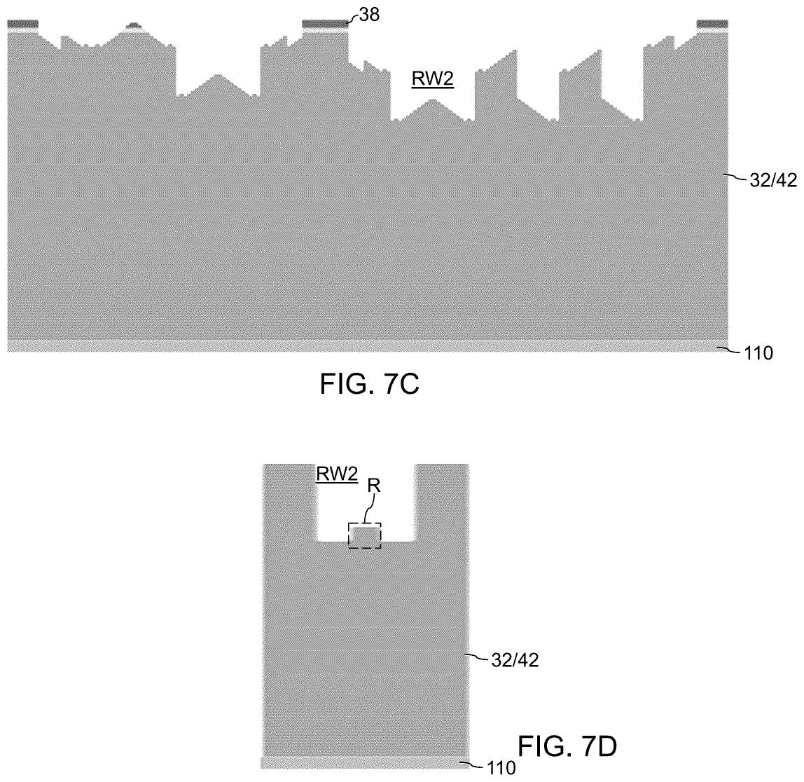

Referring to FIGS. 7A-7D, a second photoresist layer (not shown) can be applied over the first exemplary structure, and can be lithographically patterned to form at least one rectangular opening in the intermediate region 200 within the area of each repetition unit RU. The area of each rectangular opening may be entirely outside the areas of the connection regions 400. A second anisotropic etch process can be performed to vertically recess portions of the stepped surfaces that are located within the openings in the photoresist layer. At least one second recess well RW2 can be formed. Generally, the areas of the at least one second recess well RW2 may partially overlap with the areas of the at least one first recess well RW1. The depth by which the regions of the at least one second recess well RW2 are vertically recessed may be an integer multiple of the unit well recess depth. The integer multiple for the second anisotropic etch process may be different from the integer multiple for the first anisotropic etch process. The second photoresist layer can be subsequently removed, for example, by ashing.

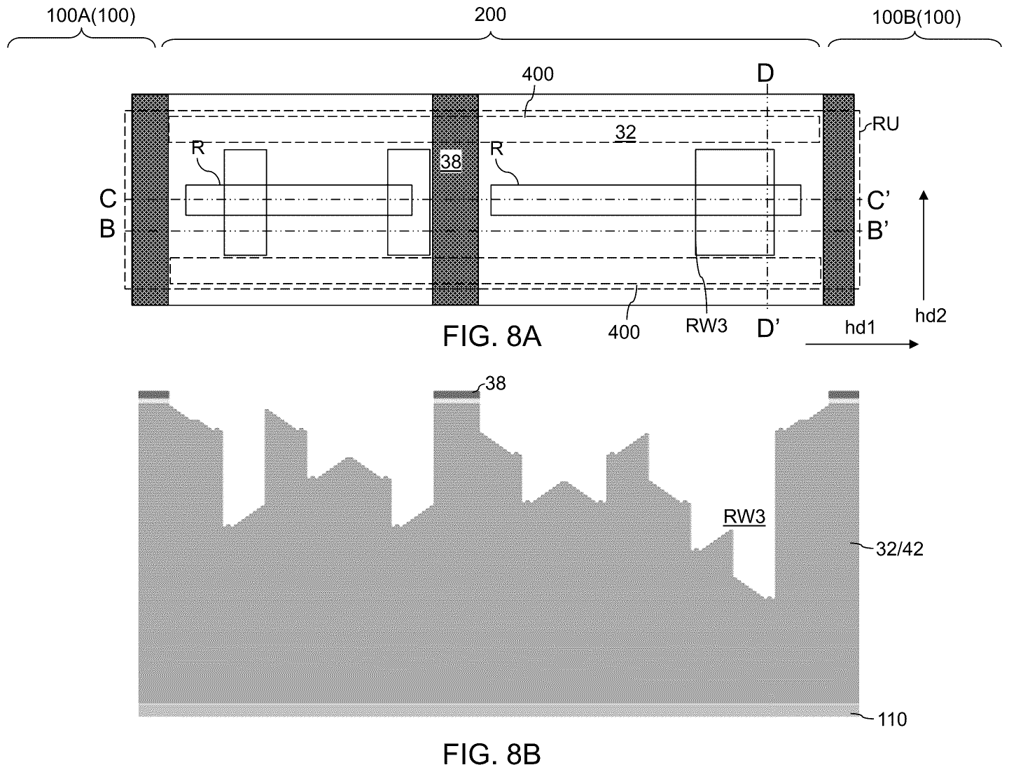

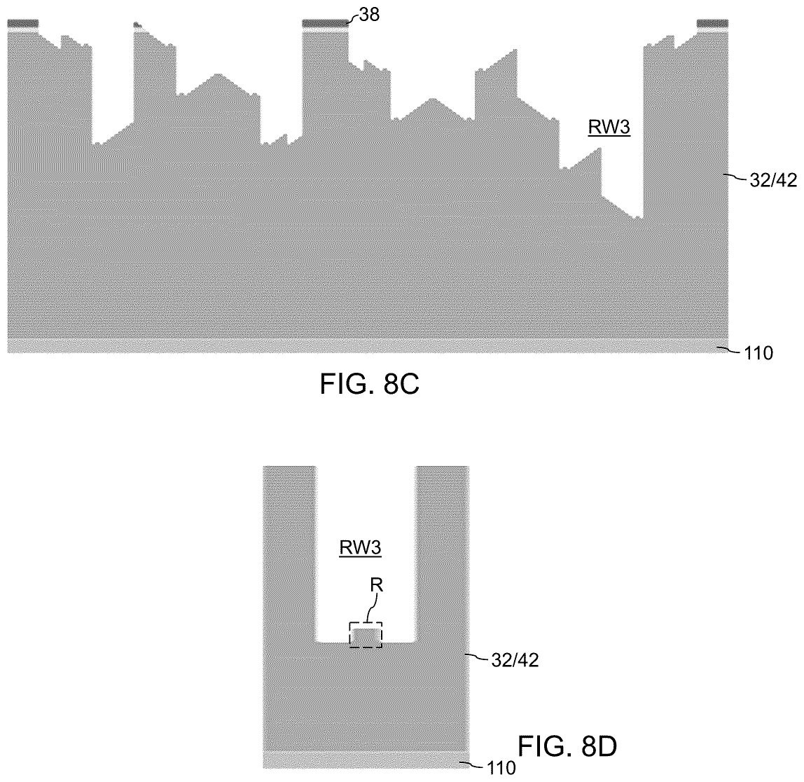

Referring to FIGS. 8A-8D, a third photoresist layer (not shown) can be applied over the first exemplary structure, and can be lithographically patterned to form at least one rectangular opening in the intermediate region 200 within the area of each repetition unit RU. The area of each rectangular opening may be entirely outside the areas of the connection regions 400. A third anisotropic etch process can be performed to vertically recess portions of the stepped surfaces that are located within the openings in the photoresist layer. At least one third recess well RW3 can be formed. Generally, the areas of the at least one third recess well RW3 may partially overlap with the areas of the at least one second recess well RW2. The depth by which the regions of the at least one third recess well RW3 are vertically recessed may be an integer multiple of the unit well recess depth. The integer multiple for the third anisotropic etch process may be different from the integer multiple for the first anisotropic etch process. The third photoresist layer can be subsequently removed, for example, by ashing.

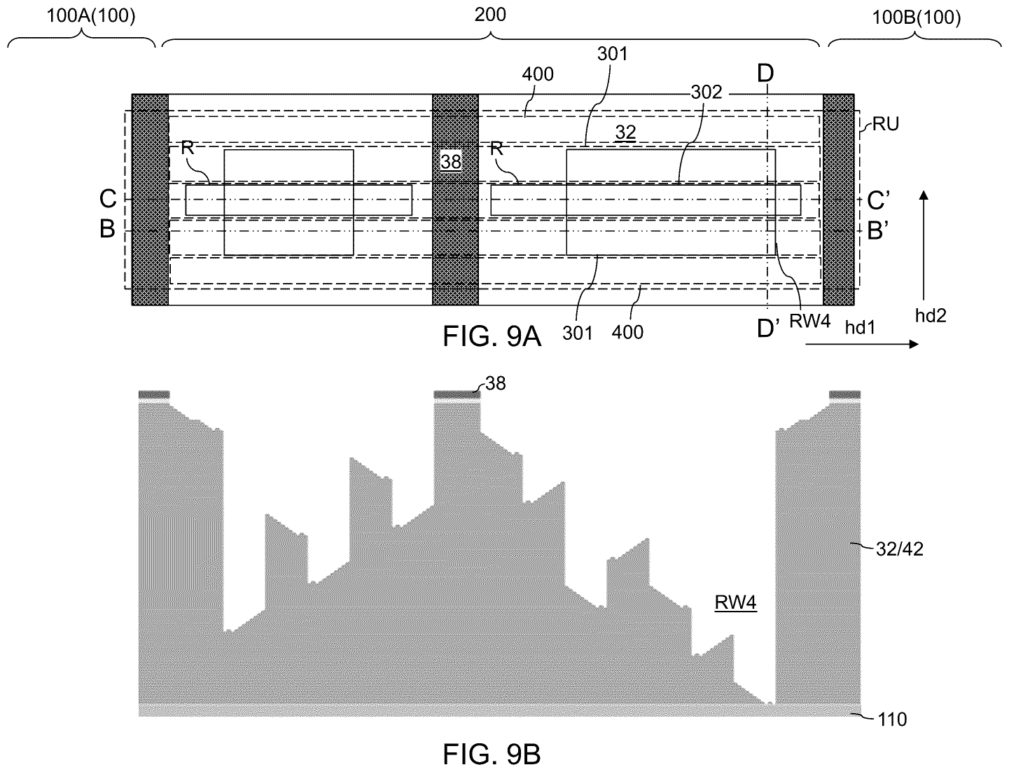

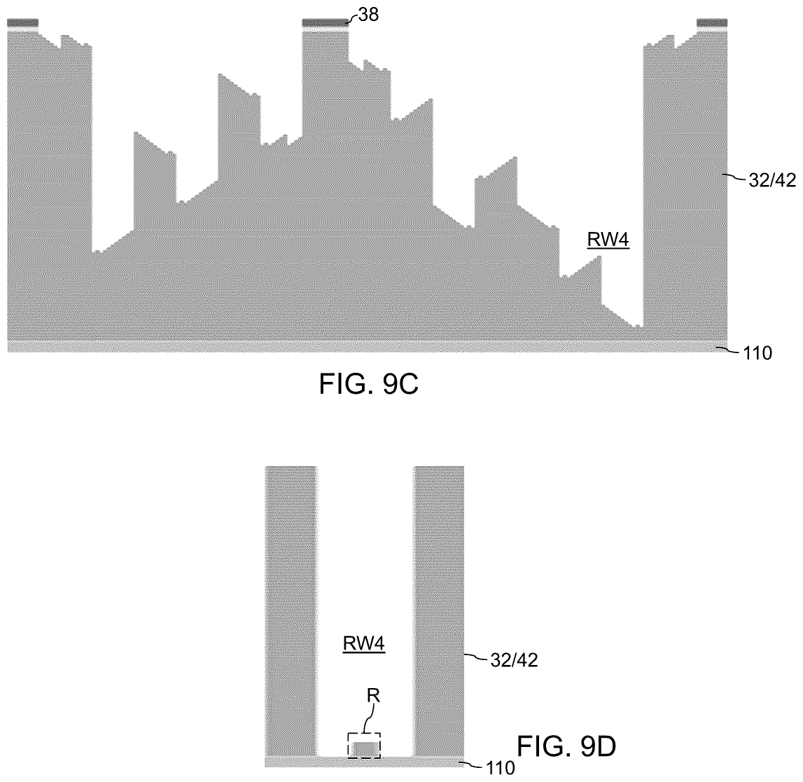

Referring to FIGS. 9A-9D, a fourth photoresist layer (not shown) can be applied over the first exemplary structure, and can be lithographically patterned to form at least one rectangular opening in the intermediate region 200 within the area of each repetition unit RU. The area of each rectangular opening may be entirely outside the areas of the connection regions 400. A fourth anisotropic etch process can be performed to vertically recess portions of the stepped surfaces that are located within the openings in the photoresist layer. At least one fourth recess well RW4 can be formed. Generally, the areas of the at least one fourth recess well RW4 may partially overlap with the areas of the at least one third recess well RW3. The depth by which the regions of the at least one fourth recess well RW4 are vertically recessed may be an integer multiple of the unit well recess depth. The integer multiple for the fourth anisotropic etch process may be different from the integer multiple for the first anisotropic etch process. The fourth photoresist layer can be subsequently removed, for example, by ashing.

An alternating stack (32, 42) of insulating layers 32 and sacrificial material layers 42 is provided. Each layer within the alternating stack (32, 42) is present in a first memory array region 100A and in a second memory array region 100B that are laterally spaced from each other along a first horizontal direction (e.g., word line direction) hd1. The intermediate region 200 comprises a connection region 400 in which at least the majority of the sacrificial material layers 42 continuously extend between the first memory array region 100A and the second memory array region 100B, a first staircase region 301 in which first horizontally-extending surface segments of the alternating stack (32, 42) are arranged along the first horizontal direction hd1 and are interconnected to each other by first vertically-extending surface segments, and a second staircase region 302 in which second horizontally-extending surface segments of the alternating stack (32, 42) are arranged along the first horizontal direction hd1 and are interconnected to each other by second vertically-extending surface segments. The second staircase region 302 includes the areas of the ridges R. Thus, each of the second horizontally-extending surface segments can be vertically offset upward relative to a respective neighboring one of the first horizontally-extending surface segments by a respective offset vertical step. The height of the respective offset vertical step can be the same as the height of each ridge, which can be an integer K times the sum of a thickness of an insulating layer 32 and a thickness of a sacrificial material layer 42. The integer K may be in a range from 1 to 10, although a greater number may also be employed. In one embodiment, all of the offset vertical steps have a same height. In one embodiment, the insulating layers 32 have a first thickness, and the sacrificial material layers 42 have a second thickness, and the same height is an integer multiple of the sum of the first thickness and the second thickness.

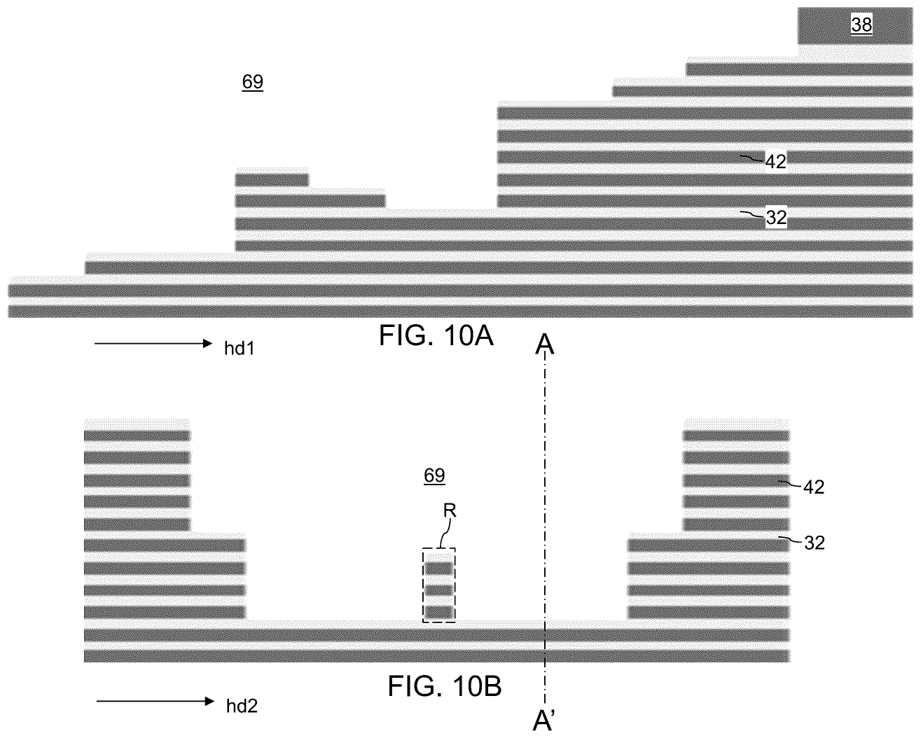

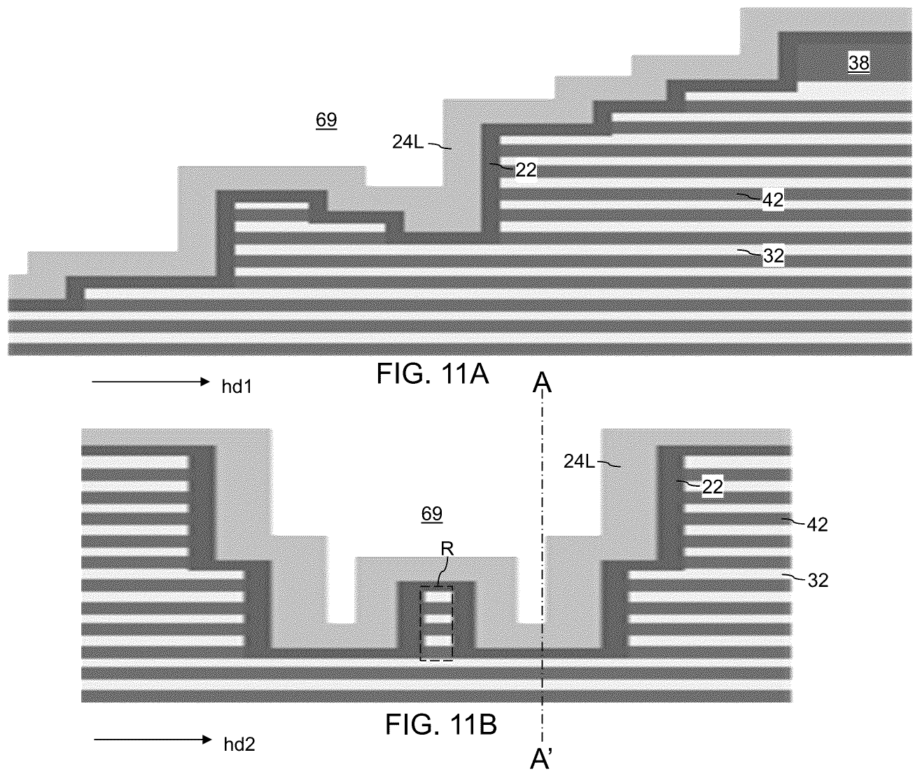

Referring to FIGS. 10A and 10B, additional vertical cross-sectional views of the first exemplary structure are illustrated after the processing steps described with reference to FIGS. 9A-9D. Generally, a retro-stepped cavity 69 can be formed within each repetition unit RU within the area of the intermediate region 200. Each retro-stepped cavity 69 has a respective stepped bottom surface.

Referring to FIGS. 11A and 11B, a conformal silicon oxide liner 22 and a dielectric etch-stop material layer 24L can be deposited over the physically exposed surfaces of the first exemplary structure. The conformal silicon oxide liner 22 comprises and/or consists essentially of, silicon oxide and may have a thickness in a range from 15 nm to 60 nm, such as from 20 nm to 40 nm, although lesser and greater thicknesses may also be employed. The conformal silicon oxide liner 22 may be formed directly on each of the first horizontally-extending surface segments and the first vertically-extending surface segments of the first staircase regions 301, and on the second horizontally-extending surface segments and the second vertically-extending surface segments of the second staircase region 302.

The dielectric etch-stop material layer 24L can be formed over the first horizontally-extending surface segments, the second horizontally-extending surface segments, and vertical steps of the alternating stack (32, 42). In one embodiment, the dielectric etch-stop material layer 24L can be formed directly on physically exposed surfaces of the conformal silicon oxide liner 22. In one embodiment, the dielectric etch-stop material layer 24L may comprise and/or may consist essentially of the same material as the material of the sacrificial material layers 42. In one embodiment, the dielectric etch-stop material layer 24L and the sacrificial material layers 42 may comprise and/or may consist essentially of silicon nitride. The thickness of the dielectric etch-stop material layer 24L may be greater than the sum of the thickness of an insulating layer 32 and the thickness of a sacrificial material layer 42. In one embodiment, the thickness of the dielectric etch-stop material layer 24L may be in a range from 30 nm to 180 nm, such as from 60 nm to 120 nm, although lesser and greater thicknesses may also be employed.

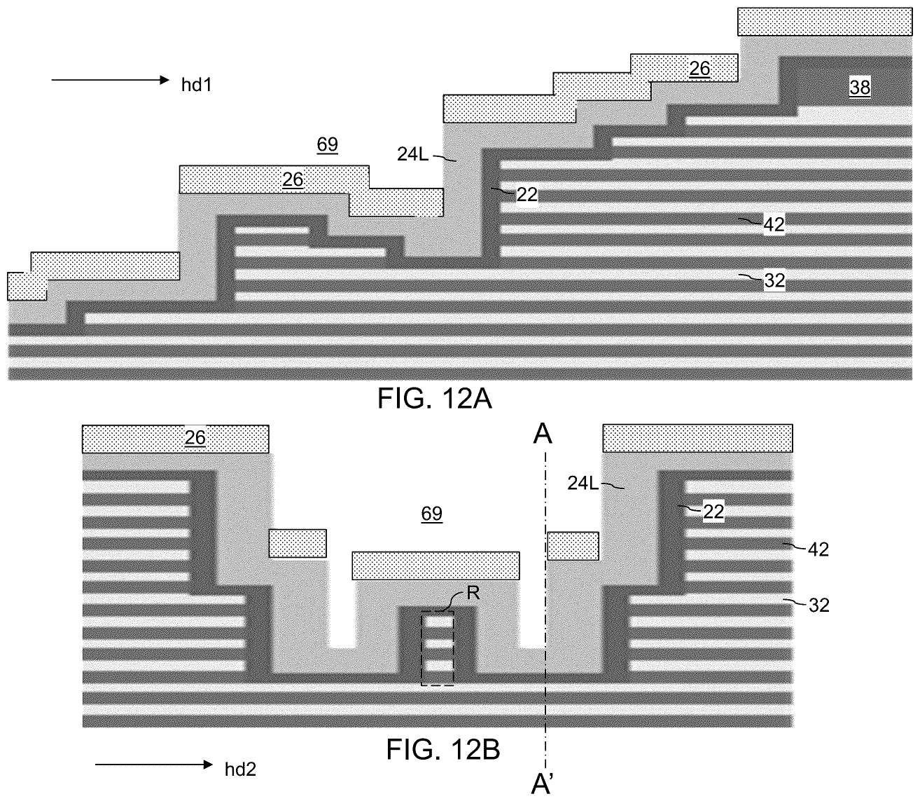

Referring to FIGS. 12A and 12B, a cover material layer 26 can be deposited. For example, the cover material layer 26 may comprise a carbon based organic material, such as a fluorocarbon material. The cover material layer 26 is then cured by applying heat to the cover material layer 26. The vertical portions of the cover material layer 26 have a lower density than the horizontal portions of the coverage material layer 26 after the curing step. The vertical portions of the cover material layer 26 are then selectively removed by trimming (e.g., etching process) to leave the horizontal portions of the cover material layer 26 on the horizontally-extending surfaces of the dielectric etch-stop material layer 24L, as shown in FIGS. 12A and 12B. Vertically-extending surfaces of the dielectric etch-stop material layer 24L can be physically exposed.

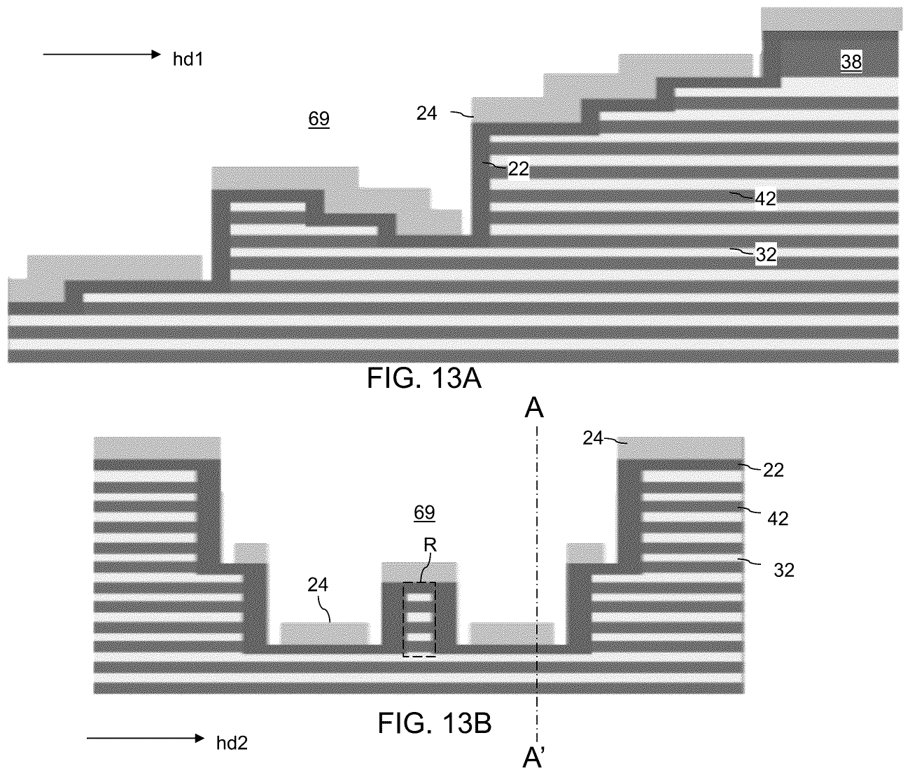

Referring to FIGS. 13A and 13B, a selective isotropic etch process can be performed to etch portions of the dielectric etch-stop material layer 24L selective to the materials of the conformal silicon oxide liner 22 and the cover material layer 26. For example, if the dielectric etch-stop material layer 24L comprises silicon nitride, a wet etch process employing hot phosphoric acid may be used to remove the exposed (i.e., uncovered) vertically-extending portions of the dielectric etch-stop material layer 24L. The remaining horizontally-extending portions of the dielectric etch-stop material layer 24L comprise dielectric etch-stop plates 24.

Remaining portions of the dielectric etch-stop material layer 24L comprise the first dielectric etch-stop plates 24 that are formed in the first staircase regions 301 and the second dielectric etch-stop plates 24 that are formed in the second staircase regions 302. A row of first dielectric etch-stop plates 24 can be formed over the first horizontally-extending surface segments of the alternating stack (32, 42) in each first staircase region 301. A row of second dielectric etch-stop plates 24 can be formed over the second horizontally-extending surface segments of the alternating stack (32, 42) in each staircase region 302. The first dielectric etch-stop plates 24 and the second dielectric etch-stop plates 24 can be formed directly on top surfaces of the conformal silicon oxide liner 22.

In one embodiment, each of the sacrificial material layers 42 may have a first thickness, and each of the dielectric etch-stop plates 24 may have a second thickness that is at least 1.5 times the first thickness, such as at least twice the first thickness. In one embodiment, each of the dielectric etch-stop plates 24 may have a lesser length along the first horizontal direction hd1 than a respective underlying horizontally-extending surface segment of the alternating stack (32, 42), and may have a lesser width along the second horizontal direction hd2 than the respective underlying horizontally-extending surface segment of the alternating stack (32, 42).

The cover material layer 26 can then be removed selective to the dielectric etch-stop plates 24 and the conformal silicon oxide liner 22. If the cover material layer 26 comprises a carbon based material, then an ashing process may be performed to remove the cover material layer 26.

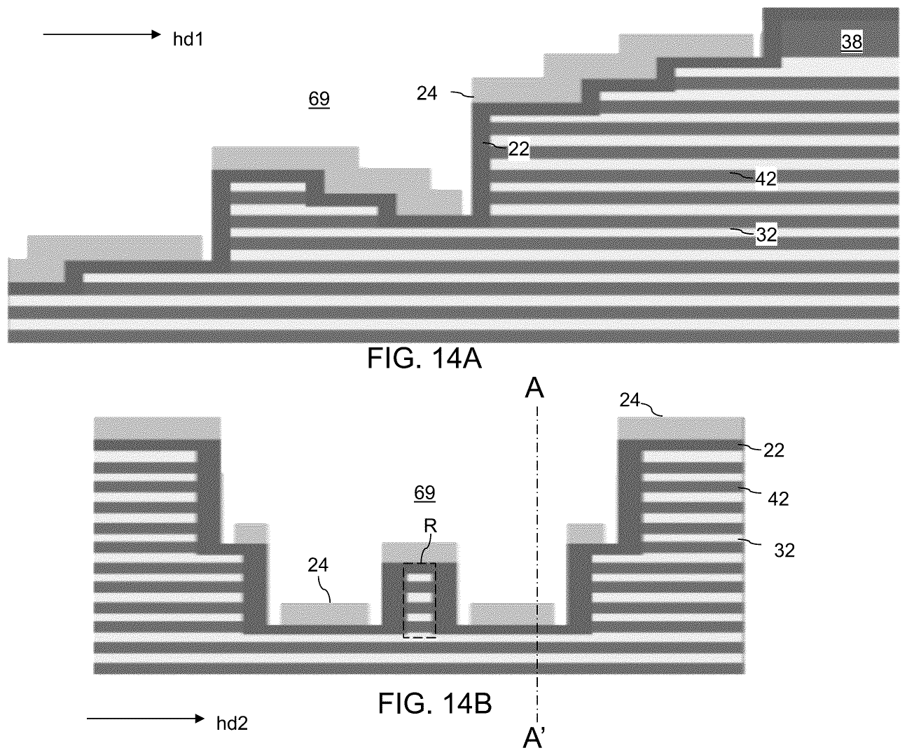

Referring to FIGS. 14A and 14B, the dielectric etch-stop plates 24 may be removed from above the remaining portions of the hard mask layer 38. For example, a photoresist layer (not shown) may be formed over the device, and patterned to expose the dielectric etch-stop plates 24 located above the remaining portions of the hard mask layer 38. The exposed dielectric etch-stop plates 24 are then removed from above the remaining portions of the hard mask layer 38 by reactive ion etching. The patterned photoresist layer may be removed by ashing.

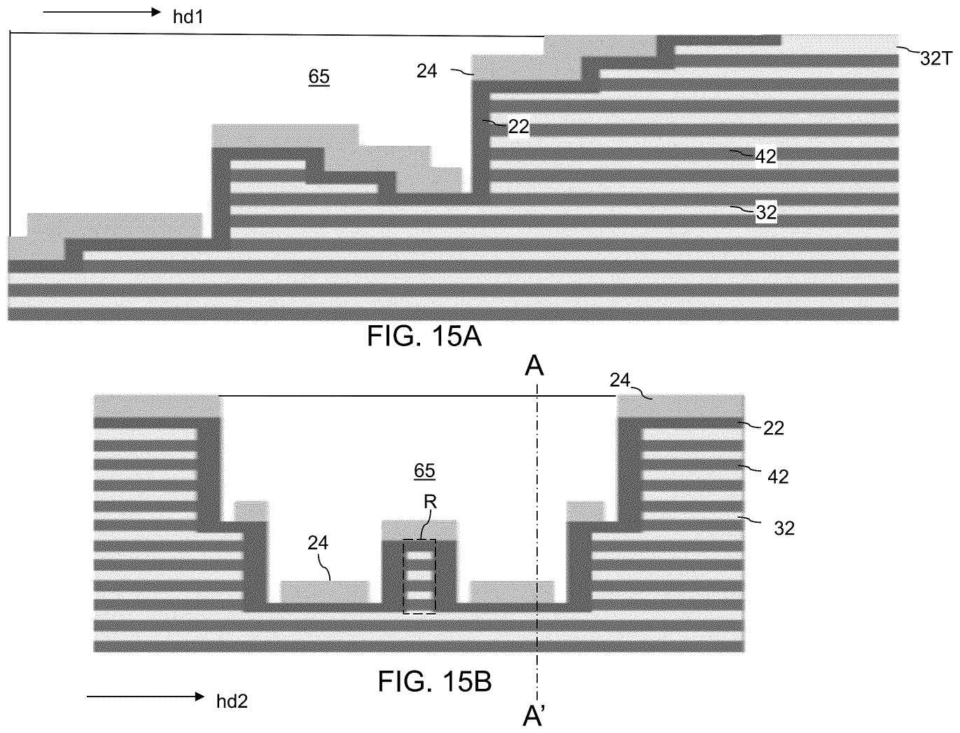

Referring to FIGS. 15A and 15B, a dielectric fill material, such as silicon oxide, can be deposited in remaining volumes of the retro-stepped cavities 69. Excess portions of the dielectric fill material may be removed from above the horizontal plane including the top surface of the hard mask layer 38 by chemical mechanical polishing. The hard mask layer 38 may act as a polish stop. Remaining portions of the dielectric fill material and the hard mask layer 38 can be vertically recessed such that the top surfaces of the remaining portions of the dielectric fill material are coplanar with the top surface of the topmost insulating layer 32T and the remaining portions of the hard mask layer 38 are removed. Each remaining portion of the dielectric fill material constitutes a retro-stepped dielectric material portion 65. Each retro-stepped dielectric material portion 65 overlies two first staircase regions 301 and a second staircase region 302, and contacts tapered sidewalls of portions of the alternating stack (32, 42) in the connection regions 400. The tapered sidewalls laterally extend along the first horizontal direction hd1. In one embodiment, each retro-stepped dielectric material portion 65 can be formed over two rows of the first dielectric etch-stop plates 24 and a row of the second dielectric etch-stop plates 24.

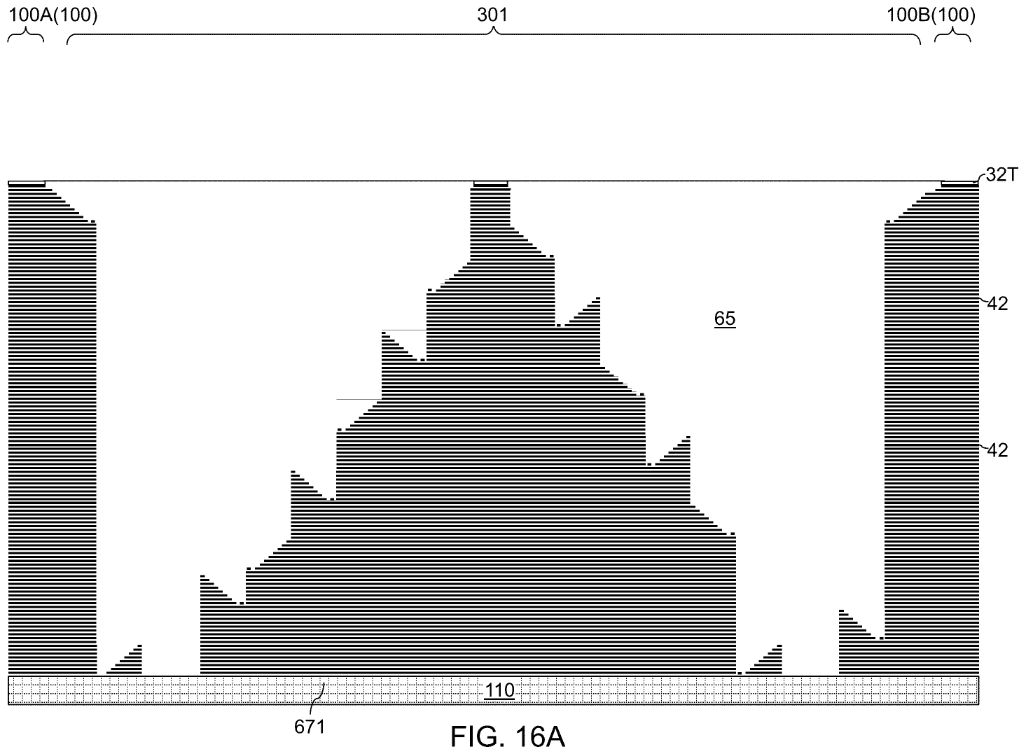

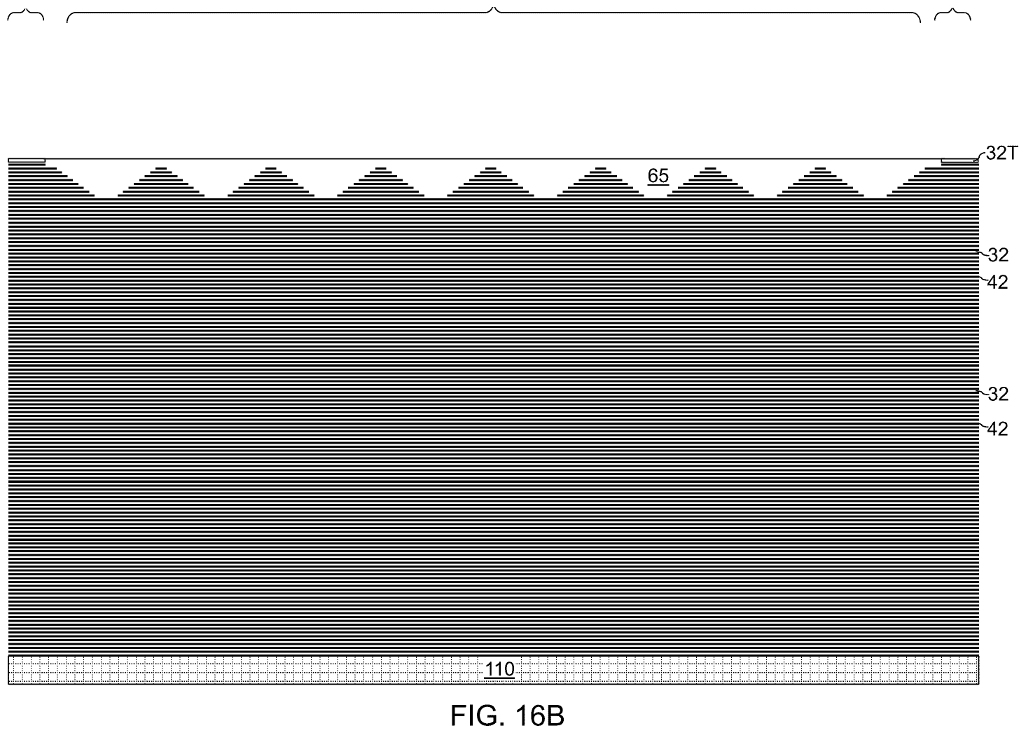

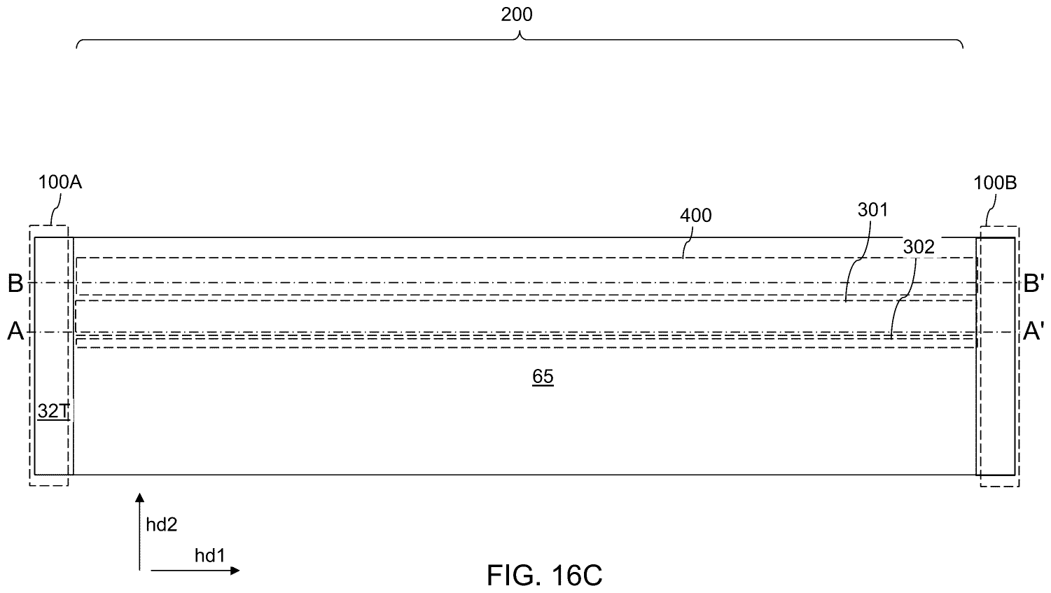

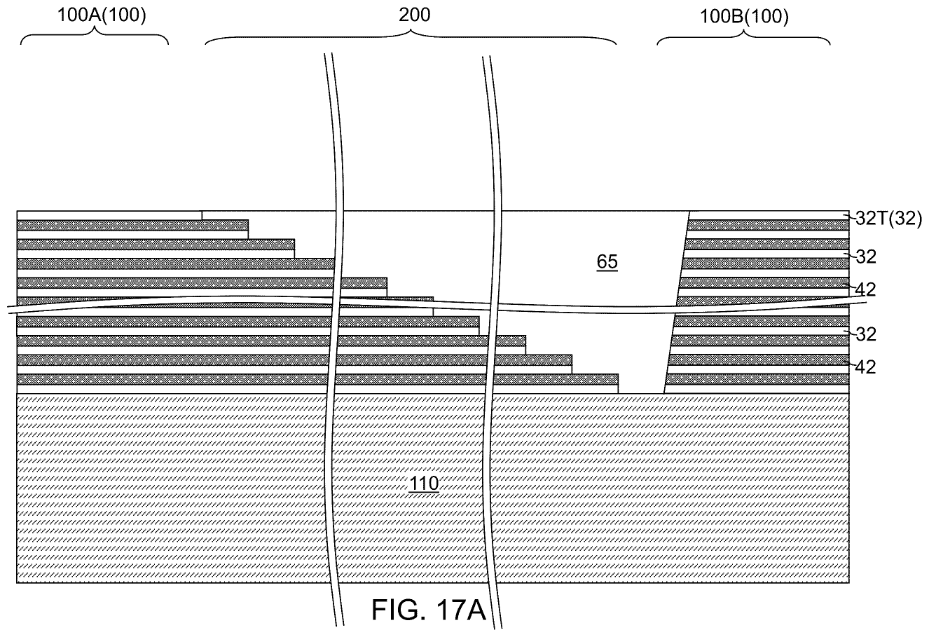

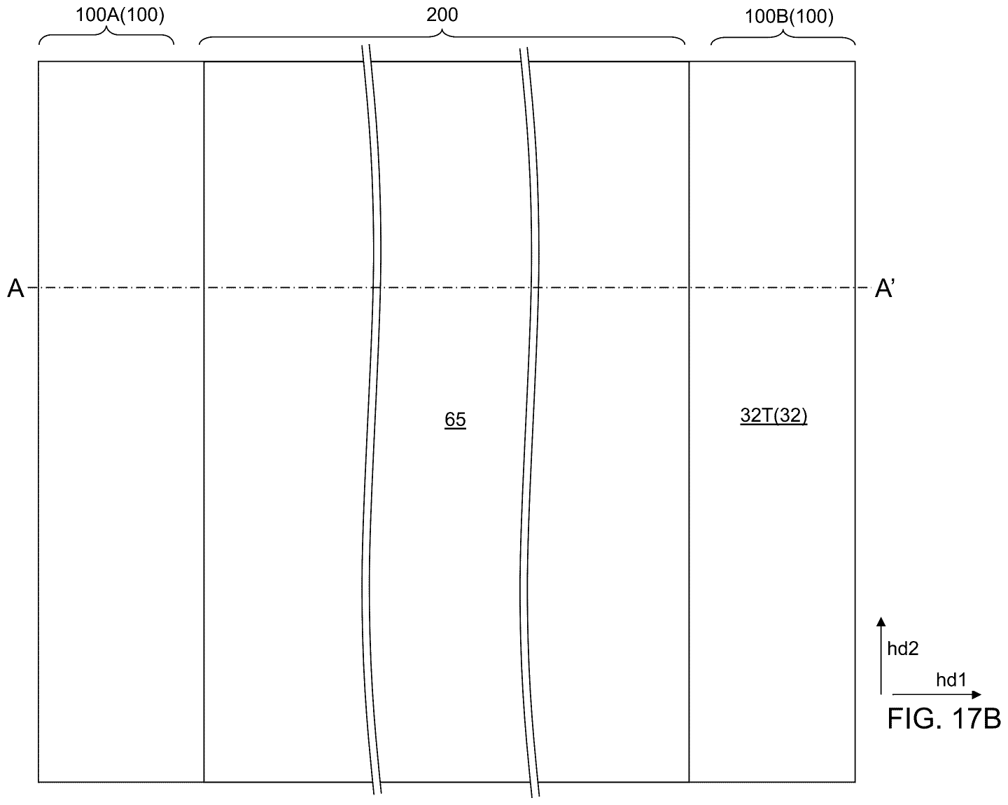

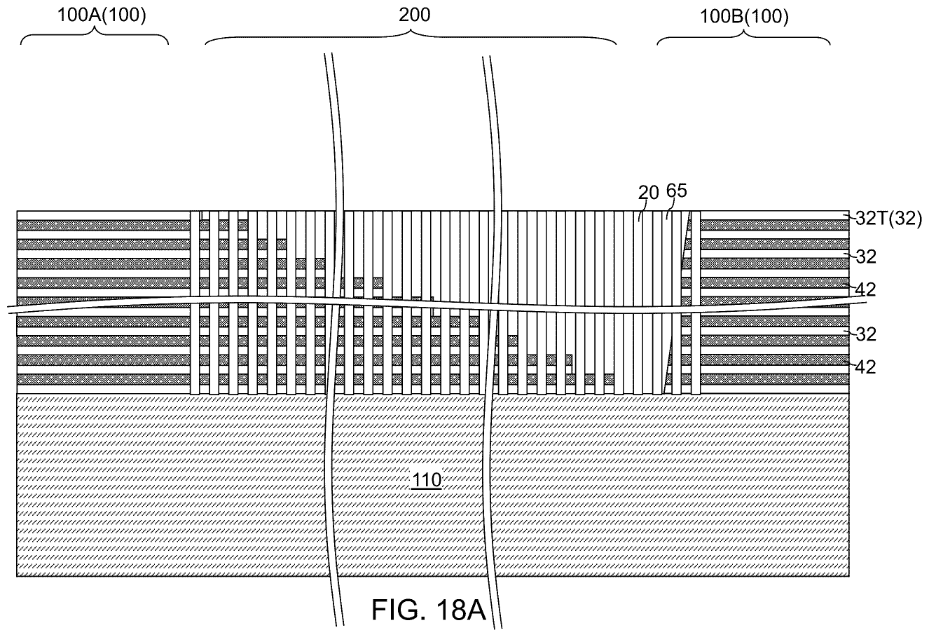

FIGS. 16A-16C are various views of a region of the first exemplary structure after formation of the retro-stepped dielectric material portion 65. FIGS. 17A and 17B are additional views of a region of the first exemplary structure at the processing steps of FIGS. 15A, 15B, and 16A-16C.

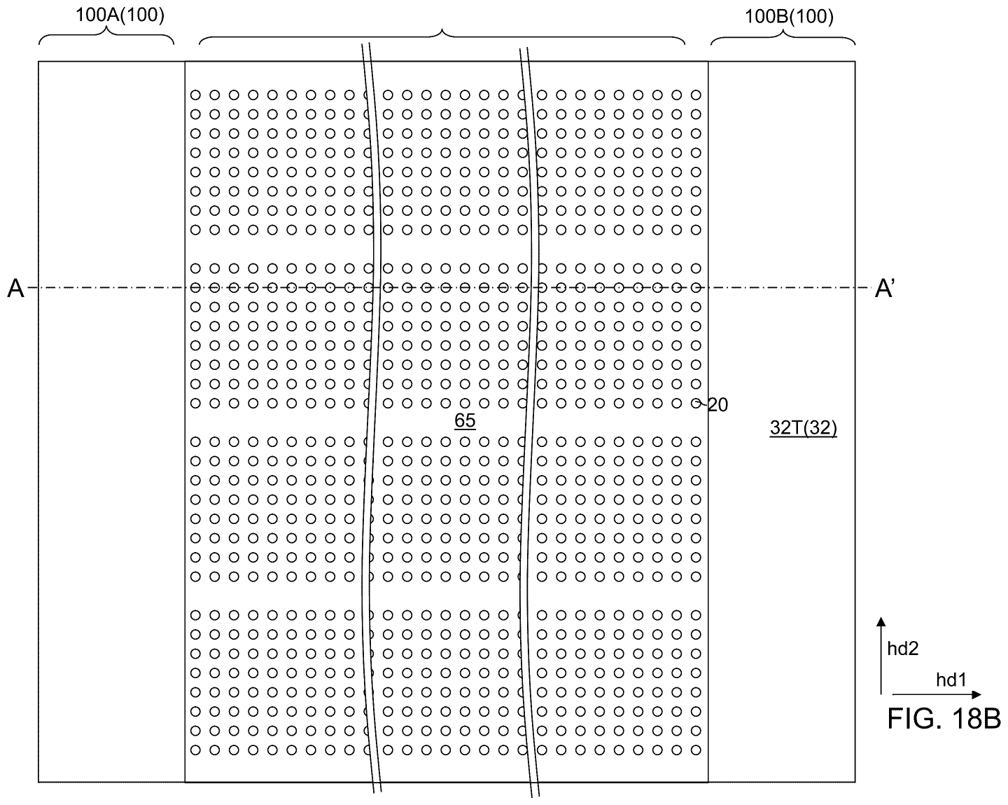

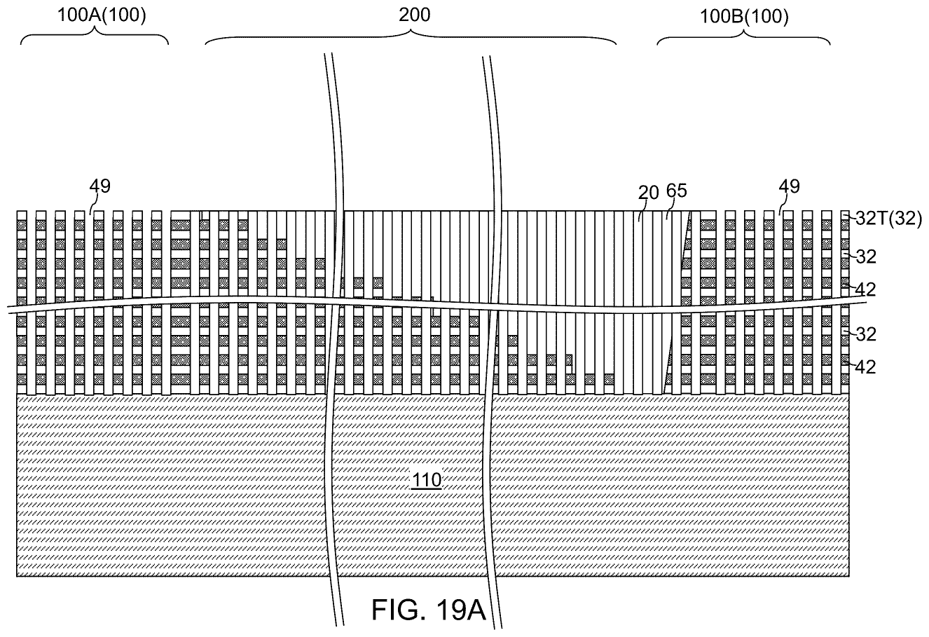

Referring to FIGS. 18A and 18B, a photoresist layer (not shown) can be applied over the first exemplary structure, and can be lithographically patterned to form discrete openings in the intermediate region 200. An anisotropic etch process can be performed to transfer the pattern of the discrete openings in the photoresist layer through the alternating stack (32, 42) and the retro-stepped dielectric material portions 65. Support openings are formed in the intermediate region 200 through the alternating stack (32, 42) and the retro-stepped dielectric material portions 65. The photoresist layer can be subsequently removed, for example, by ashing. A dielectric fill material such as silicon oxide can be deposited in the support openings to form support pillar structures 20. The support pillar structures 20 may comprise straight sidewalls that vertically extend from a horizontal plane including top surfaces of the retro-stepped dielectric material portions to the semiconductor material layer 110.

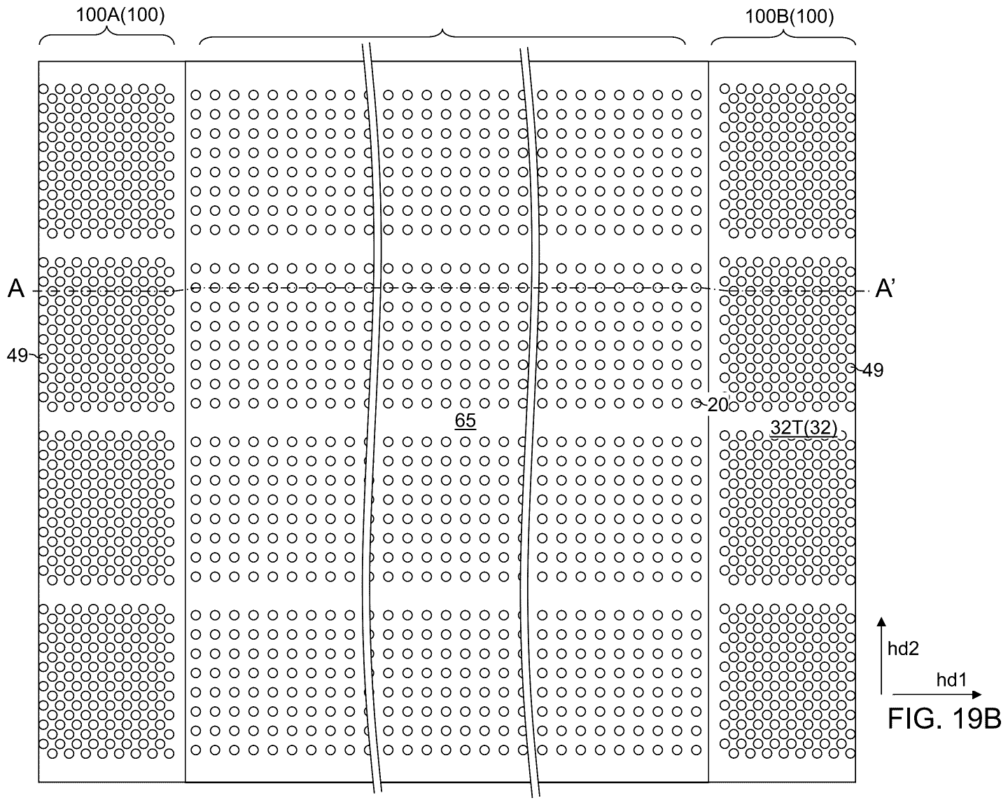

Referring to FIGS. 19A and 19B, a photoresist layer (not shown) can be applied over the first exemplary structure, and can be lithographically patterned to form discrete openings in the memory array regions 100. An anisotropic etch process can be performed to transfer the pattern of the discrete openings in the photoresist layer through the alternating stack (32, 42). Memory openings 49 are formed in the memory array regions 100 through the alternating stack (32, 42). The photoresist layer can be subsequently removed, for example, by ashing.

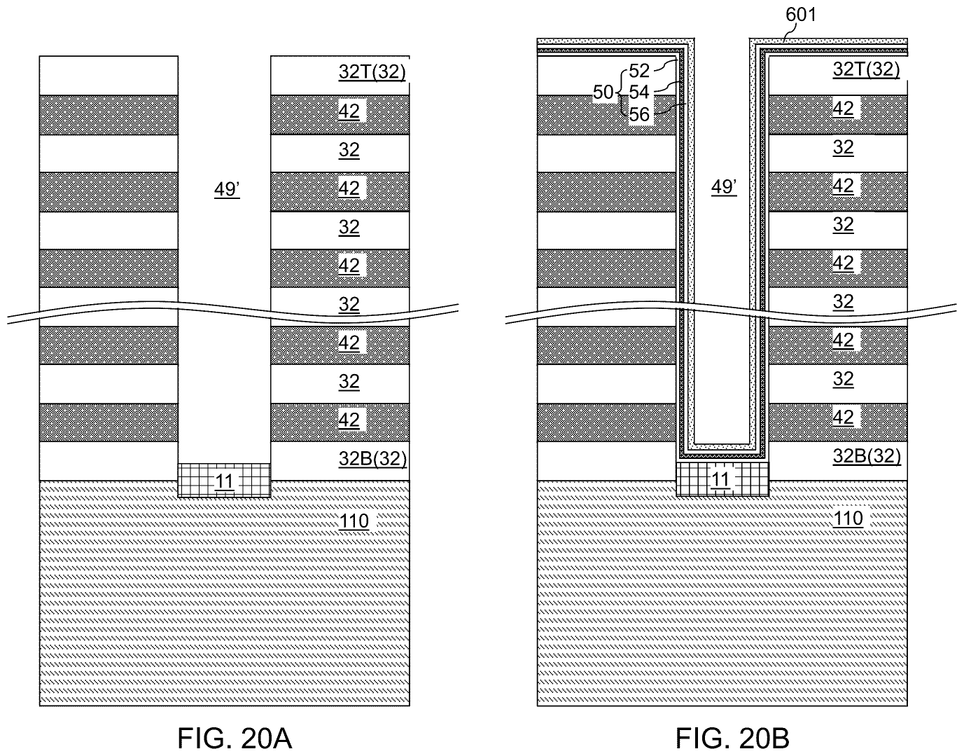

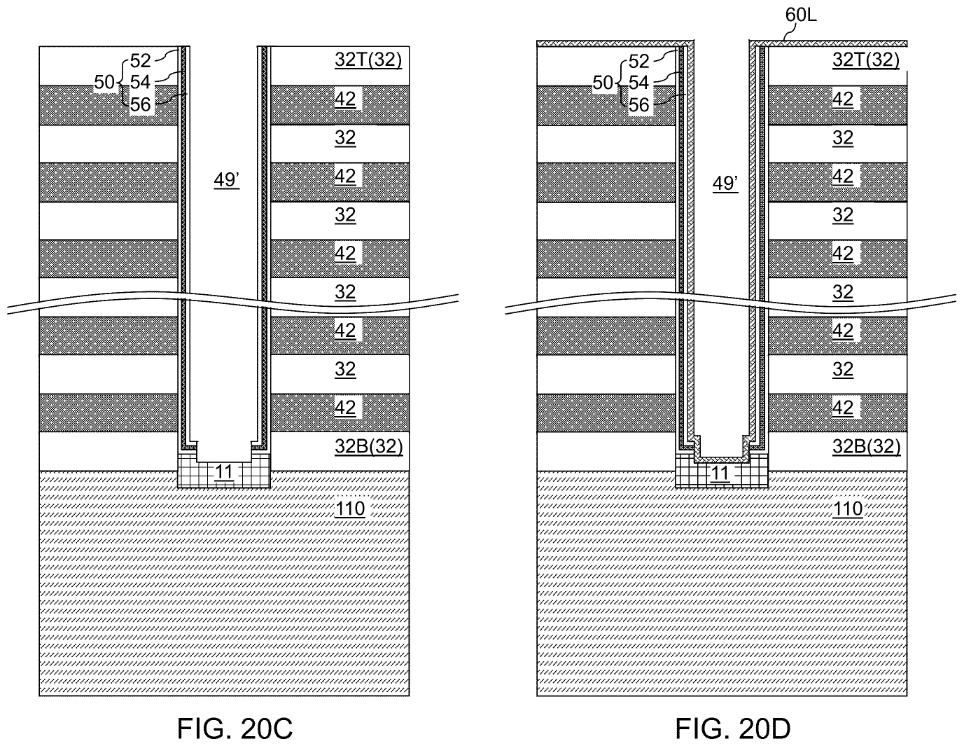

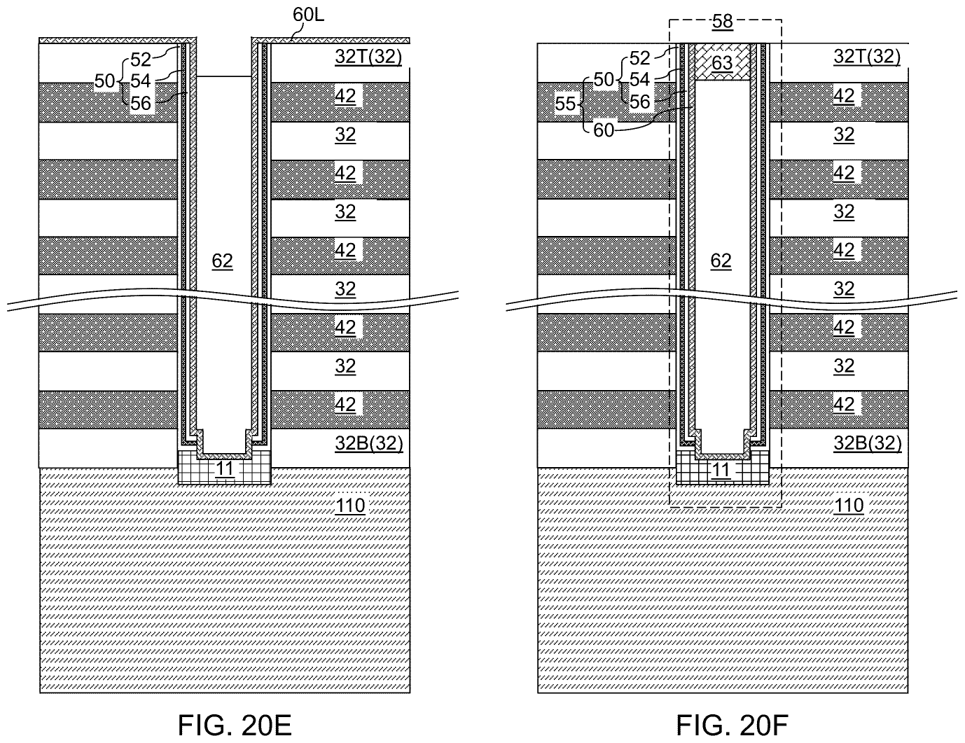

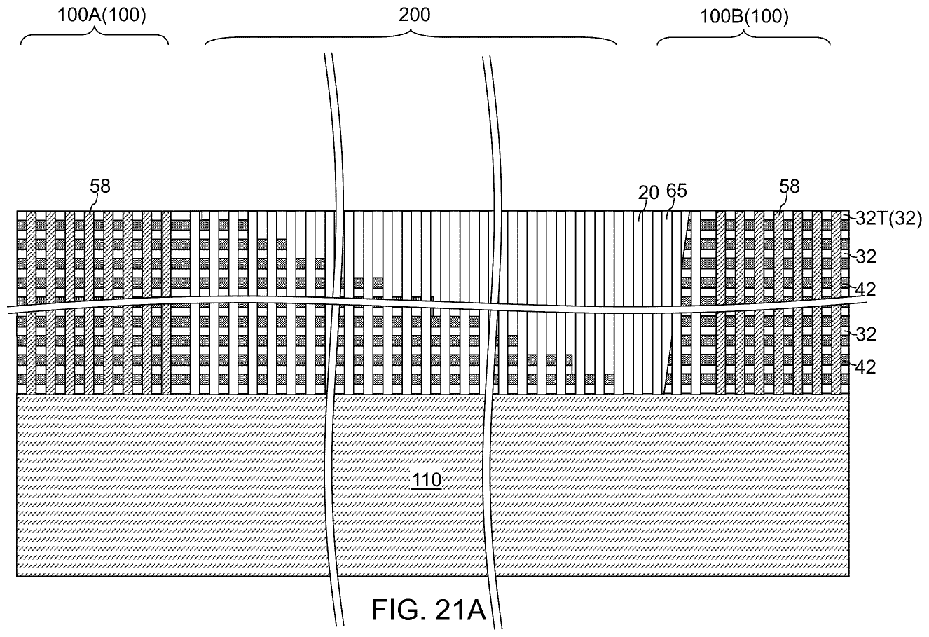

FIGS. 20A-20F are sequential vertical cross-sectional views of a memory opening 49 during formation of a memory opening fill structure 58 according to an embodiment of the present disclosure.

Referring to FIG. 20A, a memory opening 49 in the first exemplary structure of FIGS. 19A and 19B is illustrated. The memory opening 49 extends through the alternating stack (32, 42), and into an upper portion of the semiconductor material layer 110. The recess depth of the bottom surface of each memory opening 49 with respect to the top surface of the semiconductor material layer 110 can be in a range from 0 nm to 30 nm, although greater recess depths can also be employed. Optionally, the sacrificial material layers 42 can be laterally recessed partially to form laterally-extending cavities (not shown), for example, by an isotropic etch.

An optional pedestal channel portion 11 (which may be a silicon pedestal) can be formed at the bottom portion of each memory opening 49, for example, by a selective semiconductor deposition process. In one embodiment, the pedestal channel portion 11 can be doped with electrical dopants of the same conductivity type as the semiconductor material layer 110, which is a first conductivity type. In one embodiment, the top surface of each pedestal channel portion 11 can be formed below a horizontal plane including the top surface of the bottommost insulating layer 32B. The pedestal channel portion 11 can be a portion of a transistor channel that extends between a source region to be subsequently formed in the semiconductor material layer 110 and a drain region to be subsequently formed in an upper portion of the memory opening 49. A memory cavity 49′ is present in the unfilled portion of the memory opening 49 above the pedestal channel portion 11.

Referring to FIG. 20B, a stack of layers including a blocking dielectric layer 52, a memory material layer 54, and an optional dielectric liner 56 can be deposited in each memory opening 49. The stack of layers is herein referred to as a memory film 50.

The blocking dielectric layer 52 can include a single dielectric material layer or a stack of a plurality of dielectric material layers. In one embodiment, the blocking dielectric layer 52 can include a dielectric metal oxide layer consisting essentially of a dielectric metal oxide. In one embodiment, the blocking dielectric layer 52 can include a dielectric metal oxide having a dielectric constant greater than 7.9, i.e., having a dielectric constant greater than the dielectric constant of silicon nitride. Alternatively or additionally, the blocking dielectric layer 52 can include a dielectric semiconductor compound such as silicon oxide, silicon oxynitride, silicon nitride, or a combination thereof. In one embodiment, the blocking dielectric layer 52 can include silicon oxide. In this case, the dielectric semiconductor compound of the blocking dielectric layer 52 can be formed by a conformal deposition method such as low pressure chemical vapor deposition, atomic layer deposition, or a combination thereof. The thickness of the dielectric semiconductor compound can be in a range from 1 nm to 20 nm, although lesser and greater thicknesses can also be employed.

The memory material layer 54 may comprise any memory material such as a charge storage material, a ferroelectric material, a phase change material, or any material that can store data bits in the form of presence or absence of electrical charges, a direction of ferroelectric polarization, electrical resistivity, or another measurable physical parameter. In one embodiment, the memory material layer 54 can be a continuous layer or patterned discrete portions of a charge trapping material including a dielectric charge trapping material, which can be, for example, silicon nitride. Alternatively, the memory material layer 54 can include a continuous layer or patterned discrete portions of a conductive material such as doped polysilicon or a metallic material that is patterned into multiple electrically isolated portions (e.g., floating gates), for example, by being formed within laterally-extending cavities into sacrificial material layers 42. In one embodiment, the memory material layer 54 includes a silicon nitride layer. In one embodiment, the sacrificial material layers 42 and the insulating layers 32 can have vertically coincident sidewalls, and the memory material layer 54 can be formed as a single continuous layer. Generally, the memory material layer 54 may comprise a vertical stack of memory elements that are located at levels of the sacrificial material layers 42. For example, the vertical stack of memory elements may be embodied as annular portions of the memory material layer 54 located at levels of the sacrificial material layers 42.

The optional dielectric liner 56, if present, comprises a dielectric liner material. In one embodiment, the dielectric liner 56 may comprise a tunneling dielectric layer through which charge tunneling can be performed under suitable electrical bias conditions. The charge tunneling may be performed through hot-carrier injection or by Fowler-Nordheim tunneling induced charge transfer depending on the mode of operation of the monolithic three-dimensional NAND string memory device to be formed. The dielectric liner 56 can include silicon oxide, silicon nitride, silicon oxynitride, dielectric metal oxides (such as aluminum oxide and hafnium oxide), dielectric metal oxynitride, dielectric metal silicates, alloys thereof, and/or combinations thereof. In one embodiment, the dielectric liner 56 can include a stack of a first silicon oxide layer, a silicon oxynitride layer, and a second silicon oxide layer, which is commonly known as an ONO stack. In one embodiment, the dielectric liner 56 can include a silicon oxide layer that is substantially free of carbon or a silicon oxynitride layer that is substantially free of carbon. The thickness of the dielectric liner 56 can be in a range from 2 nm to 20 nm, although lesser and greater thicknesses can also be employed.

Optionally, a sacrificial cover material layer 601 may be formed over the memory film 50.

Referring to FIG. 20C, the optional sacrificial cover material layer 601, the dielectric liner 56, the memory material layer 54, the blocking dielectric layer 52 are sequentially anisotropically etched employing at least one anisotropic etch process. The portions of the sacrificial cover material layer 601, the dielectric liner 56, the memory material layer 54, and the blocking dielectric layer 52 located above the top surface of the topmost insulating layer 32T can be removed by the at least one anisotropic etch process. Further, the horizontal portions of the sacrificial cover material layer 601, the dielectric liner 56, the memory material layer 54, and the blocking dielectric layer 52 at a bottom of each memory cavity 49′ can be removed to form openings in remaining portions thereof. Each of the sacrificial cover material layer, the dielectric liner 56, the memory material layer 54, and the blocking dielectric layer 52 can be etched by a respective anisotropic etch process employing a respective etch chemistry, which may or may not be the same for the various material layers.

Each remaining portion of the sacrificial cover material layer 601, if employed, can have a tubular configuration. A surface of the pedestal channel portion 11 (or a surface of the semiconductor material layer 110 in case a pedestal channel portions 11 is not employed) can be physically exposed underneath the opening through the sacrificial cover material layer, the dielectric liner 56, the memory material layer 54, and the dielectric metal oxide blocking dielectric layer 52. Optionally, the physically exposed semiconductor surface at the bottom of each memory cavity 49′ can be vertically recessed so that the recessed semiconductor surface underneath the memory cavity 49′ is vertically offset from the topmost surface of the pedestal channel portion 11 (or of the semiconductor material layer 110 in case pedestal channel portions 11 are not employed) by a recess distance. In one embodiment, the sacrificial cover material layer 601, the dielectric liner 56, the memory material layer 54, and the blocking dielectric layer 52 can have vertically coincident sidewalls. The sacrificial cover material layer 601 can be subsequently removed selective to the material of the dielectric liner 56. In case the sacrificial cover material layer 601 includes amorphous silicon, a wet etch process employing hot trimethyl-2 hydroxyethyl ammonium hydroxide (“hot TMY”) or tetramethyl ammonium hydroxide (TMAH) can be performed to remove the sacrificial cover material layer. Alternatively, the sacrificial cover material layer 601 may be retained in the final device if it comprises a silicon material.

Referring to FIG. 20D, a semiconductor channel layer 60L can be deposited directly on the semiconductor surface of the pedestal channel portion 11 or the semiconductor material layer 110 if the pedestal channel portion 11 is omitted, and directly on the memory film 50. The semiconductor channel layer 60L includes a semiconductor material such as at least one elemental semiconductor material, at least one III-V compound semiconductor material, at least one II-VI compound semiconductor material, at least one organic semiconductor material, or other semiconductor materials known in the art. In one embodiment, the semiconductor channel layer 60L includes amorphous silicon or polysilicon. The semiconductor channel layer 60L can have a doping of a first conductivity type, which is the same as the conductivity type of the semiconductor material layer 110 and the pedestal channel portions 11. The semiconductor channel layer 60L can be formed by a conformal deposition method such as low pressure chemical vapor deposition (LPCVD). The thickness of the semiconductor channel layer 60L can be in a range from 2 nm to 10 nm, although lesser and greater thicknesses can also be employed. The semiconductor channel layer 60L may partially fill the memory cavity 49′ in each memory opening, or may fully fill the cavity in each memory opening.

Referring to FIG. 20E, a dielectric core layer can be deposited to fill any remaining portion of the memory cavity 49′ within each memory opening 49. The dielectric core layer includes a dielectric material such as silicon oxide or organosilicate glass. The dielectric core layer can be deposited by a conformal deposition method such as low pressure chemical vapor deposition (LPCVD), or by a self-planarizing deposition process such as spin coating. The horizontal portion of the dielectric core layer can be removed, for example, by a recess etch process such that each remaining portions of the dielectric core layer is located within a respective memory opening 49 and has a respective top surface below the horizontal plane including the top surface of the topmost insulating layer 32T. Each remaining portion of the dielectric core layer constitutes a dielectric core 62.

Referring to FIG. 20F, a doped semiconductor material having a doping of a second conductivity type can be deposited within each recessed region above the dielectric cores 62. The deposited semiconductor material can have a doping of a second conductivity type that is the opposite of the first conductivity type. For example, if the first conductivity type is p-type, the second conductivity type is n-type, and vice versa. The dopant concentration in the deposited semiconductor material can be in a range from 5.0×10¹⁸/cm³ to 2.0×10²¹/cm³, although lesser and greater dopant concentrations can also be employed. The doped semiconductor material can be, for example, doped polysilicon.

Excess portions of the deposited semiconductor material having a doping of the second conductivity type and a horizontal portion of the semiconductor channel layer 60L can be removed from above the horizontal plane including the top surface of the topmost insulating layer 32T, for example, by chemical mechanical planarization (CMP) or a recess etch process. Each remaining portion of the doped semiconductor material having a doping of the second conductivity type constitutes a drain region 63. Each remaining portion of the semiconductor channel layer 60L (which has a doping of the first conductivity type) constitutes a vertical semiconductor channel 60.

Each combination of a memory film 50 and a vertical semiconductor channel 60 within a memory opening 49 constitutes a memory stack structure 55. The memory stack structure 55 is a combination of a vertical semiconductor channel 60, an optional dielectric liner 56, a plurality of memory elements comprising portions of the memory material layer 54, and an optional blocking dielectric layer 52. Each combination of a pedestal channel portion 11 (if present), a memory stack structure 55, a dielectric core 62, and a drain region 63 within a memory opening 49 is herein referred to as a memory opening fill structure 58.

In the alternative embodiment in which the support openings are formed at the same time as the memory openings 49, the support pillar structures 20 may be formed in the support openings at the same time as the memory opening fill structures 58. In this alternative embodiment, the support pillar structures 20 have the same composition as the memory opening fill structures 58, but are not electrically connected to the subsequently formed bit lines.

Generally, first memory openings 49 and second memory openings 49 may vertically extend through the alternating stack (32, 42) in the first memory array region 100A and in the second memory array region 100B, respectively. First memory opening fill structures 58 and second memory opening fill structures 58 may be formed in the first memory openings 49 and in the second memory openings 49, respectively. Each of the first memory opening fill structures 58 and second memory opening fill structures 58 comprises a respective vertical stack of memory elements (e.g., portions of the memory film 50) and a vertical semiconductor channel 60.

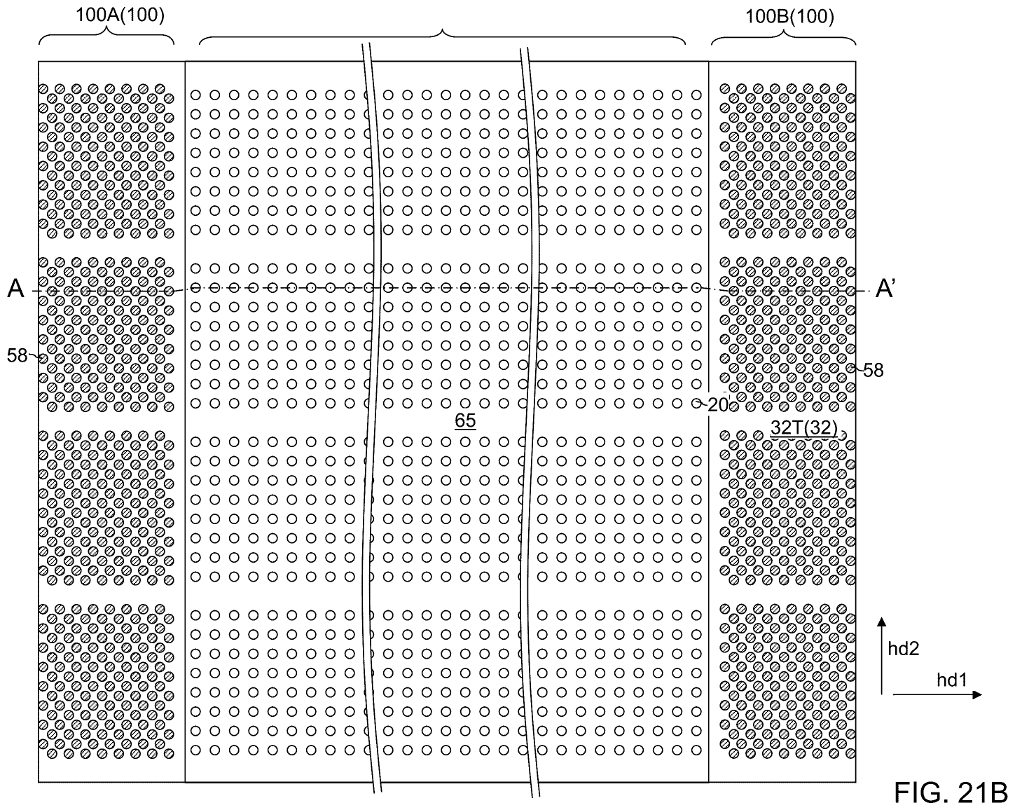

Referring to FIGS. 21A and 21B, a region of the first exemplary structure is illustrated after formation of the memory opening fill structures 58.

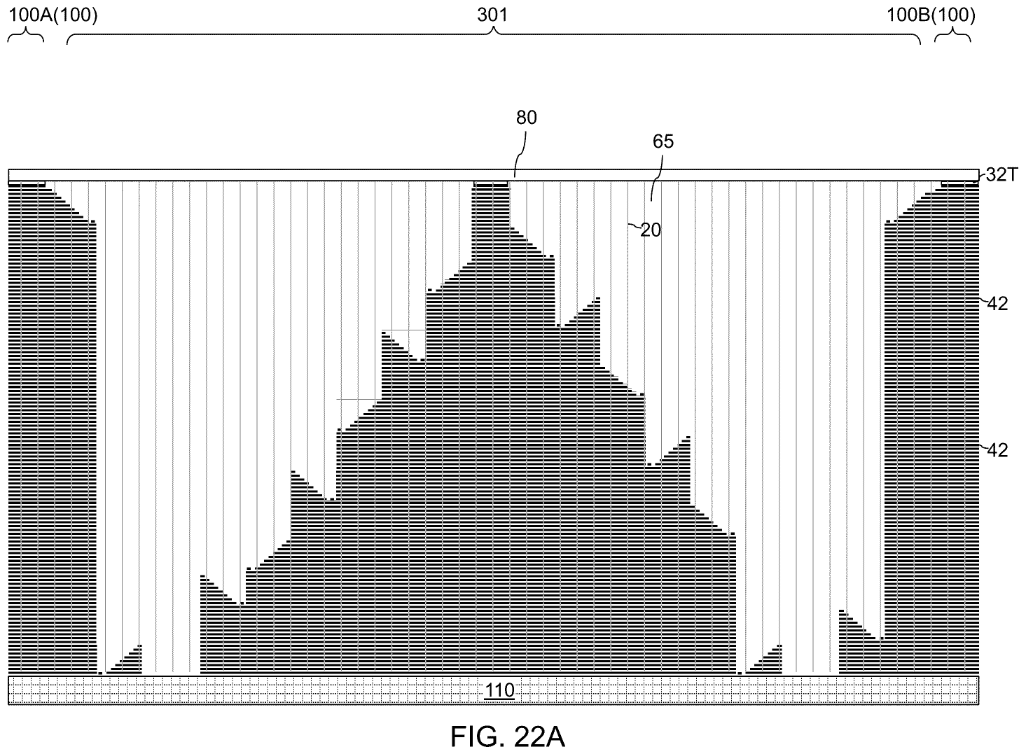

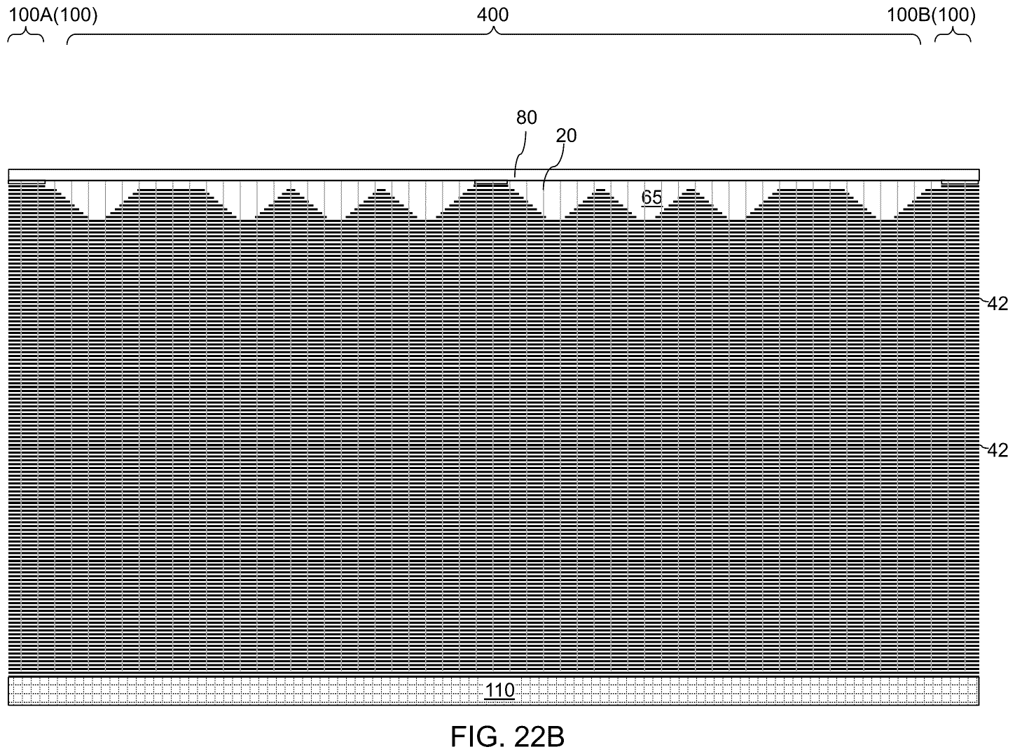

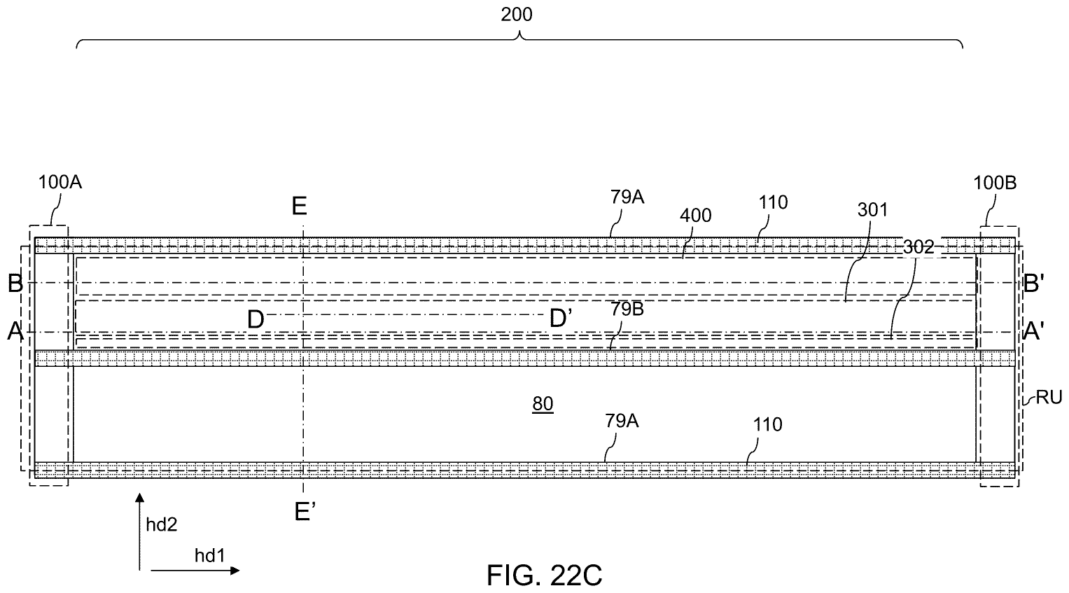

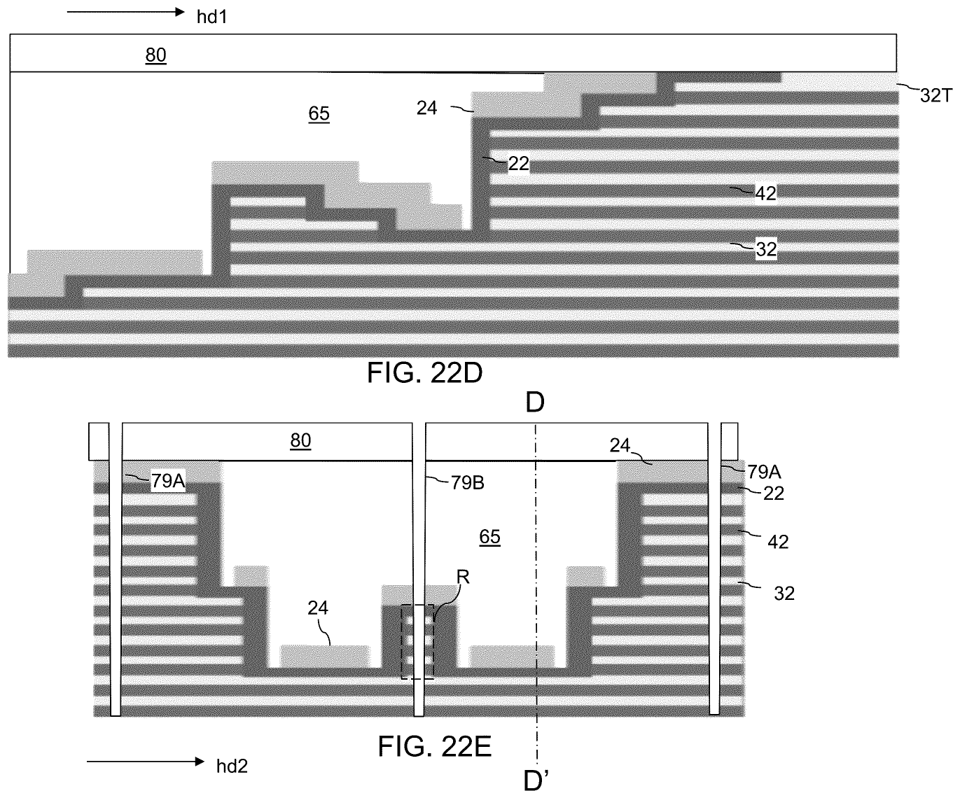

Referring to FIGS. 22A-22E, a dielectric material can be deposited above the alternating stack (32, 42) and the retro-stepped dielectric material portions 65 to form a contact-level dielectric layer 80. A photoresist layer (not shown) can be applied over the contact-level dielectric layer 80, and can be lithographically patterned to form elongated openings that laterally extend along the first horizontal direction hd1 with a uniform width along the second horizontal direction hd2. An anisotropic etch process can be performed to transfer the pattern of the elongated openings in the photoresist layer through the contact-level dielectric layer 80, the alternating stack (32, 42), and the retro-stepped dielectric material portions 65. Lateral isolation trenches 79 are formed in the volumes from which the materials of the contact-level dielectric layer 80, the alternating stack (32, 42), and the retro-stepped dielectric material portions 65 are removed.

The lateral isolation trenches 79 comprise first lateral isolation trenches 79A that do not cut through any retro-stepped dielectric material portion 65, and second lateral isolation trenches 79B that cut through a respective retro-stepped dielectric material portion 65. A pair a first lateral isolation trenches 79A and a second lateral isolation trench 79B can be formed per repetition unit RU. Each first lateral isolation trench 79A can be formed outside the areas of the retro-stepped dielectric material portions 65. Each second lateral isolation trench 79B can be formed through a respective retro-stepped dielectric material portion 65, through a respective row of second dielectric etch-stop plates 24, and through the ridges R. Thus, each row of second dielectric etch-stop plates 24 may be divided into a pair of rows of second dielectric etch-stop plates 24 by a respective second lateral isolation trench 79B.

Referring to FIGS. 23A-23C, an isotropic etch process can be performed to introduce an isotropic etchant that etches a material of the sacrificial material layers 42 into the lateral isolation trenches 79. For example, if the sacrificial material layers 42 comprise silicon nitride, the isotropic etch process may comprise a wet etch process employing hot phosphoric acid. Laterally-extending cavities are formed in volumes from which portions of the sacrificial material layers 42 are removed by the isotropic etch process. The isotropic etch process etches the second dielectric etch-stop plates 24 that are physically exposed to the lateral isolation trenches 79. Lateral recess cavities are formed in the volumes from which the second dielectric etch-stop plates 24 are removed. The first dielectric etch stop plates 24 that are laterally spaced from the lateral isolation trenches 79 are not etched by the isotropic etch process.

A backside blocking dielectric layer (not shown) may be optionally deposited in the laterally-extending cavities (formed by removal of the sacrificial material layers 42) and in the lateral recess cavities (formed by removal of the second dielectric etch-stop plates 24) on the physically exposed surfaces of the retro-stepped dielectric material portions 65, the memory opening fill structures 58, and the insulating layers 32 by a conformal deposition process. At least one conductive material can be deposited in unfilled volumes of the laterally-extending cavities and in the volumes of the lateral recess cavities by providing at least one reactant gas into the laterally-extending cavities and into the lateral recess cavities through the lateral isolation trenches. For example, the at least one conductive material may comprise a metallic barrier layer and a metallic fill material.

The metallic barrier layer includes an electrically conductive metallic material that can function as a diffusion barrier layer and/or adhesion promotion layer for a metallic fill material to be subsequently deposited. The metallic barrier layer can include a conductive metallic nitride material such as TIN, TaN, WN, or a stack thereof, or can include a conductive metallic carbide material such as TiC, TaC, WC, or a stack thereof. In one embodiment, the metallic barrier layer can be deposited by a conformal deposition process such as chemical vapor deposition (CVD) or atomic layer deposition (ALD). The thickness of the metallic barrier layer can be in a range from 2 nm to 8 nm, such as from 3 nm to 6 nm, although lesser and greater thicknesses can also be employed. In one embodiment, the metallic barrier layer can consist essentially of a conductive metal nitride such as TiN.

The metal fill material can be deposited over the metallic barrier layer to form a metallic fill material layer. The metallic fill material can be deposited by a conformal deposition method, which can be, for example, chemical vapor deposition (CVD), atomic layer deposition (ALD), electroless plating, electroplating, or a combination thereof. In one embodiment, the metallic fill material layer can consist essentially of at least one elemental metal. The at least one elemental metal of the metallic fill material layer can be selected, for example, from tungsten, cobalt, ruthenium, titanium, and tantalum. In one embodiment, the metallic fill material layer can consist essentially of a single elemental metal. In one embodiment, the metallic fill material layer can be deposited employing a fluorine-containing precursor gas, such as WF₆. In one embodiment, the metallic fill material layer can be a tungsten layer including a residual level of fluorine atoms as impurities. The metallic fill material layer is spaced from the insulating layers 32 and the memory opening fill structures 58 by the metallic barrier layer, which is a metallic barrier layer that blocks diffusion of fluorine atoms therethrough.

A plurality of electrically conductive layers 46 can be formed in the plurality of laterally-extending cavities, a plurality of electrically conductive plates 28 can be formed in the plurality of lateral recess cavities from which the second dielectric etch-stop plates 24 are removed, and a continuous metallic material layer can be formed on the sidewalls of each lateral isolation trench 79 and over the topmost insulating layer 32T. Each electrically conductive layer 46 includes a portion of the metallic barrier layer and a portion of the metallic fill material layer that are located between a vertically neighboring pair of dielectric material layers such as a pair of insulating layers 32. Each electrically conductive plate 28 includes a portion of the metallic barrier layer and a portion of the metallic fill material layer that is formed within a respective one of the laterally-extending cavities. The continuous metallic material layer includes a continuous portion of the metallic barrier layer and a continuous portion of the metallic fill material layer that are located in the lateral isolation trenches 79 or above the contact-level dielectric layer 80.

The deposited metallic material of the continuous electrically conductive material layer is etched back from the sidewalls of each lateral isolation trench 79 and from above the topmost insulating layer 32T by performing an etch process that etches the at least one conductive material of the continuous electrically conductive material layer. Each remaining portion of the deposited metallic material in the laterally-extending cavities constitutes an electrically conductive layer 46. Thus, the sacrificial material layers 42 are replaced with the electrically conductive layers 46.

A subset of the electrically conductive layers 46 can function as a combination of a plurality of control gate electrodes located at a same level and a word line electrically interconnecting the plurality of control gate electrodes located at the same level. The plurality of control gate electrodes within each electrically conductive layer 46 are the control gate electrodes for the vertical memory devices including the memory stack structures 55. In other words, the electrically conductive layer 46 can be a word line that functions as a common control gate electrode for the plurality of vertical memory devices. At least one upper most electrically conductive layer 46 may comprise a drain side select gate electrode. At least one lower most electrically conductive layer 46 may comprise a source side select gate electrode.

Generally, the sacrificial material layers 42 and the second dielectric etch-stop plates 24 may be replaced with electrically conductive layers 46 and electrically conductive plates 28, respectively, without removing the first dielectric etch-stop plates 24. Multiple alternating stacks (32, 46) of insulating layers 32 and electrically conductive layers 46 can be laterally spaced from each other by the lateral isolation trenches 79. Each layer within an alternating stack (32, 46) is present in a first memory array region 100A and in a second memory array region 100B that are laterally spaced from each other along a first horizontal direction hd1. The portion of an alternating stack (32, 46) located in a first memory array region 100A and the portion of the alternating stack (32, 46) located in the second memory array region 100B have a first width, which may be a uniform width, along a second horizontal direction hd2 that is perpendicular to the first horizontal direction hd1. Each row of second dielectric etch-stop plates 24 can be replaced with a respective row of electrically conductive plates 28, which are formed on second horizontally-extending surface segments of second stepped surfaces of an alternating stack (32, 46). The electrically conductive plates 28 comprise the same material as the electrically conductive layers 46.

In one embodiment, the electrically conductive layers 46 have a first thickness, and the electrically conductive plates 28 have a second thickness that is at least 1.5 times the first thickness, such as least 2.0 times the first thickness. In one embodiment, the first dielectric etch-stop plates 24 have the second thickness. In one embodiment, each of the electrically conductive plates 28 has a lesser length along the first horizontal direction hd1, and has a lesser width along the second horizontal direction hd2, than a respective underlying one of the second horizontally-extending surface segments of the second stepped surfaces of an alternating stack (32, 46). In one embodiment, each of the first dielectric etch-stop plates 24 has a lesser length along the first horizontal direction hd1, and has a lesser width along the second horizontal direction hd2, than a respective underlying one of the first horizontally-extending surface segments of the alternating stack (32, 46).

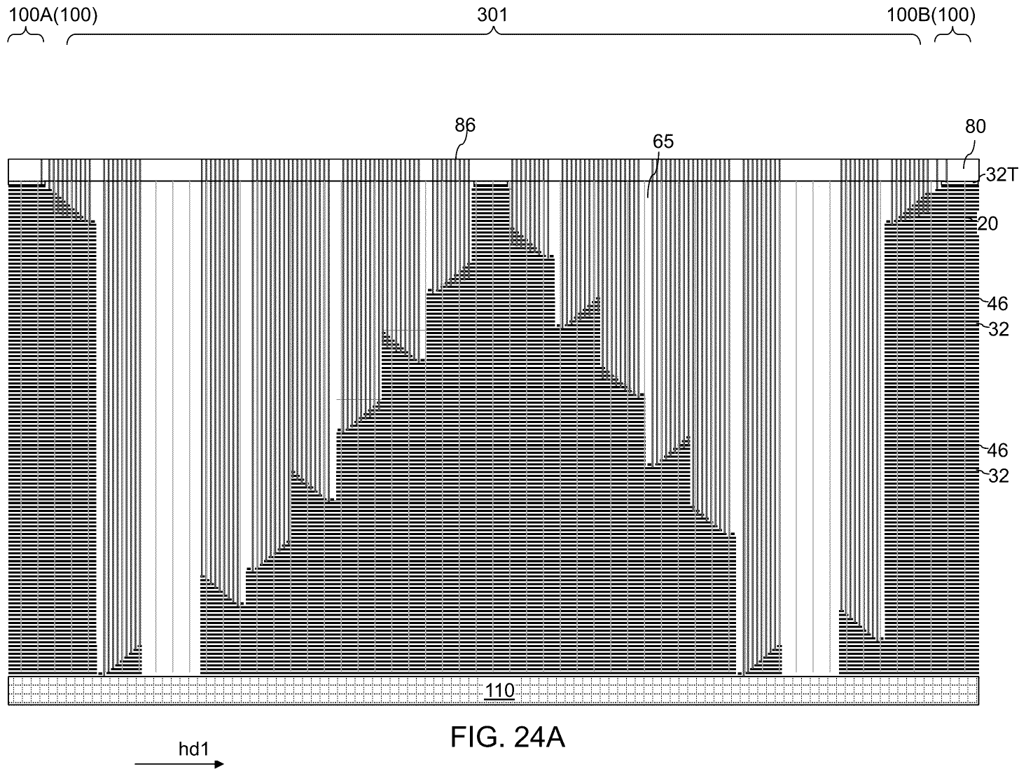

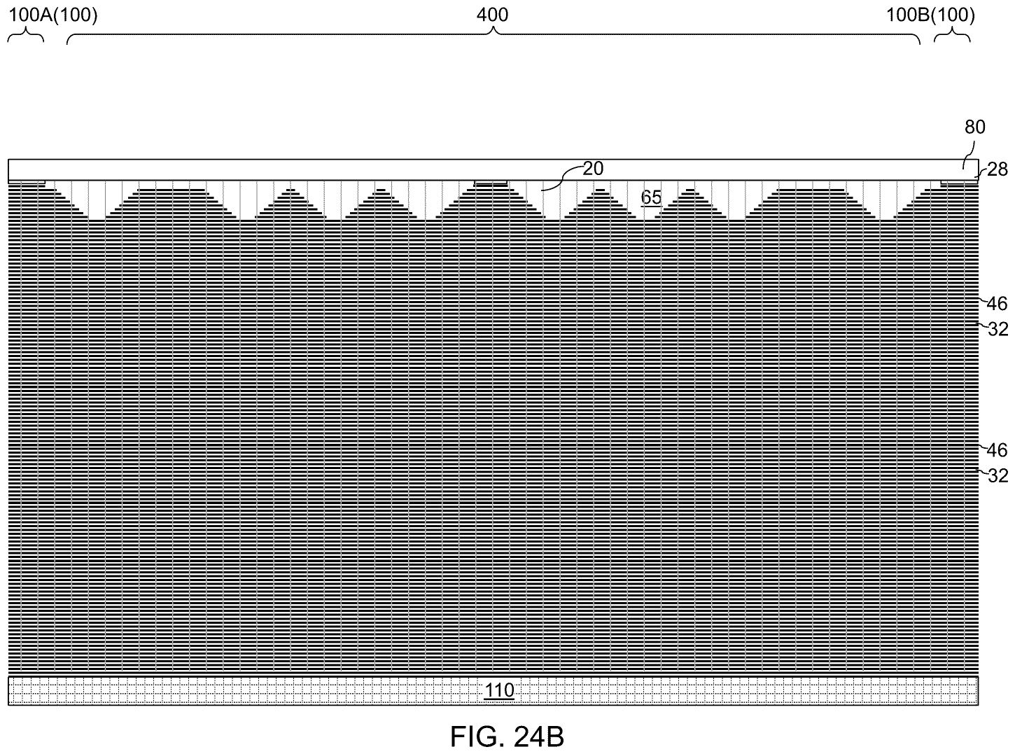

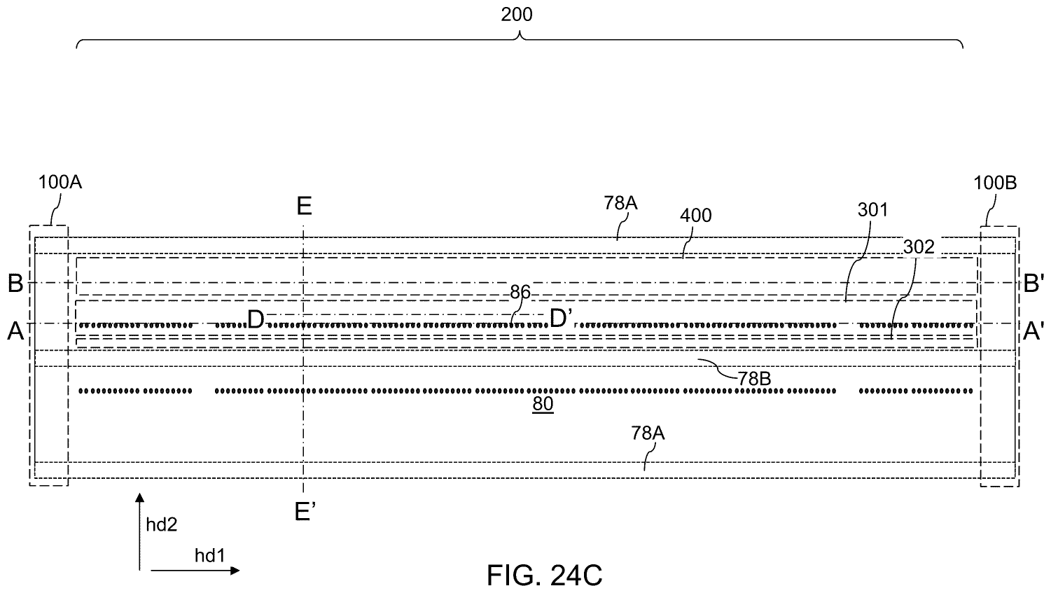

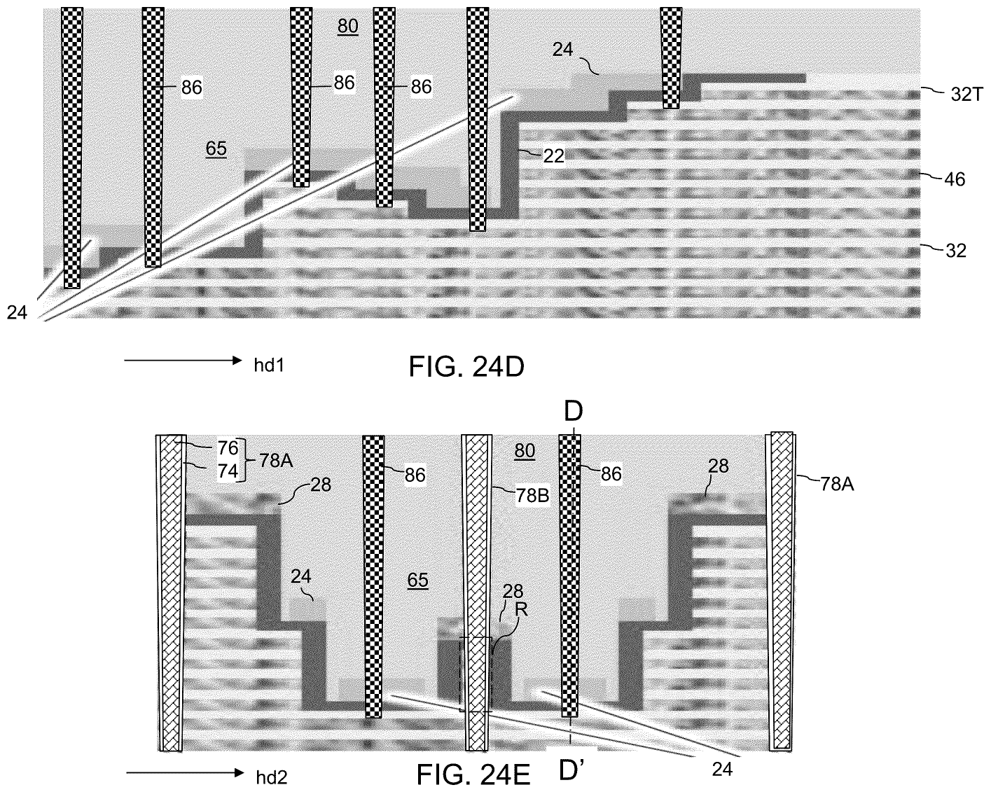

Referring to FIGS. 24A-24E, 25A, and 25B, an insulating material layer can be conformally deposited in peripheral regions of the lateral isolation trenches 79. An anisotropic etch process can be performed to remove horizontally-extending portions of the insulating material layer. Each remaining portion of the insulating material layer in the lateral isolation trenches 79 constitute insulating spacers 74.

At least one conductive material, such as at least one metallic material, can be optionally deposited in remaining volumes of the lateral isolation trenches 79. Excess portions of the at least one conductive material can be removed from above the horizontal plane including the top surface of the contact-level dielectric layer 80 by performing a planarization process, such as a chemical mechanical polishing process. Each remaining portion of the at least one conductive material in a respective one of the lateral isolation trenches 79 constitute a source contact wall structure 76. Each contiguous combination of an insulating spacer 74 and a source contact wall structure 76 constitutes an isolation trench fill structure 78.

The lateral isolation trench fill structures 78 may comprise first lateral isolation trench fill structures 78A formed in the first lateral isolation trenches 79A and second lateral isolation trench fill structures 78B formed in the second lateral isolation trenches 79B. The first lateral isolation trench fill structures 78A do not cut through any retro-stepped dielectric material portion 65 or ridges R, and second isolation trench fill structures 78B cut through a respective retro-stepped dielectric material portion 65 and a respective ridge R.

A photoresist layer (not shown) can be applied over the contact-level dielectric layer 80, and can be lithographically patterned to form openings over areas of the memory opening fill structures 58 and horizontally-extending portions of the electrically conductive layers 46 that underlie the stepped bottom surfaces of the retro-stepped dielectric material portions 65. An anisotropic etch process can be performed to form drain contact via cavities (not shown) over the drain regions 63 of the memory opening fill structures 58, and to form layer contact via structure cavities over the horizontally-extending surfaces of the electrically conductive layers 46 underlying the retro-stepped dielectric material portions 65. At least one conductive material can be deposited in the drain contact via cavities to form drain contact via structures (not shown), and can be deposited in the layer contact via structure cavities to form layer contact via structures 86. Each layer contact via structure 86 contacts a top surface segment of a respective electrically conductive layer 46. Each electrically conductive layer 46 can be contacted by at least one layer contact via structure 86. Additional metal interconnect structures (not shown) may be formed above the contact-level dielectric layer 80 as needed.

In one embodiment, each of the layer contact via structures 86 may be formed through a respective one of the first dielectric etch-stop plates 24 and directly on a respective one of the electrically conductive layers 46. A row of layer contact via structures 86 can be formed through each retro-stepped dielectric material portion 65. The layer contact via structures 86 may vertically extend through a respective one of the first dielectric etch-stop plates 24, and may contact a respective one of the word lines (comprising a middle subset of the electrically conductive layers 46). A row of electrically conductive plates 28 can be located on the second horizontally-extending surface segments of the alternating stack (32, 46). The electrically conductive plates comprise a same material as the electrically conductive layers 46. In one embodiment, the layer contact via structures 86 do not contact electrically conductive plates 28.

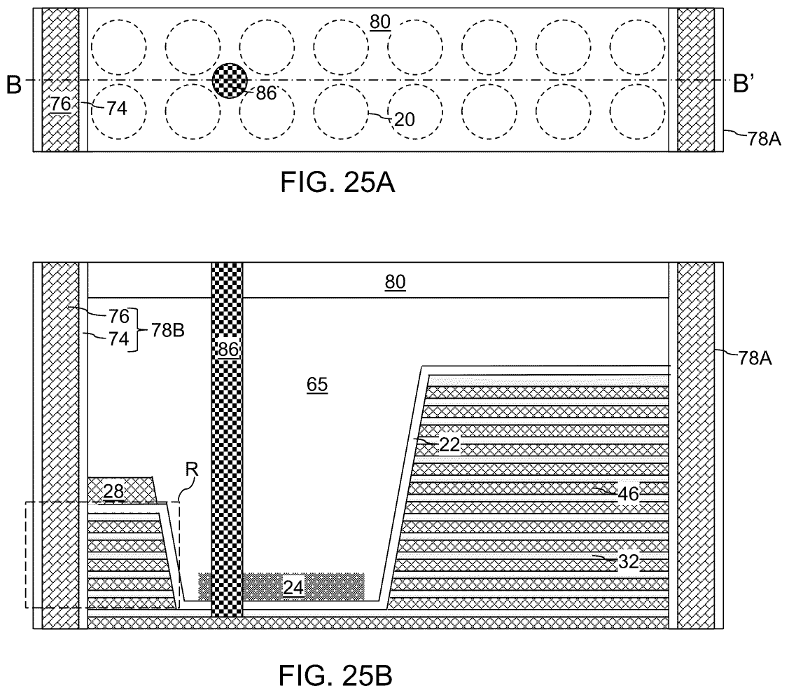

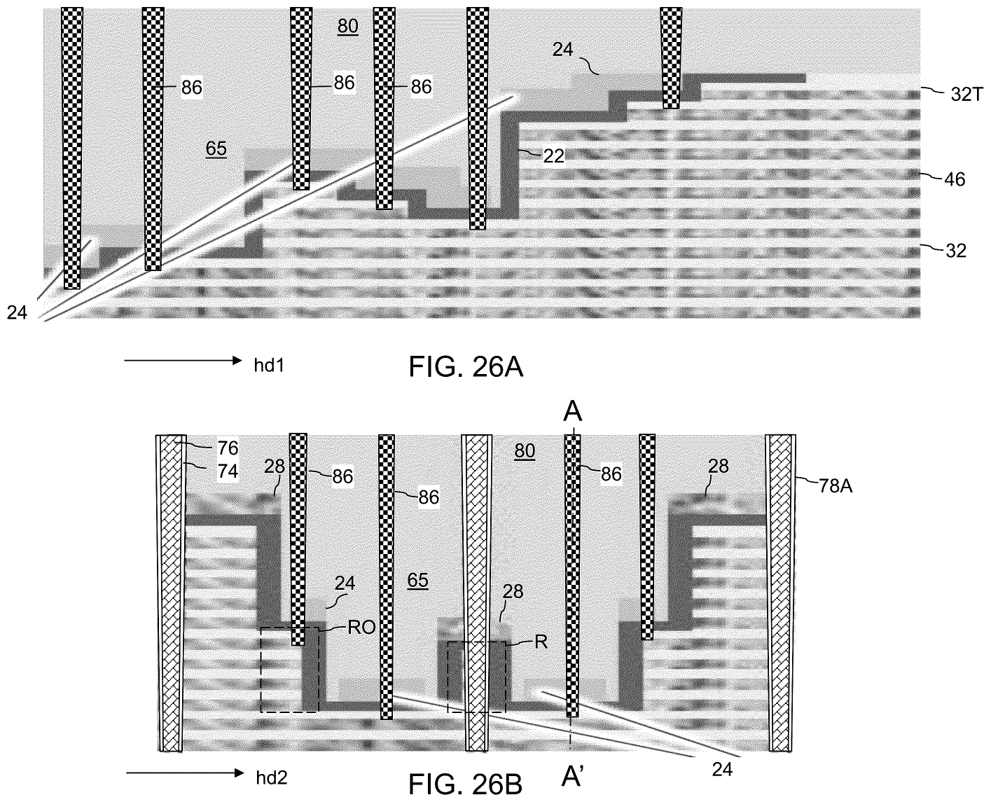

Referring to FIGS. 26A and 26B, an alternative configuration of the first exemplary structure is illustrated. In the alternative configuration, an additional staircase region, which is herein referred to as a third staircase region, may be formed between a first staircase region 301 and a connection region 400. The third staircase region may comprise third stepped surfaces including third horizontally-extending surface segments and third vertically-extending surface segments. The third horizontally-extending surface segments of the alternating stack (32, 46) may be arranged along the first horizontal direction hd1, and may be interconnected to each other by third vertically-extending surface segments in the third staircase region. A row of third dielectric etch-stop plates 24 can be located on the third horizontally-extending surface segments of the alternating stack (32, 46). The third stepped surfaces may be vertically offset from the first stepped surfaces by an offset ridge “RO” that laterally extends along the first horizontal direction hd1. The height of the offset ridge RO may be an integer multiple of the product of the total number L of iterations of the sequence of processing steps and the sum of the thickness of an insulating layer 32 and the thickness of an electrically conductive layer 46. In this case, two rows of layer contact via structures 86 can be formed through each retro-stepped dielectric material portion 65.

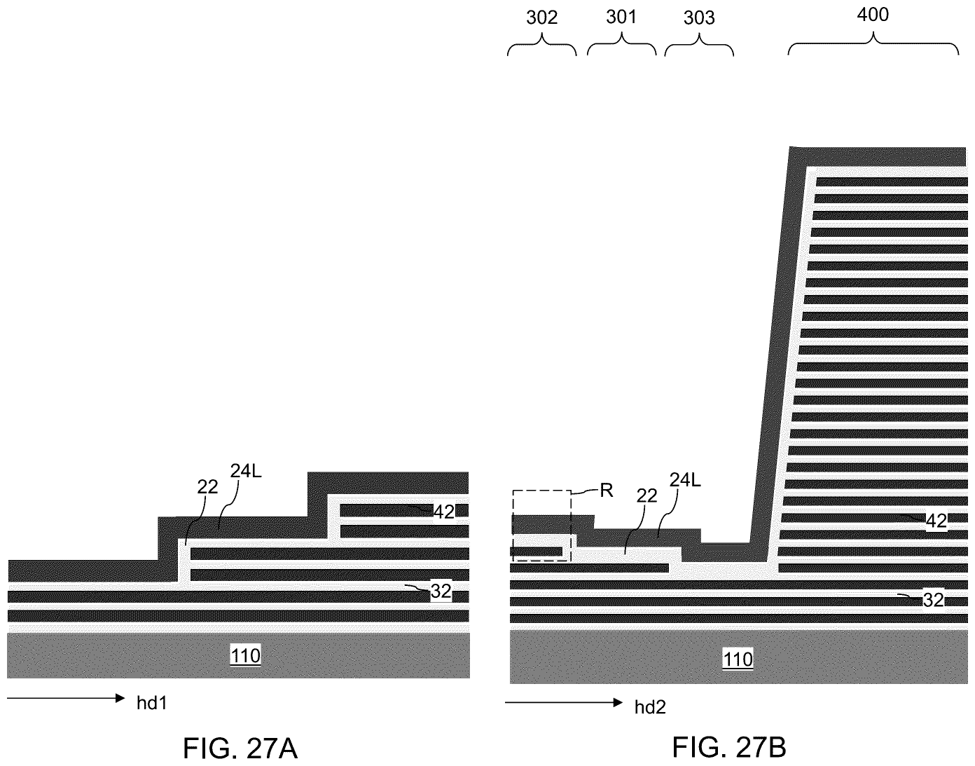

Referring to FIGS. 27A and 27B, a second exemplary structure is illustrated after formation of a conformal silicon oxide liner 22 and a dielectric etch-stop material layer 24L according to a second embodiment of the present disclosure. The second exemplary structure illustrated in FIGS. 27A and 27B may be derived from the first exemplary structure illustrated in FIGS. 11A and 11B by forming an additional staircase region. Specifically, a third staircase region 303 can be formed between a first staircase region 301 and the connection region 400 in the second exemplary structure in the same manner as in the alternative configuration of the first exemplary structure which is described with reference to FIGS. 26A and 26B.

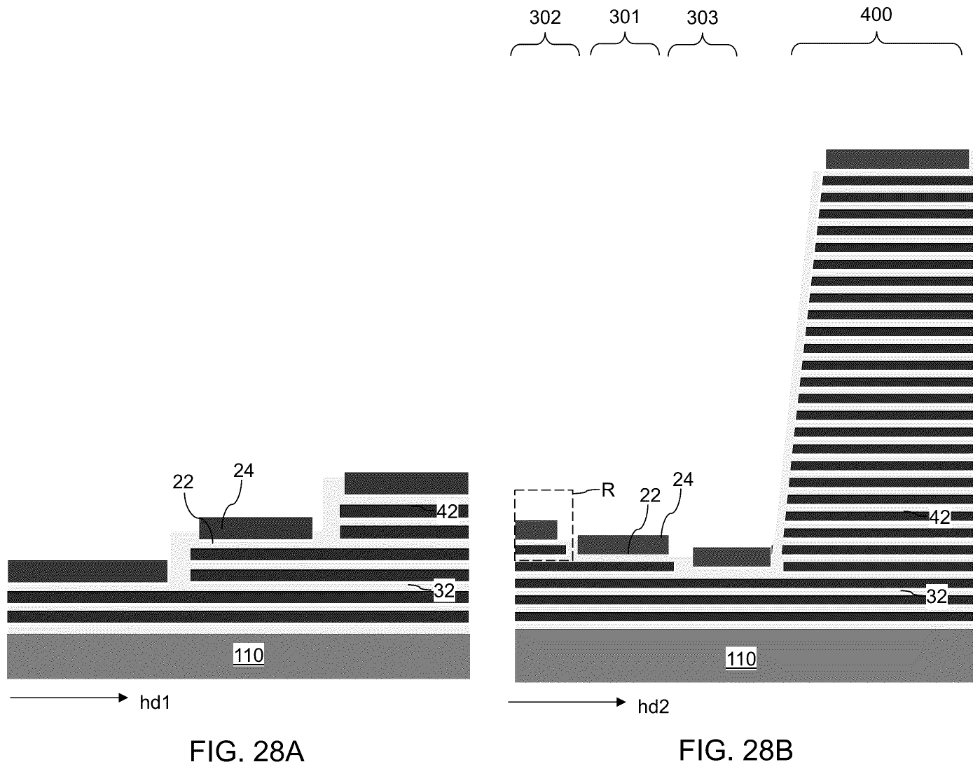

Referring to FIGS. 28A and 28B, the processing steps described with reference to FIGS. 12A-14B can be performed to convert the dielectric etch-stop material layer 24L into rows of dielectric etch-stop plates 24.

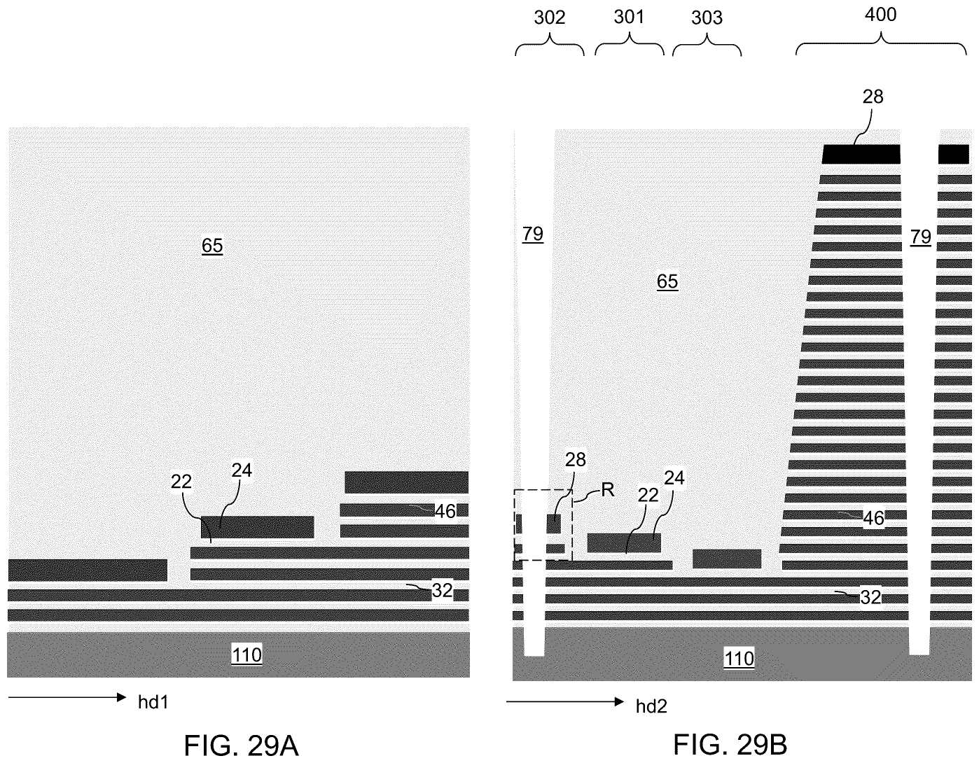

Referring to FIGS. FIGS. 29A and 29B, the processing steps described with reference to FIGS. 15A-23C can be performed to form a retro-stepped dielectric material portion 65, a contact-level dielectric layer 80, and lateral isolation trenches 79, and to replace the sacrificial material layers 42 with electrically conductive layers 46, and to replace a subset of the dielectric etch-stop plates 24 into electrically conductive plates 28.

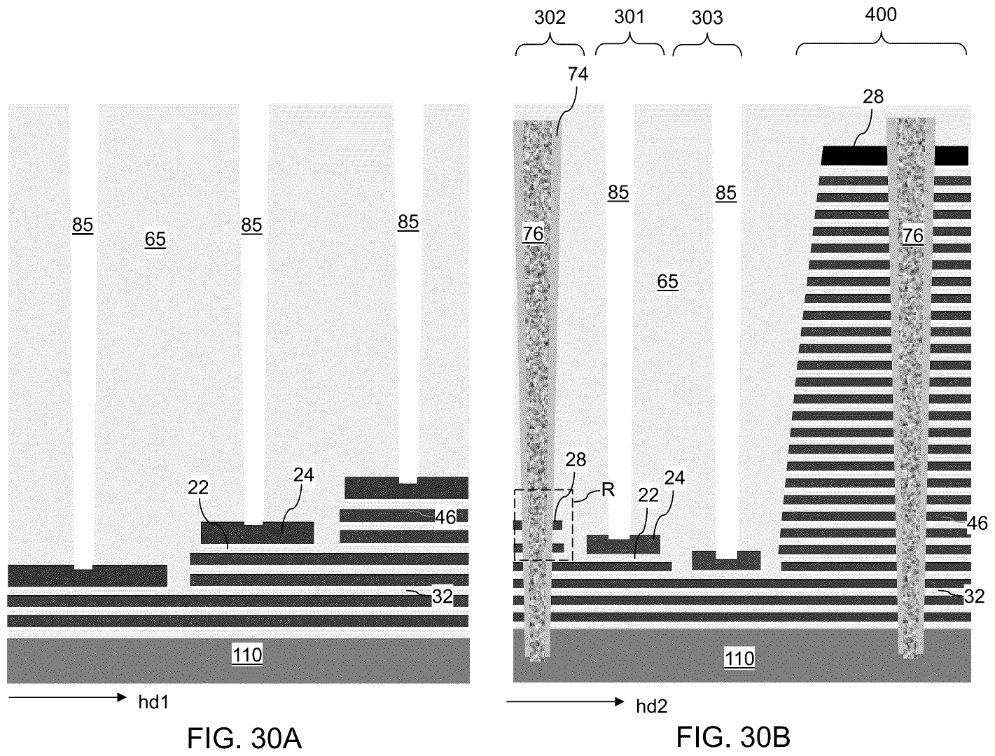

Referring to FIGS. 30A and 30B, the lateral isolation trench fill structures (74, 76) can be formed in the lateral isolation trenches 79. Layer contact via cavities 85 can be formed through the retro-stepped dielectric material portion 65 on a respective one of the dielectric etch-stop plates 24. The dielectric etch-stop plates 24 can be employed as etch-stop structures for the purpose of formation of the layer contact via cavities 85.

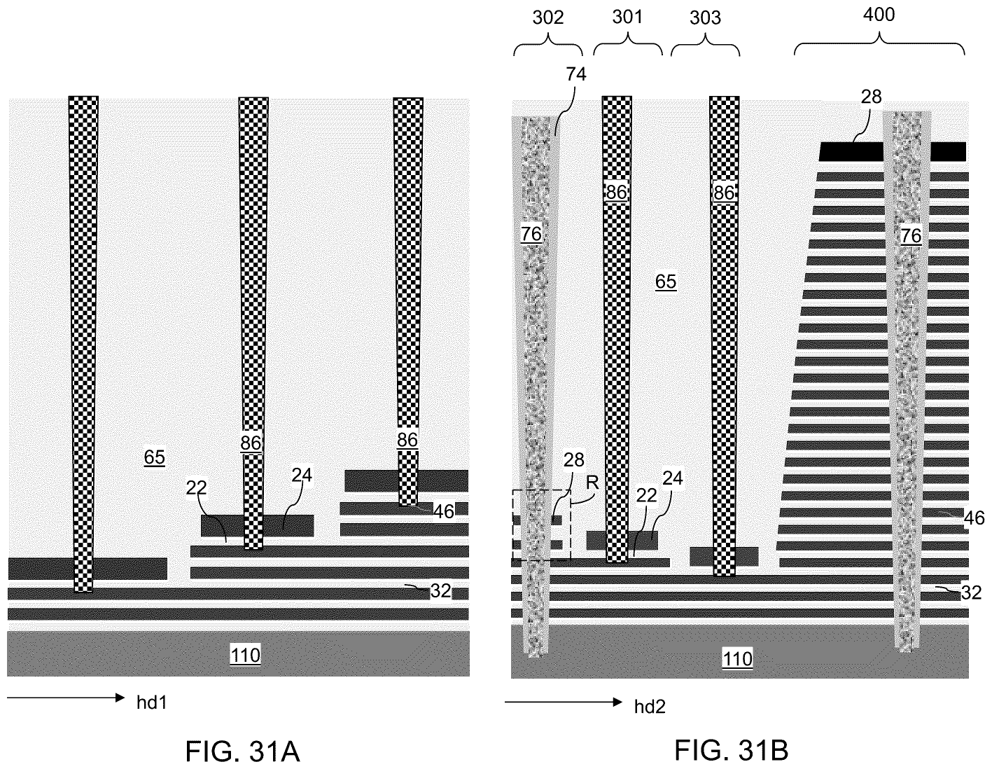

Referring to FIGS. 31A and 31B, an anisotropic etch can be performed to vertically extend the layer contact via cavities 85 through the dielectric etch-stop plates 24 and the conformal silicon oxide liner 22 to top surfaces of the underlying electrically conductive layers 46. At least one conductive material can be deposited in the layer contact via cavities 85 to form layer contact via structures 86.

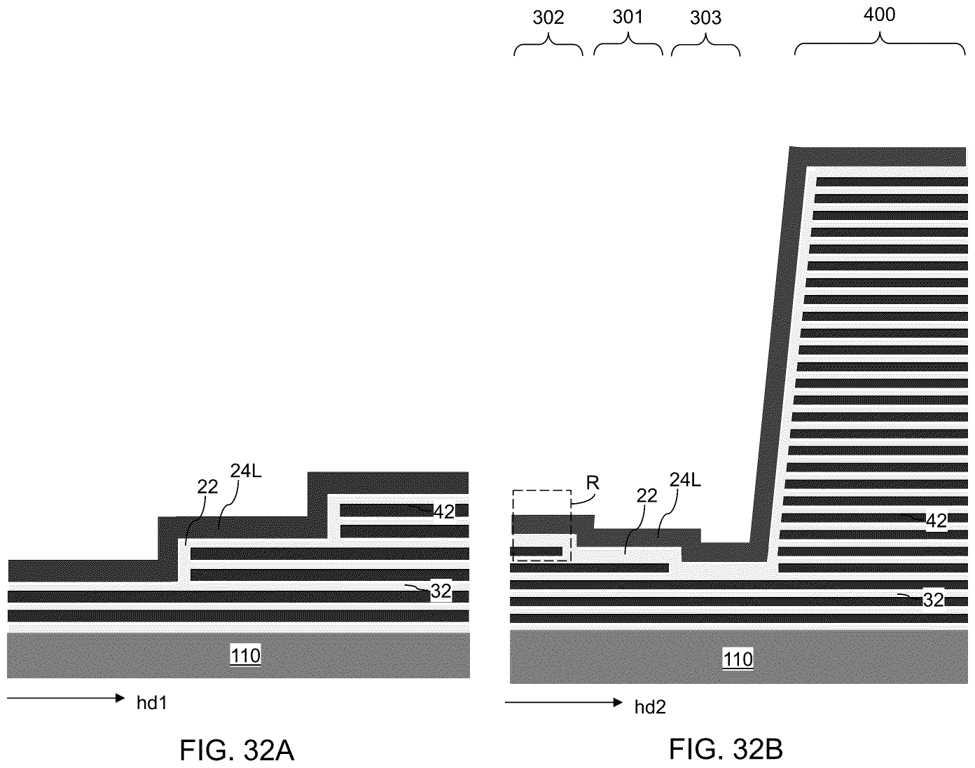

Referring to FIGS. 32A and 32B, a third exemplary structure is illustrated after formation of a conformal silicon oxide liner 22 and a dielectric etch-stop material layer 24L according to a third embodiment of the present disclosure. The third exemplary structure illustrated in FIGS. 32A and 32B may be the same as the second exemplary structure illustrated in FIGS. 22A and 22B. In the third exemplary structure, a third staircase region 303 can be formed between a first staircase region 301 and the connection region 400 as in the alternative configuration of the first exemplary structure which is described with reference to FIGS. 26A and 26B.

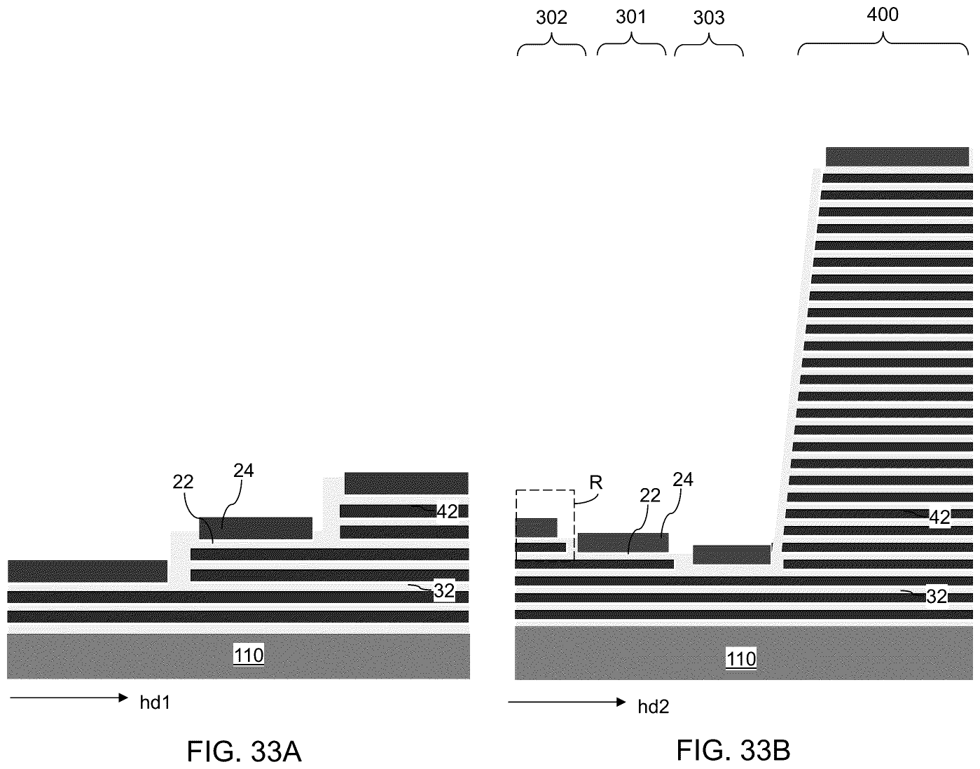

Referring to FIGS. 33A and 33B, the processing steps described with reference to FIGS. 12A-14B can be performed to convert the dielectric etch-stop material layer 24L into rows of dielectric etch-stop plates 24.

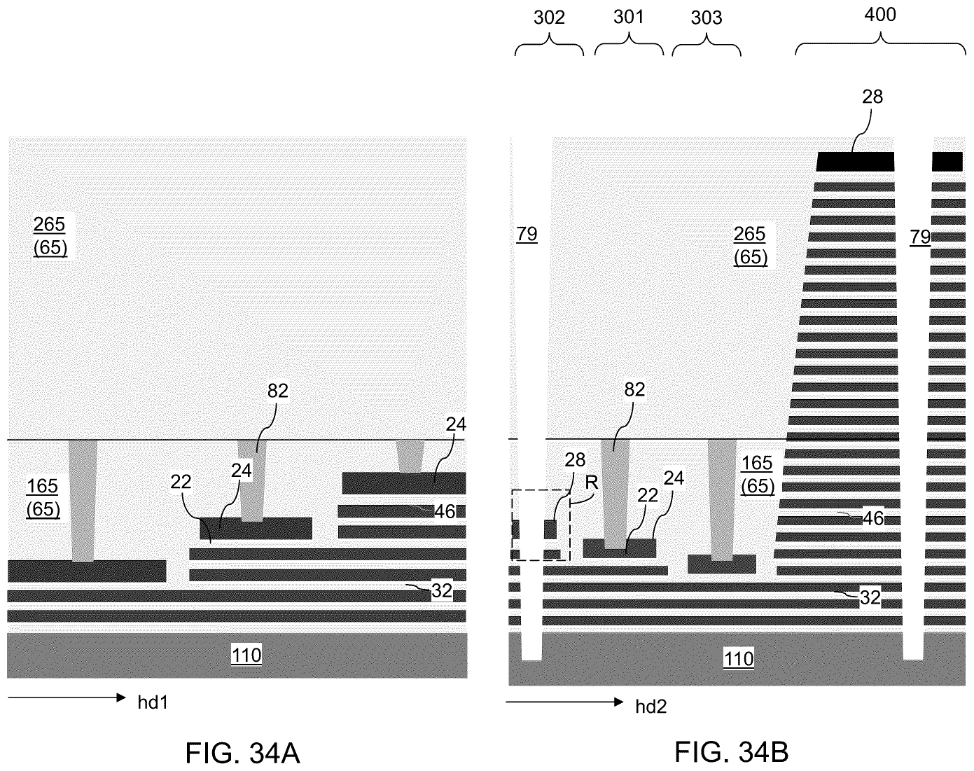

Referring to FIGS. 34A and 34B, the retro-stepped dielectric material portion 65 may be formed as a stack of a first retro-stepped dielectric material portion 165 and a second retro-stepped dielectric material portion 265. Sacrificial via structures 82 may be formed through the first retro-stepped dielectric material portion 165 directly on a respective one of the dielectric etch-stop plates 24. The sacrificial via structures 82 may comprise a sacrificial fill material, such as amorphous carbon or amorphous silicon. The dielectric etch-stop plates 24 can be employed as etch-stop structures during formation of the vias filled by the sacrificial via structures 82. The second retro-stepped dielectric material portion 265 can be formed above the first retro-stepped dielectric material portion 165. The processing steps described with reference to FIGS. 18A-23C can be performed to form a contact-level dielectric layer 80 and lateral isolation trenches 79, and to replace the sacrificial material layers 42 with electrically conductive layers 46, and to replace a subset of the dielectric etch-stop plates 24 into electrically conductive plates 28.

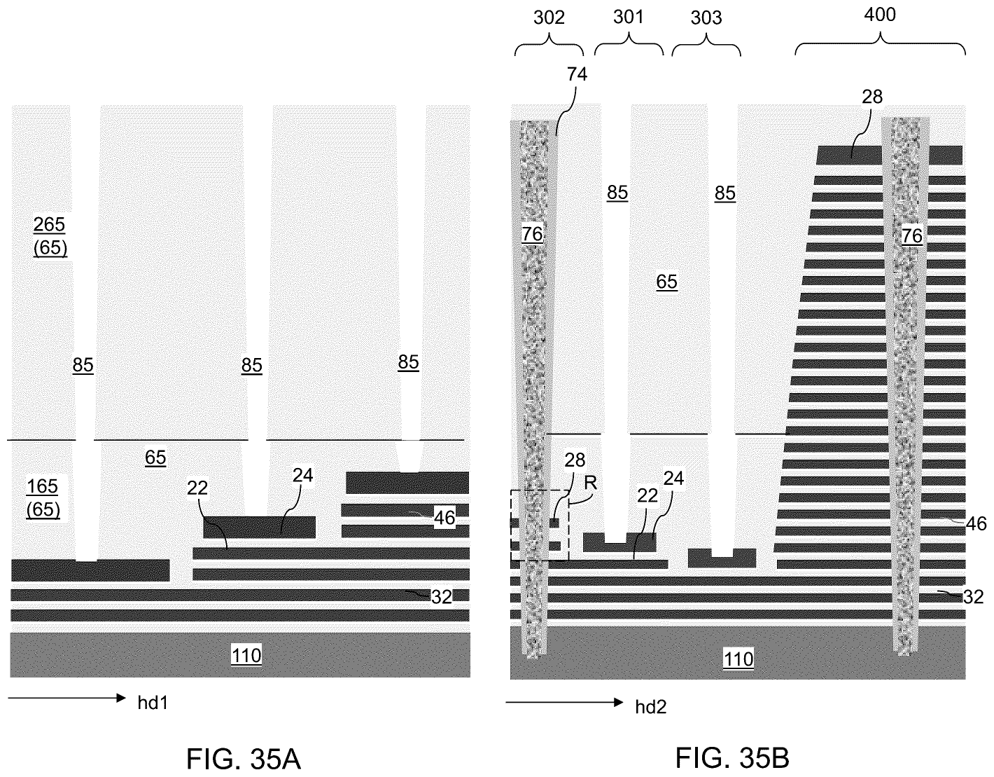

Referring to FIGS. 35A and 35B, the lateral isolation trench fill structures (74, 76) can be formed in the lateral isolation trenches 79. Layer contact via cavities 85 can be formed by forming via cavities through the second retro-stepped dielectric material portion 265 and by removing the sacrificial via structures 82.

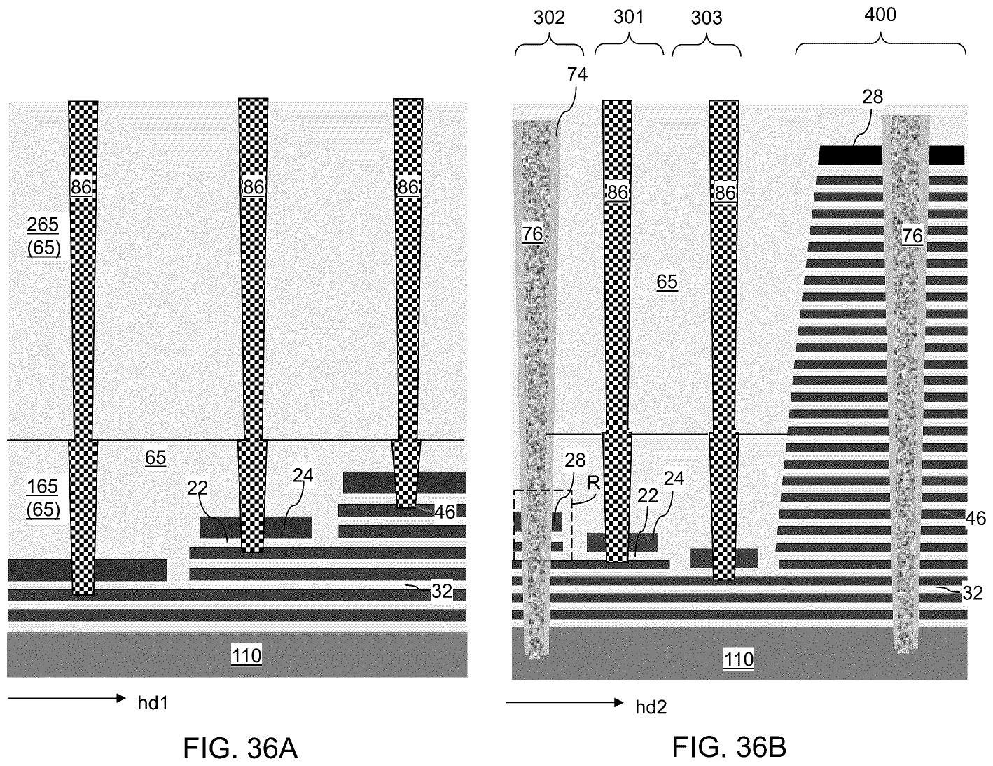

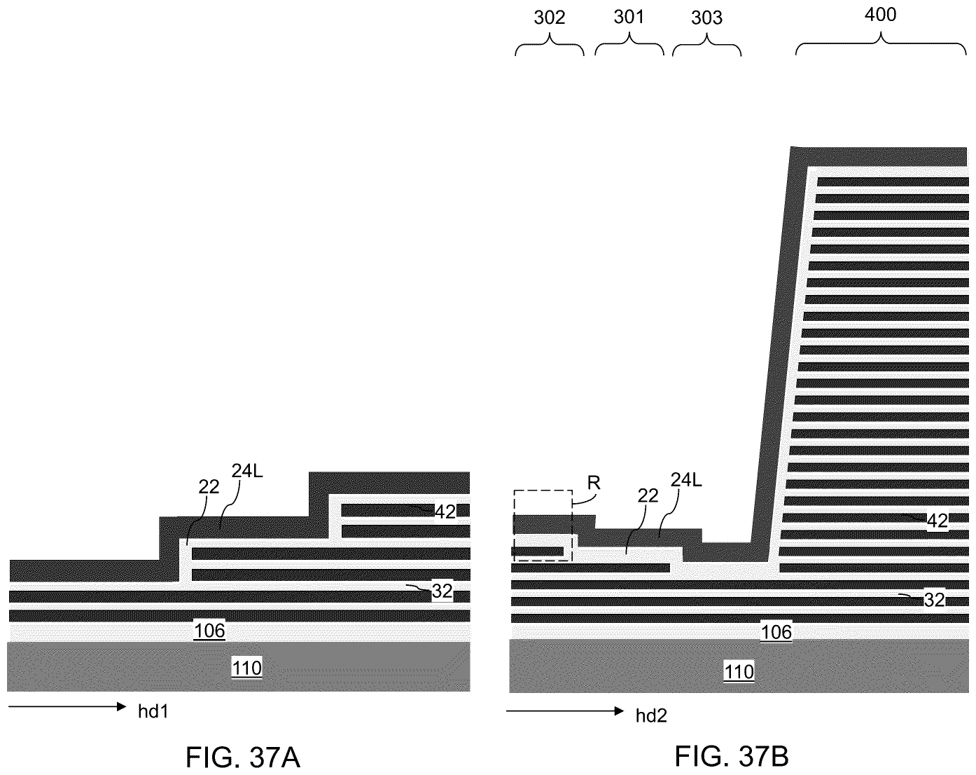

Referring to FIGS. 36A and 36B, an anisotropic etch can be performed to vertically extend the layer contact via cavities 85 through the dielectric etch-stop plates 24 and the conformal silicon oxide liner 22 to top surfaces of the underlying electrically conductive layers 46. At least one conductive material can be deposited in the layer contact via cavities 85 to form layer contact via structures 86.

In the third exemplary structure, each of the layer contact via structures 86 may comprise a respective first tapered sidewall contacting the first retro-stepped dielectric material portion 165, a respective second tapered sidewall that overlies the respective first tapered sidewall and contacting the second retro-stepped dielectric material portion 265, and a respective annular connection surface connecting a top periphery of the respective first tapered sidewall to a bottom periphery of the respective second tapered sidewall.

Referring to FIGS. 32A and 32B, a fourth exemplary structure is illustrated after formation of a conformal silicon oxide liner 22 and a dielectric etch-stop material layer 24L according to a fourth embodiment of the present disclosure. The fourth exemplary structure illustrated in FIGS. 32A and 33B may be derived from the second exemplary structure illustrated in FIGS. 22A and 22B by forming a planar insulating layer 106 between the semiconductor material layer 110 and the alternating stack (32, 42). In the third exemplary structure, a third staircase region 303 can be formed between a first staircase region 301 and the connection region 400 as in the alternative configuration of the first exemplary structure which is described with reference to FIGS. 26A and 26B.

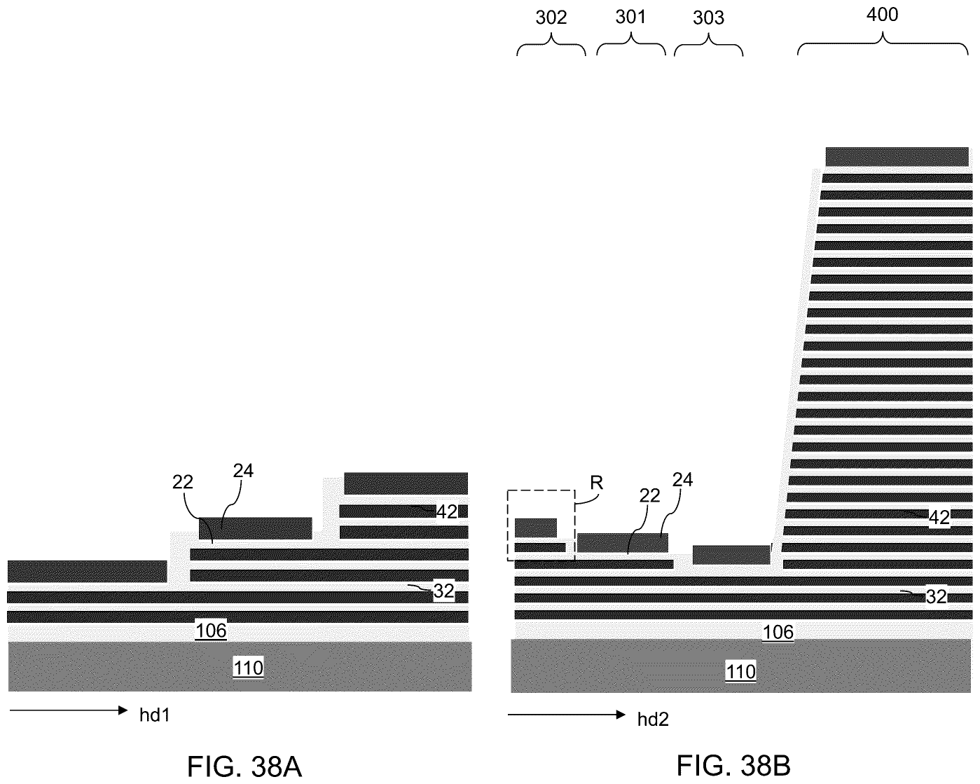

Referring to FIGS. 38A and 38B, the processing steps described with reference to FIGS. 12A-14B can be performed to convert the dielectric etch-stop material layer 24L into rows of dielectric etch-stop plates 24.

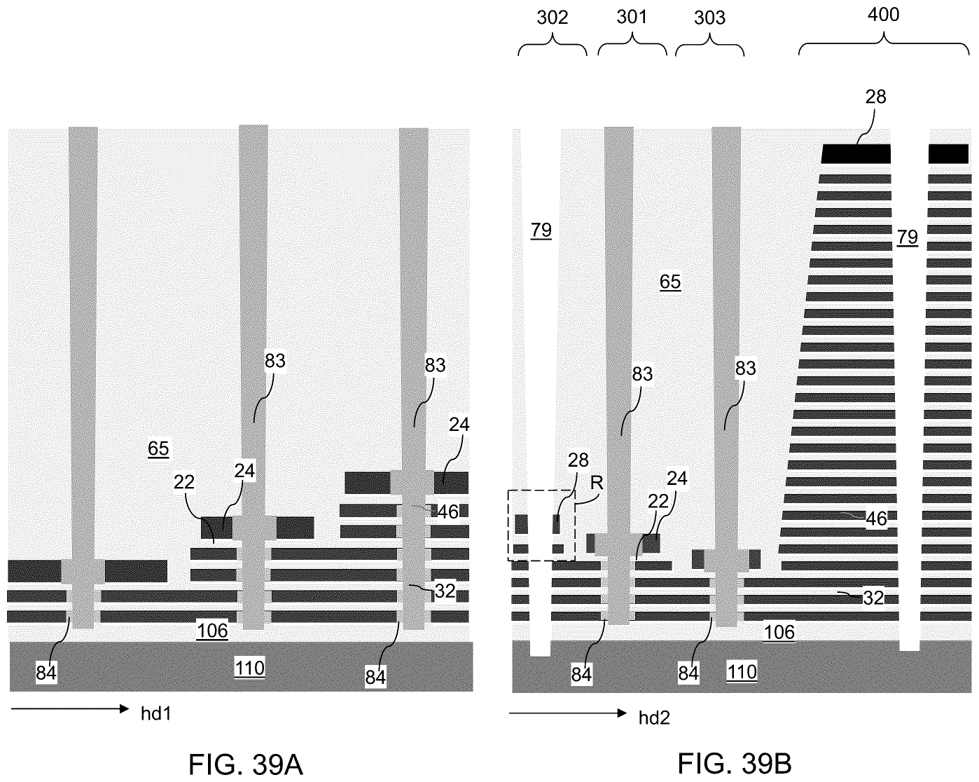

Referring to FIGS. 39A and 39B, via cavities can be formed through the retro-stepped dielectric material portion 65, through a respective one of the dielectric etch-stop plates 24, the conformal silicon oxide liner 22, and underlying portions of the alternating stack (32, 42) and into an upper portion of the planar insulating layer 106. Annular fin cavities can be formed around each via cavity by laterally recessing the sacrificial material layers 42. Annular contact cavities can be formed by laterally recessing the dielectric etch-stop plates 24 around the via cavities. A dielectric liner having a greater thickness than one half of the thickness of each sacrificial material layer and having a lesser thickness than one half of the thickness of each dielectric etch-stop plate 24 can be conformally deposited around each via cavity, and can be isotropically partially etched. Each remaining portion of the dielectric liner that fills an annular fin cavity constitutes an annular dielectric fin spacer 84. The dielectric liner is removed from inside the annular contact cavities. A sacrificial fill material, such as amorphous silicon or carbon, can be deposited in the remaining volumes of the via cavities to form sacrificial contact via structures 83. The processing steps described with reference to FIGS. 18A-23C can be performed to form a contact-level dielectric layer 80 and lateral isolation trenches 79, and to replace the sacrificial material layers 42 with electrically conductive layers 46, and to replace a subset of the dielectric etch-stop plates 24 into electrically conductive plates 28.

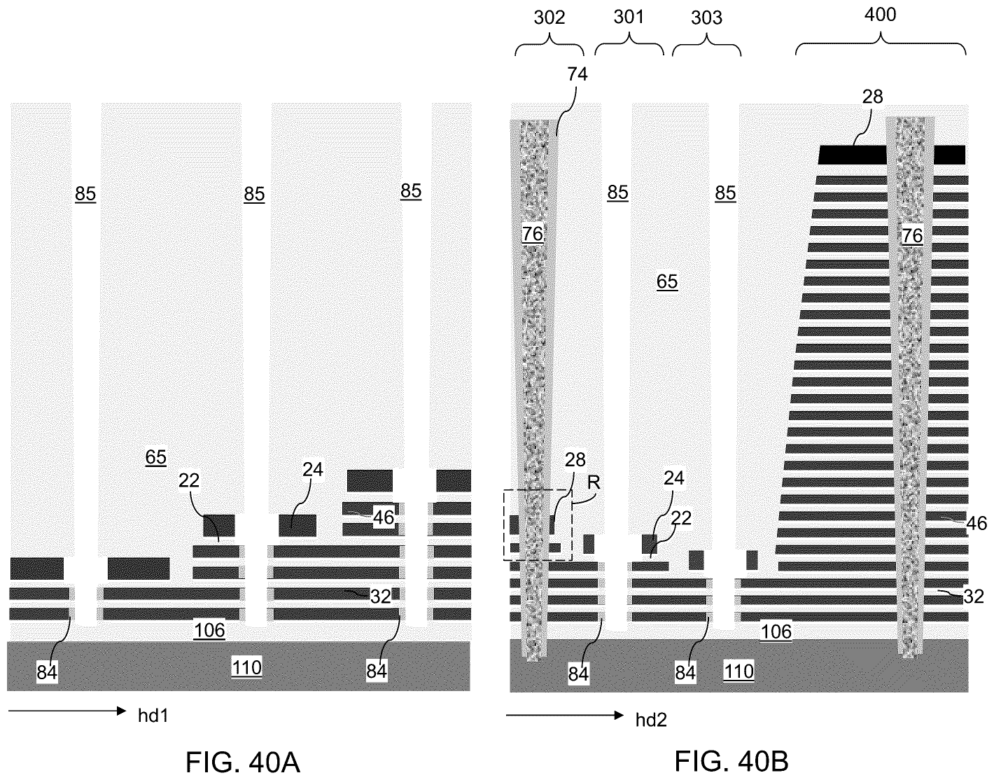

Referring to FIGS. 40A and 40B, the lateral isolation trench fill structures (74, 76) can be formed in the lateral isolation trenches 79. Layer contact via cavities 85 can be formed by forming via cavities through the second retro-stepped dielectric material portion 265 and by removing the sacrificial via structures 83.

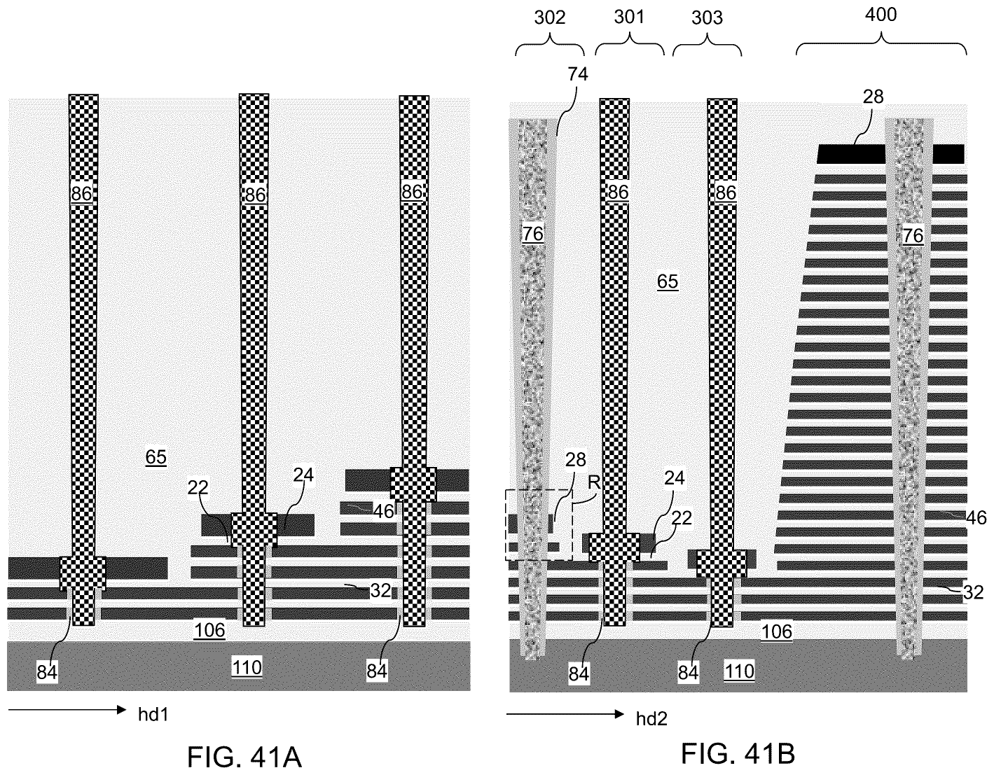

Referring to FIGS. 41A and 41B, at least one conductive material can be deposited in the layer contact via cavities 85 to form layer contact via structures 86. In the fourth exemplary structure, each of the layer contact via structures 86 comprises an upper cylindrical portion overlying the respective one of the first dielectric etch-stop plates 24, a bulging portion having a greater lateral extent than the upper cylindrical portion and contacting an annular top surface of the respective one of the word lines (comprising a middle subset of the electrically conductive layers 46), and a lower cylindrical portion having a lesser lateral extent than the bulging portion and vertically extending through the respective one of the word lines (comprising the middle subset of the electrically conductive layers 46) and any additional electrically conductive layer 46 that underlies the respective one of the word lines. The additional electrically conductive layers 46 may comprise source-side select gate electrodes.

Referring to all drawings and according to various embodiments of the present disclosure, a three-dimensional memory device is provided, which comprises: an alternating stack (32, 46) of insulating layers 32 and electrically conductive layers 46, wherein each layer within the alternating stack (32, 46) is present in a first memory array region 100A and in a second memory array region 100B that are laterally spaced from each other along a first horizontal direction hd1, and the first memory array region 100A and the second memory array region 100B have a first width along a second horizontal direction hd2 that is perpendicular to the first horizontal direction hd1; first memory openings 49 and second memory openings 49 vertically extending through the alternating stack (32, 46) in the first memory array region 100A and in the second memory array region 100B, respectively; first memory opening fill structures 58 and second memory opening fill structures 58 located in the first memory openings 49 and in the second memory openings 49, respectively, and comprising a respective vertical stack of memory elements (e.g., portions of the memory film 50) and a vertical semiconductor channel, wherein a predominant subset of the electrically conductive layers 46 comprise word lines (comprising a middle subset of the electrically conductive layers 46) for the vertical stacks of memory elements; and an intermediate region 200 located between the first memory array region 100A and the second memory array region 100B and comprising, in order along a second horizontal direction hd2 that is perpendicular to the first horizontal direction hd1, a connection region 400 in which the word lines continuously extend between the first memory array region 100A and the second memory array region 100B with a respective width that is less than the first width, a first staircase region 301 in which first horizontally-extending surface segments of the alternating stack (32, 46) are arranged along the first horizontal direction hd1 and are interconnected to each other by first vertically-extending surface segments, and a second staircase region 302 in which second horizontally-extending surface segments of the alternating stack (32, 46) are arranged along the first horizontal direction hd1 and are interconnected to each other by second vertically-extending surface segments, wherein each of the second horizontally-extending surface segments is vertically offset upward relative to a respective neighboring one of the first horizontally-extending surface segments by a respective offset vertical step.

In one embodiment, the three-dimensional memory device comprises a row of first dielectric etch-stop plates 24 located on the first horizontally-extending surface segments of the alternating stack (32, 46), and a row of electrically conductive plates 28 located on the second horizontally-extending surface segments of the alternating stack (32, 46).

In one embodiment, the three-dimensional memory device comprises a row of layer contact via structures 86, wherein each of the layer contact via structures 86 vertically extends through a respective one of the first dielectric etch-stop plates 24 and contacts a respective one of the word lines. In one embodiment, no layer contact via structures 86 extend through the electrically conductive plates 28 because they are located over the ridge R which comprises a dummy staircase (e.g., dummy terrace) in which to connections are made between the contact via structures 86 and the word lines.

In one embodiment, each of the layer contact via structures 86 comprises a respective first tapered sidewall, a respective second tapered sidewall that overlies the respective first tapered sidewall, and a respective annular connection surface connecting a top periphery of the respective first tapered sidewall to a bottom periphery of the respective second tapered sidewall.

In one embodiment, each of the layer contact via structures comprises an upper cylindrical portion overlying the respective one of the first dielectric etch-stop plates 24, a bulging portion having a greater lateral extent than the upper cylindrical portion and contacting an annular top surface of the respective one of the word lines (as embodied as a subset of the electrically conductive layers 46), and a lower cylindrical portion having a lesser lateral extent than the bulging portion and vertically extending through the respective one of the word lines (as embodied as the subset of the electrically conductive layers 46) and any additional electrically conductive layer that underlies the respective one of the word lines (as embodied as the subset of the electrically conductive layers 46).

In one embodiment, the electrically conductive plates 28 comprise a same material as the electrically conductive layers 46. In one embodiment, the electrically conductive layers 46 have a first thickness; and the electrically conductive plates 28 have a second thickness that is at least 1.5 times the first thickness. In one embodiment, the first dielectric etch-stop plates 24 have the second thickness.

In one embodiment, each of the electrically conductive plates 28 has a lesser length along the first horizontal direction hd1, and has a lesser width along the second horizontal direction hd2, than a respective underlying one of the second horizontally-extending surface segments; and each of the dielectric etch-stop plates 24 has a lesser length along the first horizontal direction hd1, and has a lesser width along the second horizontal direction hd2, than a respective underlying one of the first horizontally-extending surface segments of the alternating stack (32, 46).

In one embodiment, the first and the second staircase regions (301, 302) are located in a recess well RW4 between two adjacent connection regions 400; and the second staircase region comprises a ridge R which extends along the first horizontal direction hd1, is offset from sidewalls of the recess well RW4 along the second horizontal direction hd2, and has an upper surface located above a bottom surface of the recess well RW4.

In one embodiment, the three-dimensional memory device comprises: a first lateral isolation trench fill structure 78A that laterally extends along the first horizontal direction hd1 and contacts first sidewalls of the alternating stack (32, 46) in the first memory array region 100A, in the second memory array region 100B, and in the connection region 400; and a second lateral isolation trench fill structure 78B that laterally extends along the first horizontal direction hd1 and contacts second sidewalls of the alternating stack (32, 46) in the first memory array region 100A and in the second memory array region 100B and in the ridge R, and contacts the row of electrically conductive plates 28 located above the top surface of the ridge R.

In one embodiment, the three-dimensional memory device comprises a retro-stepped dielectric material portion 65 located in the recess well RW4 overlying the first staircase region 301 and the second staircase region 302 and contacting a tapered sidewall of a portion of the alternating stack (32, 46) in the connection region 400, the tapered sidewall laterally extending along the first horizontal direction hd1.

In one embodiment, all of the vertical steps have a same height. In one embodiment, the insulating layers 32 have a first thickness; the electrically conductive layers 46 have a second thickness; and the same height is an integer multiple of a sum of the first thickness and the second thickness. In one embodiment, the intermediate region 200 further comprises a third staircase region located between the first staircase region 301 and the connection region 400, wherein third horizontally-extending surface segments of the alternating stack (32, 46) are arranged along the first horizontal direction hd1 and are interconnected to each other by third vertically-extending surface segments in the third staircase region; and a row of dielectric etch-stop plates 24 are located on the third horizontally-extending surface segments of the alternating stack (32, 46).

The various embodiments of the present disclosure can be employed to provide rows of dielectric etch-stop plates 24 that are not replaced with electrically conductive plates 28 during replacement of sacrificial material layers 42 with electrically conductive layers 46. The dielectric etch-stop plates 24 can be employed as etch-stop structures during formation of all via cavities for formation of layer contact via structures 86. Furthermore, the patterning and etching steps used to form the dielectric etch-stop plates 24 is simplified by adding the ridge R, which allows a set of the dielectric etch-stop plates 24 to be laterally separated from the second lateral isolation trench 79B, to prevent replacement of this set of the dielectric etch-stop plates 24 with the electrically conductive plates 28.

Although the foregoing refers to particular preferred embodiments, it will be understood that the disclosure is not so limited. It will occur to those of ordinary skill in the art that various modifications may be made to the disclosed embodiments and that such modifications are intended to be within the scope of the disclosure. Compatibility is presumed among all embodiments that are not alternatives of one another. The word “comprise” or “include” contemplates all embodiments in which the word “consist essentially of” or the word “consists of” replaces the word “comprise” or “include,” unless explicitly stated otherwise. Whenever two or more elements are listed as alternatives in a same paragraph of in different paragraphs, a Markush group including a listing of the two or more elements is also impliedly disclosed. Whenever the auxiliary verb “can” is employed in this disclosure to describe formation of an element or performance of a processing step, an embodiment in which such an element or such a processing step is not performed is also expressly contemplated, provided that the resulting apparatus or device can provide an equivalent result. As such, the auxiliary verb “can” as applied to formation of an element or performance of a processing step should also be interpreted as “may” or as “may, or may not” whenever omission of formation of such an clement or such a processing step is capable of providing the same result or equivalent results, the equivalent results including somewhat superior results and somewhat inferior results. Where an embodiment employing a particular structure and/or configuration is illustrated in the present disclosure, it is understood that the present disclosure may be practiced with any other compatible structures and/or configurations that are functionally equivalent provided that such substitutions are not explicitly forbidden or otherwise known to be impossible to one of ordinary skill in the art. If publications, patent applications, and/or patents are cited herein, each of such documents is incorporated herein by reference in their entirety.

What is claimed is:

1. A three-dimensional memory device, comprising:
an alternating stack of insulating layers and electrically conductive layers, wherein each layer within the alternating stack is present in a first memory array region and in a second memory array region that are laterally spaced from each other along a first horizontal direction, and the first memory array region and the second memory array region have a first width along a second horizontal direction that is perpendicular to the first horizontal direction;
first memory openings and second memory openings vertically extending through the alternating stack in the first memory array region and in the second memory array region, respectively;
first memory opening fill structures and second memory opening fill structures located in the first memory openings and in the second memory openings, respectively, and comprising a respective vertical stack of memory elements and a vertical semiconductor channel, wherein a predominant subset of the electrically conductive layers comprise word lines for the vertical stacks of memory elements;
an intermediate region located between the first memory array region and the second memory array region and comprising, in order along the second horizontal direction, a connection region in which at least a majority of the word lines continuously extend between the first memory array region and the second memory array region with a respective width that is less than the first width, a first staircase region in which first horizontally-extending surface segments of the alternating stack are arranged along the first horizontal direction and are interconnected to each other by first vertically-extending surface segments, and a second staircase region in which second horizontally-extending surface segments of the alternating stack are arranged along the first horizontal direction and are interconnected to each other by second vertically-extending surface segments, wherein each of the second horizontally-extending surface segments is vertically offset upward relative to a respective neighboring one of the first horizontally-extending surface segments by a respective offset vertical step;
a row of first dielectric etch-stop plates located on the first horizontally-extending surface segments of the alternating stack; and
a row of electrically conductive plates located on the second horizontally-extending surface segments of the alternating stack.

2. The three-dimensional memory device of claim 1, further comprising a row of layer contact via structures, wherein each of the layer contact via structures vertically extends through a respective one of the first dielectric etch-stop plates and contacts a respective one of the word lines.

3. The three-dimensional memory device of claim 2, wherein no layer contact via structures extend through the electrically conductive plates.

4. The three-dimensional memory device of claim 2, wherein each of the layer contact via structures comprises a respective first tapered sidewall, a respective second tapered sidewall that overlies the respective first tapered sidewall, and a respective annular connection surface connecting a top periphery of the respective first tapered sidewall to a bottom periphery of the respective second tapered sidewall.

5. The three-dimensional memory device of claim 2, wherein each of the layer contact via structures comprises an upper cylindrical portion overlying the respective one of the first dielectric etch-stop plates, a bulging portion having a greater lateral extent than the upper cylindrical portion and contacting an annular top surface of the respective one of the word lines, and a lower cylindrical portion having a lesser lateral extent than the bulging portion and vertically extending through the respective one of the word lines and any additional electrically conductive layer that underlies the respective one of the word lines.

6. The three-dimensional memory device of claim 2, wherein:
the first and the second staircase regions are located in a recess well between two adjacent connection regions; and
the second staircase region comprises a ridge which extends along the first horizontal direction, is offset from sidewalls of the recess well along the second horizontal direction, and has an upper surface located above a bottom surface of the recess well.

7. The three-dimensional memory device of claim 6, further comprising:
a first lateral isolation trench fill structure that laterally extends along the first horizontal direction and contacts first sidewalls of the alternating stack in the first memory array region, in the second memory array region, and in the connection region; and
a second lateral isolation trench fill structure that laterally extends along the first horizontal direction and contacts second sidewalls of the alternating stack in the first memory array region and in the second memory array region and in the ridge, and contacts the row of electrically conductive plates located above the top surface of the ridge.

8. The three-dimensional memory device of claim 7, further comprising a retro-stepped dielectric material portion located in the recess well overlying the first staircase region and the second staircase region and contacting a tapered sidewall of a portion of the alternating stack in the connection region, the tapered sidewall laterally extending along the first horizontal direction.

9. The three-dimensional memory device of claim 1, wherein:
the electrically conductive plates comprise a same material as the electrically conductive layers;
the electrically conductive layers have a first thickness; and
the electrically conductive plates have a second thickness that is at least 1.5 times the first thickness.

10. The three-dimensional memory device of claim 9, wherein the first dielectric etch-stop plates have the second thickness.

11. The three-dimensional memory device of claim 9, wherein:
each of the electrically conductive plates has a lesser length along the first horizontal direction, and has a lesser width along the second horizontal direction, than a respective underlying one of the second horizontally-extending surface segments; and
each of the dielectric etch-stop plates has a lesser length along the first horizontal direction, and has a lesser width along the second horizontal direction, than a respective underlying one of the first horizontally-extending surface segments of the alternating stack.

12. The three-dimensional memory device of claim 1, wherein all of the offset vertical steps have a same height.

13. The three-dimensional memory device of claim 12, wherein:
the insulating layers have a first thickness;
the electrically conductive layers have a second thickness; and
the same height is an integer multiple of a sum of the first thickness and the second thickness.

14. The three-dimensional memory device of claim 1, wherein:
the intermediate region further comprises a third staircase region located between the first staircase region and the connection region, wherein third horizontally-extending surface segments of the alternating stack are arranged along the first horizontal direction and are interconnected to each other by third vertically-extending surface segments in the third staircase region; and
a row of dielectric etch-stop plates are located on the third horizontally-extending surface segments of the alternating stack.

15. A method forming a device structure, comprising:
forming an alternating stack of insulating layers and sacrificial material layers over a substrate, wherein the alternating stack comprises a first memory array region, a second memory array region that is laterally spaced from the first memory array region along a first horizontal direction, and an intermediate region that is located between the first memory array region and the second memory array region;
forming stepped surfaces within the intermediate region, wherein the intermediate region comprises a connection region in which at least a majority of the sacrificial material layers continuously extend between the first memory array region and the second memory array region, a first staircase region in which first horizontally-extending surface segments of the alternating stack are arranged along the first horizontal direction and are interconnected to each other by first vertically-extending surface segments, and a second staircase region in which second horizontally-extending surface segments of the alternating stack are arranged along the first horizontal direction and are interconnected to each other by second vertically-extending surface segments, wherein each of the second horizontally-extending surface segments is vertically offset upward relative to a respective neighboring one of the first horizontally-extending surface segments by a respective offset vertical step;
forming a row of first dielectric etch-stop plates over the first horizontally-extending surface segments of the alternating stack;
forming a row of second dielectric etch-stop plates over the second horizontally-extending surface segments of the alternating stack;
forming a retro-stepped dielectric material portion over the first dielectric etch-stop plates and the second dielectric etch-stop plates;
forming a first lateral isolation trench outside an area of the retro-stepped dielectric material portion and a second lateral isolation trench through the retro-stepped dielectric material portion and through the second dielectric etch-stop plates; and
replacing the sacrificial material layers and the second dielectric etch-stop plates with electrically conductive layers and electrically conductive plates, respectively, without removing the first dielectric etch-stop plates.

16. The method of claim 15, further comprising forming layer contact via structures through the retro-stepped dielectric material portion, wherein each of the layer contact via structures is formed through a respective one of the first dielectric etch-stop plates and directly on a respective one of the electrically conductive layers.

17. The method of claim 15, further comprising:
forming memory openings through the alternating stack in the first memory array region and in the second memory array region; and
forming memory opening fill structures in the memory openings, wherein each of the memory opening fill structures comprises a respective vertical stack of memory elements and a vertical semiconductor channel.

18. The method of claim 15, further comprising:
conformally depositing a dielectric etch-stop material layer over the first horizontally-extending surface segments, the second horizontally-extending surface segments, and vertical steps of the alternating stack;
forming a cover material layer over horizontally-extending surfaces of the dielectric etch-stop material layer without covering vertically-extending surface surfaces of the dielectric etch-stop material layer; and
isotropically etching uncovered portions of the dielectric etch-stop material layer, wherein remaining portions of the dielectric etch-stop material layer comprise the first dielectric etch-stop plates and the second dielectric etch-stop plates.

19. The method of claim 15, wherein:
the intermediate region further comprises a third staircase region located between the first staircase region and the connection region;
third horizontally-extending surface segments of the alternating stack are arranged along the first horizontal direction and are interconnected to each other by third vertically-extending surface segments in the third staircase region; and
forming a row of third dielectric etch-stop plates on the third horizontally-extending surface segments of the alternating stack.

20. The method of claim 15, further comprising forming a conformal silicon oxide liner directly on each of the first horizontally-extending surface segments, the first vertically-extending surface segments, the second horizontally-extending surface segments, and the second vertically-extending surface segments, wherein the first dielectric etch-stop plates and the second dielectric etch-stop plates are formed directly on top surfaces of the conformal silicon oxide liner.
